(19) United States
(12) Patent Application Publication
(10) Pub. No.: US 2024/0085784 A1
(43) Pub. Date: Mar. 14, 2024

(54) ORGANIC EL DISPLAY DEVICE

(71) Applicants: TOYO INK SC HOLDINGS CO., LTD., Tokyo (JP); TOYO VISUAL SOLUTIONS CO., LTD., Tokyo (JP); TOPPAN INC., Tokyo (JP)

(72) Inventors: Taketo KOGURE, Tokyo (JP); Kenji HIKI, Tokyo (JP); Kazufumi NISHIDA, Tokyo (JP); Shinji TSUNEKAWA, Tokyo (JP); Atsushi YAMAUCHI, Tokyo (JP); Hiroki NAGATOME, Tokyo (JP)

(73) Assignees: TOYO INK SC HOLDINGS CO., LTD., Tokyo (JP); TOYO VISUAL SOLUTIONS CO., LTD., Tokyo (JP); TOPPAN INC., Tokyo (JP)

(21) Appl. No.: 18/475,169

(22) Filed: Sep. 26, 2023

Related U.S. Application Data
(63) Continuation of application No. PCT/JP22/16191, filed on Mar. 30, 2022.

(30) Foreign Application Priority Data
Apr. 22, 2021 (JP) 2021-072704

(51) Int. Cl. G03F 7/00; G03F 7/004; G03F 7/031; H10K 59/38

(52) U.S. Cl. CPC G03F 7/0007; G03F 7/0048; G03F 7/031; H10K 59/38

(57) ABSTRACT

Provided is an organic EL display device that exhibits high luminance and high color reproducibility and has a color filter which exhibits excellent pixel adhesion and excellent pixel linearity in a development step even in a case of high colorant concentration. This organic EL display device comprises an organic EL layer and a color filter on a silicon substrate in which a driving element is formed. The color filter has pixels including specific red, green, and blue pixels. Each of the pixels is a cured product of a photosensitive coloring composition which contains a specific colorant (A), a photopolymerizable monomer (B), a photopolymerization initiator (C), and a resin (D). The photopolymerizable monomer (B) includes a compound represented by formula (1), and the photopolymerization initiator (C) includes an oxime ester photopolymerization initiator. Formula (1): [CH₂═CHC(═O)—(OCₘH₂ₘ)ₙ—OCH₂]₃—CCH₂CH₃ (Signs in formula (1) are according to those described in the description.)

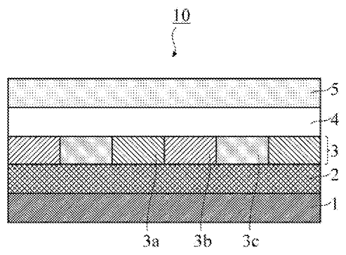

### CROSS-REFERENCE TO RELATED APPLICATION

This application is a continuation application of International Application number PCT/JP2022/016191 on Mar. 30, 2022, which claims the priority benefit of Japan Patent Application No. 2021-072704, filed on Apr. 22, 2021. The entirety of each of the above-mentioned patent applications is hereby incorporated by reference herein and made a part of this specification.

### BACKGROUND

### Technical Field

The present disclosure relates to an organic EL display device.

### Related Art

In recent years, in electronic devices such as mobile phones and personal digital assistants, in order to meet the demand for thinner, lighter-weight and curved displays, which has been difficult to achieve in current mainstream liquid crystal display devices, development and mass production of display devices using organic electroluminescence (organic EL), which are self-light emitting elements, have progressed. Amid this, in order to take advantage of features of thinness and lightness, application to high-definition and small displays of about 0.5 inches (hereinafter referred to as micro-displays) such as head-mounted displays and electronic viewfinders is expected.

For display methods for organic EL displays, there are two main methods: a method of forming a white-light emitting layer and expressing colors such as RGB using a color filter and a method of expressing colors by depositing light emitting layers that emit respective colors such as RGB. Since the micro-displays have fine pixels, it is very difficult to apply a method of selectively forming RGB light emitting layers. Therefore, the method of using a color filter for a white-light emitting layer is actively used for the micro-displays.

As described above, since the micro-displays have a fine pixel size of 1 μm to 5 μm, in a method of producing organic EL elements and color filters on separate substrates and bonding them, which is conventionally used, the accuracy is lowered and color shifts occur. Therefore, a method of forming a color filter on an organic EL element has been proposed.

Color filters can be produced by methods such as an inkjet method and a photolithographic method, and the photolithographic method which allows fine pixels to be formed is being used. However, since the organic light emitting layer has low heat resistance, it is necessary to perform firing at a low temperature in order to form a color filter on an organic EL element. Specifically, in conventional photolithographic methods, firing is performed at a very high temperature of 230° C., but firing at about 100° C. is necessary. However, if the firing temperature of colored pixels is lowered, curing becomes insufficient, and problems such as peeling off of colored pixels and the rough surface due to the solvent contained in the applied coloring composition occur during pixel formation in the next step. On the other hand, when the amount of exposure increases, the reaction of crosslinkable components contained in the colored pixels progresses and curing progresses, but it is very difficult to form pixels with any size.

In order to address the above problems, for example, Patent Literature 1 proposes a method of improving curability at a low temperature using a coloring composition containing an alkali-soluble resin containing an epoxy group and an amine compound as a curing agent. However, when an amine compound is added to the coloring composition, there is a risk of transmittance of the color filter being reduced. In addition, Patent Literature 2 proposes a method of performing curing at a low temperature using an oxetane compound and a benzophenone compound having a peroxide framework as a thermal polymerization initiator.

### CITATION LIST

### Patent Literature

[Patent Literature 1]

Japanese Patent Laid-Open No. 2012-063745
[Patent Literature 2]

Japanese Patent Laid-Open No. 2003-255531

However, in the above Patent Literature 1 and 2, the curing temperature is 150° C., and in consideration of heat resistance of organic EL elements, curability at a lower temperature is required. In addition, in order to achieve high color reproducibility, it is necessary to control spectral transmittance of the color filter by adding a colorant, and in order to make the film thinner, it is necessary to increase the concentration of the colorant. In the methods of Patent Literature 1 and 2, if the concentration of the colorant is high, there are problems that photocurability is insufficient, it is very difficult to obtain sufficient sensitivity for patterning, and when fine pixels are formed, the linearity of the pixels deteriorates (poor pixel linearity), and the pixels peel off in the development step (poor adhesion). In addition, there is a problem that the colorants that can be used are limited.

In view of the above problems, an objective of the present disclosure is to provide an organic EL display device which has high luminance and high color reproducibility and includes a color filter which has favorable pixel adhesion and favorable pixel linearity in a development step even if a concentration of a colorant is high.

### SUMMARY

An organic EL display device according to the present disclosure is an organic EL display device including an organic EL layer and a color filter on a silicon substrate on which a driving element is formed,
wherein the color filter has pixels including red pixels, green pixels, and blue pixels,
wherein, when the film thickness of the pixel is 1.5 μm, for the spectral transmittance of the red pixel, the maximum transmittance of light in a wavelength range of 450 nm to 560 nm is 0.5% or less, the 50% half-value wavelength is 593 nm to 603 nm, and the maximum transmittance of light in a wavelength range of 600 nm to 700 nm is 80% or more and less than 100%,
for the spectral transmittance of the green pixel, the maximum transmittance of light in a wavelength range of 400 nm to 470 nm is 2% or less, the maximum transmittance of light at a wavelength of 525 to 535 nm is 67% or more, the 50% half-value wavelength on the short wavelength side is 497 to 507 nm, and the 50% half-value wavelength on the long wavelength side is 554 to 581 nm, and
for the spectral transmittance of the blue pixel, the maximum transmittance of light in a wavelength range of 500 nm to 560 nm is less than 20%,
wherein the pixel is a cured product of a photosensitive coloring composition containing a colorant (A), a photopolymerizable monomer (B), a photopolymerization initiator (C) and a resin (D),
wherein, in the red pixel, the colorant (A) contains Pigment Red 177 and other colorants,
wherein, in the green pixel, the colorant (A) contains Pigment Yellow 185, and one or more selected from the group consisting of Pigment Green 36, Pigment Green 62, Pigment Green 63 and Pigment Green 59, and optionally contains other colorants, and the content of Pigment Yellow 185 in the colorant (A) of the green pixel is 49 weight % to 59 weight %,
wherein the blue pixel contains Pigment Blue 15:6 and other colorants,
wherein, in the red pixel, the other colorants include one or more selected from the group consisting of Pigment Red 254 and Pigment Yellow 139,
wherein, in the green pixel, the other colorants include Pigment Blue 15:3,
wherein, in the blue pixel, the other colorants include one or more selected from the group consisting of Pigment Violet 23 and a xanthene dye,
wherein the photopolymerizable monomer (B) contains a compound represented by the following General Formula (1), and
wherein the photopolymerization initiator (C) contains an oxime ester photopolymerization initiator:

[CH₂═CHC(═O)—(OCₘH₂ₘ)ₙ—OCH₂]₃—CR General Formula (1)

(in General Formula (1), m represents an integer of 1 to 3, n represents an integer of 0 to 2, and a plurality of m and n may be the same as or different from each other, and R represents a substituent selected from among —CH₂CH₃, —CH₂OH, and —CH₂O(C═O)C═CH₂).

In one embodiment of the organic EL display device,
a cured product constituting the red pixel contains a colorant (A-1) Pigment Red 177, a colorant (A-2) Pigment Red 254, and a colorant (A-3) Pigment Yellow 139,
in the colorant (A) in the red pixel,
the content of the colorant (A-1) is 55 weight % to 65 weight %,
the content of the colorant (A-2) is 15 weight % to 25 weight %, and
the content of the colorant (A-3) is 15 weight % to 25 weight %, a cured product constituting the green pixel contains a colorant (A-4) Pigment Yellow 185, a colorant (A-5) Pigment Green 36, a colorant (A-6) Pigment Green 62, a colorant (A-11) Pigment Green 63, a colorant (A-12) Pigment Green 59, and a colorant (A-7) Pigment Blue 15:3 according to the following combinations (I) to (IV):
(I) the colorant (A-4), the colorant (A-5) and the colorant (A-7)
(II) the colorant (A-4) and the colorant (A-6)
(III) the colorant (A-4) and the colorant (A-11)
(IV) the colorant (A-4) and the colorant (A-12),
in the colorant (A) in the green pixel,
the content of the colorant (A-4) is 49 weight % to 59 weight %,
the content of the colorant (A-5), the colorant (A-6), the colorant (A-11) or the colorant (A-12) is 33 weight % to 51 weight %, and the content of the colorant (A-7) is 0 weight % to 13 weight %,
a cured product constituting the blue pixel contains a colorant (A-8) Pigment Blue 15:6, a colorant (A-9) Pigment Violet 23, and a colorant (A-10) xanthene dye, and
in the colorant (A) in the blue pixel
the content of the colorant (A-8) is 58 weight % to 64 weight %, the content of the colorant (A-9) is 12 weight % to 20 weight %, and the content of the colorant (A-10) is 17 weight % to 25 weight %.

In one embodiment of the organic EL display device, the content of the compound represented by General Formula (1) with respect to a total amount of the photopolymerizable monomer (B) is 50 weight % or more.

In one embodiment of the organic EL display device, the oxime ester photopolymerization initiator is a compound represented by the following General Formula (2):

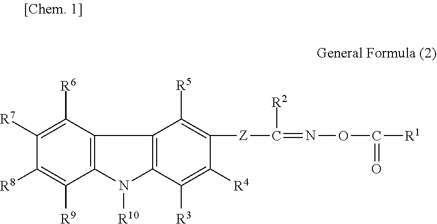

(in General Formula (2), Z represents a direct bond or a —C(═O)— group, R¹ represents an alkyl group which optionally has a substituent and has 1 to 20 carbon atoms, R² represents an alkyl group which optionally has a substituent and has 1 to 20 carbon atoms or an aryl group which optionally has a substituent, R³ to R¹⁰ each independently represent a hydrogen atom, an alkyl group which optionally has a substituent and has 1 to 20 carbon atoms, an aryl group which optionally has a substituent, a nitro group, or an R¹¹—C(═O)— group, and R¹¹ represents an aryl group which optionally has a substituent).

In one embodiment of the organic EL display device, the oxime ester photopolymerization initiator is a compound represented by the following General Formula (3).

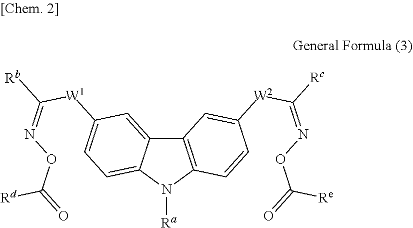

(in General Formula (3), W¹ and W² each independently represent a carbonyl bond (—CO—) or a single bond, and at least one of W¹ and W² is a carbonyl bond (—CO—), and

R^{a} is an alkyl group having 2 to 6 carbon atoms, R^{b} is an alkyl group having 4 to 10 carbon atoms, R^{c} is a group which contains at least a hydrocarbon ring or a heterocycle and may additionally contain at least one divalent linking group selected from among an alkylene chain having 1 to 4 carbon atoms, a thioether bond (—S—), an ether bond (—O—), and a carbonyl bond (—CO—), R^{b} and R^{c} are substituents different from each other, and R^{d} and R^{e} are each independently an alkyl group having 1 to 6 carbon atoms).

In one embodiment of the organic EL display device, the resin (D) includes a photosensitive resin.

In one embodiment of the organic EL display device, the photosensitive resin contains a vinyl polymer having an aromatic carboxylic acid at its terminal.

In one embodiment of the organic EL display device, the photosensitive coloring composition further contains a solvent, and the solvent includes an ether ester solvent and an ether alcohol solvent.

### BRIEF DESCRIPTION OF DRAWINGS

FIGURE is a schematic cross-sectional view of the present organic EL display device.

### DESCRIPTION OF EMBODIMENTS

According to the present disclosure, it is possible to provide an organic EL display device which has high luminance and high color reproducibility and includes a color filter which has favorable pixel adhesion and favorable pixel linearity in a development step even if a concentration of a colorant is high.

Hereinafter, an organic EL display device according to the present disclosure will be described.

Here, in the present disclosure, unless otherwise specified, “to” indicating a numerical value range means that numerical values stated before and after “to” are included as a lower limit value and an upper limit value.

In the present disclosure, the “50% half-value wavelength” represents a wavelength (nm) at which the spectral transmittance is 50% in a wavelength range of 400 nm to 700 nm. The “50% half-value wavelength on the short wavelength side” represents a wavelength (nm) at which the spectral transmittance reaches 50% for the first time when measurement starts from the short wavelength (400 nm) and scanning is performed to the long wavelength, and the “50% half-value wavelength on the long wavelength side” represents a wavelength (nm) at which the spectral transmittance reaches 50% for the first time when measurement starts from the long wavelength (700 nm) and scanning is performed to the short wavelength.

Unless otherwise specified, “acryloyl and/or methacryloyl,” “acryl and/or methacryl,” “acrylic acid and/or methacrylic acid,” “acrylate and/or methacrylate,” and “acrylamide and/or methacrylamide” are referred to as “(meth)acryloyl,” “(meth)acryl,” “(meth)acrylic acid,” “(meth)acrylate,” and “(meth)acryl amide,” respectively. In addition, “C. I.” mentioned in this specification is a color index (C. I.).

The organic EL display device according to the present disclosure (hereinafter referred to as the present organic EL display device) is an organic EL display device including an organic EL layer and a color filter on a silicon substrate on which a driving element is formed,
wherein the color filter has pixels including red pixels, green pixels, and blue pixels,
wherein, when the film thickness of the pixel is 1.5 μm, for the spectral transmittance of the red pixel, the maximum transmittance of light in a wavelength range of 450 nm to 560 nm is 0.5% or less, the 50% half-value wavelength is 593 nm to 603 nm, and the maximum transmittance of light in a wavelength range of 600 nm to 700 nm is 80% or more and less than 100%,
for the spectral transmittance of the green pixel, the maximum transmittance of light in a wavelength range of 400 nm to 470 nm is 2% or less, the maximum transmittance of light at a wavelength of 525 to 535 nm is 67% or more, the 50% half-value wavelength on the short wavelength side is 497 to 507 nm, and the 50% half-value wavelength on the long wavelength side is 554 to 581 nm, and
for the spectral transmittance of the blue pixel, the maximum transmittance of light in a wavelength range of 500 nm to 560 nm is less than 20%,
wherein the pixel is a cured product of a photosensitive coloring composition containing a colorant (A), a photopolymerizable monomer (B), a photopolymerization initiator (C) and a resin (D),
wherein, in the red pixel, the colorant (A) contains Pigment Red 177 and other colorants,
wherein, in the green pixel, the colorant (A) contains Pigment Yellow 185, and one or more selected from the group consisting of Pigment Green 36, Pigment Green 62, Pigment Green 63 and Pigment Green 59, and optionally contains other colorants, and the content of Pigment Yellow 185 in the colorant (A) of the green pixel is 49 weight % to 59 weight %,
wherein the blue pixel contains Pigment Blue 15:6 and other colorants,
wherein, in the red pixel, the other colorants include one or more selected from the group consisting of Pigment Red 254 and Pigment Yellow 139,
wherein, in the green pixel, the other colorants include Pigment Blue 15:3,
wherein, in the blue pixel, the other colorants include one or more selected from the group consisting of Pigment Violet 23 and a xanthene dye,
wherein the photopolymerizable monomer (B) contains a compound represented by the following General Formula (1), and
wherein the photopolymerization initiator (C) contains an oxime ester photopolymerization initiator:

[CH₂═CHC(═O)—(OCₘH₂ₘ)ₙ—OCH₂]₃—CR General Formula (1)

(in General Formula (1), m represents an integer of 1 to 3, n represents an integer of 0 to 2, and a plurality of m and n may be the same as or different from each other, and
R represents a substituent selected from among —CH₂CH₃, —CH₂OH, and —CH₂O(C═O)C═CH₂).

In the present organic EL display device, since the pixel of the color filter is a cured product of the specific photosensitive coloring composition, even if a color filter is formed on the organic EL layer, the effect of heat on the organic EL layer can be reduced, and it is possible to obtain a high-quality organic EL display device having high luminance, high color reproducibility, and excellent pixel linearity.

In addition, in the present organic EL display device, when pixels of the color filter having the specific spectral characteristics are used, the area of the region defined by a color triangle connecting R (red), G (green), and B (blue) in the xy chromaticity diagram is widened and the display device has a wide color reproduction range (that is, high color reproducibility).

Hereinafter, regarding the present organic EL display device, first, a photosensitive coloring composition for pixel formation will be described, and the configuration of the organic EL display device will be then described.

### [Photosensitive Coloring Composition]

Each pixel of the color filter is a cured product of a photosensitive coloring composition containing a colorant (A), a photopolymerizable monomer (B), a photopolymerization initiator (C), and a resin (D). In the photosensitive coloring composition, the photopolymerizable monomer (B) contains at least a compound represented by General Formula (1), and the photopolymerization initiator (C) contains at least an oxime ester photopolymerization initiator. Therefore, pixels having high luminance and high color reproducibility, favorable pixel adhesion in the development step and favorable pixel linearity can be obtained even if the concentration of the colorant is high.

The photosensitive coloring composition contains at least a colorant (A), a photopolymerizable monomer (B), a photopolymerization initiator (C), and a resin (D), and as necessary, may further contain other components. Hereinafter, respective components will be described in detail.

### <Colorant (A)>

The colorant (A) adjusts the tone of pixels of the color filter so that specific spectral characteristics described below are obtained, and one appropriately selected from known pigments and dyes according to the hue of predetermined pixels can be used.

As the pigment, both organic pigments and inorganic pigments can be suitably used. In addition, since the present photosensitive coloring composition has excellent low-temperature curability, even dyes with low heat resistance compared to pigments can be suitably used.

Examples of inorganic pigments include metal oxide powders, metal sulfide powders, and metal powders such as barium sulfate, zinc oxide, lead sulfate, yellow lead, zinc yellow, red oxide (red iron(III) oxide), cadmium red, ultramarine blue, prussian blue, chromium oxide green, cobalt green, amber, titanium black, synthesized iron black, titanium oxide, and triiron tetroxide. Inorganic pigments are preferably used in combination with organic pigments in order to achieve a balance between chroma and brightness and secure favorable coating properties, sensitivity, developability and the like.

As dyes, any of acid dyes, direct dyes, basic dyes, salt-forming dyes, oil-soluble dyes, disperse dyes, reactive dyes, mordant dyes, vat dyes, and sulfur dyes can be used. In addition, the form of lake pigments obtained by converting derivatives thereof or dyes into lakes may be used.

The colorant (A) preferably contains a pigment and more preferably contains an organic pigment because it has high color development, excellent heat resistance, and particularly excellent thermal decomposition resistance.

Hereinafter, the colorant (A) will be described more specifically for each color.

### (Colorant for Red Pixels)

In the present organic EL display device, a combination of C. I. Pigment Red 177 (also referred to as a colorant (A-1)) and other colorants is used as a colorant for red pixels. When Pigment Red 177 and other colorants are combined, the spectral transmittance of the red pixel when the film thickness of the pixel is 1.5 μm is easily adjusted so that the maximum transmittance of light in a wavelength range of 450 nm to 560 nm is 0.5% or less, the 50% half-value wavelength is 593 nm to 603 nm, and the maximum transmittance of light in a wavelength range of 600 nm to 700 nm is 80% or more and less than 100%.

Red pigments, orange pigments, or yellow pigments are preferable as other colorants for the colorant for red pixels. Other colorants may be used alone or two or more thereof may be used in combination.

Specific examples of red pigments include C. I. Pigment Red 1, 2, 3, 4, 5, 6, 7, 8, 9, 12, 14, 15, 16, 17, 21, 22, 23, 31, 32, 37, 38, 41, 47, 48, 48:1, 48:2, 48:3, 48:4, 49, 49:1, 49:2, 50:1, 52:1, 52:2, 53, 53:1, 53:2, 53:3, 57, 57:1, 57:2, 58:4, 60, 63, 63:1, 63:2, 64, 64:1, 68, 69, 81, 81:1, 81:2, 81:3, 81:4, 83, 88, 90:1, 101, 101:1, 104, 108, 108:1, 109, 112, 113, 114, 122, 123, 144, 146, 147, 149, 151, 166, 168, 169, 170, 172, 173, 174, 175, 176, 178, 179, 181, 184, 185, 187, 188, 190, 193, 194, 200, 202, 206, 207, 208, 209, 210, 214, 216, 220, 221, 224, 230, 231, 232, 233, 235, 236, 237, 238, 239, 242, 243, 245, 247, 249, 250, 251, 253, 254, 255, 256, 257, 258, 259, 260, 262, 263, 264, 265, 266, 267, 268, 269, 270, 271, 272, 273, 274, 275, and 276.

Specific examples of orange pigments include C. I. Pigment Orange 36, 38, 43, 51, 55, 59, 61.

Specific examples of yellow pigments include C. I. Pigment Yellow 1, 1:1, 2, 3, 4, 5, 6, 9, 10, 12, 13, 14, 16, 17, 24, 31, 32, 34, 35, 35:1, 36, 36:1, 37, 37:1, 40, 41, 42, 43, 48, 53, 55, 61, 62, 62:1, 63, 65, 73, 74, 75, 81, 83, 87, 93, 94, 95, 97, 100, 101, 104, 105, 108, 109, 110, 111, 116, 117, 119, 120, 126, 127, 127:1, 128, 129, 133, 134, 136, 138, 139, 142, 147, 148, 150, 151, 153, 154, 155, 157, 158, 159, 160, 161, 162, 163, 164, 165, 166, 167, 168, 169, 170, 172, 173, 174, 175, 176, 180, 181, 182, 183, 184, 185, 188, 189, 190, 191, 191:1, 192, 193, 194, 195, 196, 197, 198, 199, 200, 202, 203, 204, 205, 206, 207, 208.

Among other colorants for red pixels, Pigment Red 254 (colorant (A-2)) and Pigment Yellow 139 (colorant (A-3)) are preferable because they allow the spectral transmittance of pixels to be within a predetermined range, and they have high luminance, high color reproducibility, and excellent pixel linearity.

When colorants (A-1), (A-2), and (A-3) are used in combination, in the colorant (A), preferably, the content of the colorant (A-1) is 55 weight % to 65 weight %, the content of the colorant (A-2) is 15 weight % to 25 weight %, and the content of the colorant (A-3) is 15 weight % to 25 weight %.

### (Colorant for Green Pixels)

In the present organic EL display device, the colorant for green pixels which contains C. I. Pigment Yellow 185 (also referred to as a colorant (A-4)) and one or more selected from the group consisting of Pigment Green 36, Pigment Green 62, Pigment Green 63 and Pigment Green 59, and in which the content of Pigment Yellow 185 in the colorant (A) is 49 weight % to 59 weight % is used. When Pigment Yellow 185 in the above proportion is used, the spectral transmittance of the green pixel when the film thickness of the pixel is 1.5 μm is easily adjusted so that the maximum transmittance of light in a wavelength range of 400 nm to 470 nm is 2% or less, the maximum transmittance of light at a wavelength of 525 to 535 nm is 67% or more, the 50% half-value wavelength on the short wavelength side is 497 to 507 nm, and the 50% half-value wavelength on the long wavelength side is 554 to 581 nm.

Green pigments, yellow pigments, or blue pigments are preferable as other colorants for the colorant for green pixels. Other colorants may be used alone or two or more thereof may be used in combination.

Specific examples of green pigments include C. I. Pigment Green 1, 2, 4, 7, 8, 10, 13, 14, 15, 17, 18, 19, 26, 36, 45, 48, 50, 51, 54, 55, 58, 59, 62, 63.

Specific examples of blue pigments include C. I. Pigment Blue 1, 1:2, 9, 14, 15, 15:1, 15:2, 15:3, 15:4, 15:6, 16, 17, 19, 25, 27, 28, 29, 33, 35, 36, 56, 56:1, 60, 61, 61:1, 62, 63, 66, 67, 68, 71, 72, 73, 74, 75, 76, 78, 79.

In addition, specific examples of yellow pigments include those exemplified for the colorant for red pixels.

Among the colorants for green pixels, Pigment Green 36 (colorant (A-5)), Pigment Green 62 (colorant (A-6)), Pigment Green 63 (colorant (A-11)), Pigment Green 59 (colorant (A-12)), and Pigment Blue 15:3 (colorant (A-7)) are preferable because they allow the spectral transmittance of pixels to be within a predetermined range, and they have high luminance, high color reproducibility, and excellent pixel linearity.

As a combination of colorants for green pixels (A), the following combinations (I) to (IV) are more preferable.
(I) colorant (A-4), colorant (A-5) and colorant (A-7)
(II) colorant (A-4) and colorant (A-6)
(III) colorant (A-4) and colorant (A-11)
(IV) colorant (A-4) and colorant (A-12)

When colorants (A-4), (A-5), (A-6), (A-7), (A-11), and (A-12) are used in combination, in the colorant (A), preferably, the content of the colorant (A-4) is 49 weight % to 59 weight %, the content of the colorant (A-5), the colorant (A-6), the colorant (A-11) or the colorant (A-12) is 33 weight % to 51 weight %, and the content of the colorant (A-7) is 0 weight % to 13 weight %, and more preferably, the content of the colorant (A-7) is 3 weight % to 13 weight %.

### (Colorant for Blue Pixels)

In the present organic EL display device, a combination of Pigment Blue 15:6 (also referred to as a colorant (A-8)) and other colorants is used as a colorant for blue pixels. When Pigment Blue 15:6 and other colorants are combined, the spectral transmittance of the blue pixel when the film thickness of the pixel is 1.5 μm is easily adjusted so that the maximum transmittance of light in a wavelength range of 500 nm to 560 nm is less than 20%.

Blue pigments, purple pigments, or xanthene dyes are preferable as other colorants for the colorant for blue pixels. Other colorants may be used alone or two or more thereof may be used in combination.

Specific examples of purple pigments include C. I. Pigment Violet 1, 1:1, 2, 2:2, 3, 3:1, 3:3, 5, 5:1, 14, 15, 16, 19, 23, 25, 27, 29, 31, 32, 37, 39, 42, 44, 47, 49, 50.

Specific examples of blue pigments include those exemplified for the colorant for green pixels.

Xanthene dyes may be in the form of oil-soluble dyes, acid dyes, direct dyes, or basic dyes, and may also be used as lake pigments.

Xanthene basic dyes are preferably used after salt-forming using an organic acid or perchloric acid. As the organic acid, it is preferable to use an organic sulfonic acid or organic carboxylic acid. Among these, naphthalenesulfonic acid such as tobias acid or perchloric acid is preferable in consideration of resistance.

A xanthene acid dye can be used as a salt-forming compound obtained by salt-forming using a quaternary ammonium salt compound, a tertiary amine compound, a secondary amine compound, a primary amine compound or the like or a resin component having these functional groups or can be used as a sulfonic acid amide compound by sulfonamidation. A salt-forming compound of a xanthene acid dye and a sulfonic acid amide compound of a xanthene acid dye are preferable because they have excellent hue and resistance, and furthermore, it is more preferable to use a compound obtained by salt-forming a xanthene acid dye with a quaternary ammonium salt and a sulfonic acid amide compound obtained by sulfonamidation of a xanthene acid dye.

In addition, among xanthene pigments, a rhodamine pigment is preferable because it has excellent color development and resistance.

Specific examples of xanthene oil-soluble dye include C. I. Solvent Red 35, C. I. Solvent Red 36, C. I. Solvent Red 42, C. I. Solvent Red 43, C. I. Solvent Red 44, C. I. Solvent Red 45, C. I. Solvent Red 46, C. I. Solvent Red 47, C. I. Solvent Red 48, C. I. Solvent Red 49, C. I. Solvent Red 72, C. I. Solvent Red 73, C. I. Solvent Red 109, C. I. Solvent Red 140, C. I. Solvent Red 141, C. I. Solvent Red 237, C. I. Solvent Red 246, C. I. Solvent Violet 2, C. I. and Solvent Violet 10.

Among these, C. I. Solvent Red 35, C. I. Solvent Red 36, C. I. Solvent Red 49, C. I. Solvent Red 109, C. I. Solvent Red 237, C. I. Solvent Red 246, and C. I. Solvent Violet 2, which are rhodamine oil-soluble dyes having high color development, are more preferable.

Specific examples of xanthene basic dyes include C. I. Basic Red 1 (Rhodamine 6GCP), 8 (Rhodamine G), and C. I. Basic Violet 10 (Rhodamine B). Among these, C. I. Basic Red 1, and C. I. Basic Violet 10 are preferable because they have excellent color development.

Specific examples of xanthene acid dyes include C. I. Acid Red 51 (Erythrosine (Food Red No. 3)), C. I. Acid Red 52 (Acid Rhodamine), C. I. Acid Red 87 (Eosin G (Food Red 10No. 3)), C. I. Acid Red 92 (Acid Phloxine PB (Food Red No. 104)), C. I. Acid Red 289, C. I. Acid Red 388, Rose Bengal B (Food Red No. 5), Acid Rhodamine G, and C. I. Acid Violet 9.

Among these, in consideration of heat resistance and light resistance, C. I. Acid Red 87, C. I. Acid Red 92, C. I. Acid Red 388, C. I. Acid Red 52 (Acid Rhodamine), C. I. Acid Red 289, Acid Rhodamine G, and C. I. Acid Violet 9 are more preferable, and furthermore, C. I. Acid Red 52, and C. I. Acid Red 289 are preferably used because they have excellent color development, heat resistance, and light resistance.

A xanthene acid dye may be a salt-forming compound with a nitrogen-containing compound, and is preferable because it can be salt-formed using a quaternary ammonium salt compound, a tertiary amine compound, a secondary amine compound, a primary amine compound, or a resin component having these functional groups to form a salt-forming compound of an acid dye and thus it can impart high heat resistance, light resistance, and solvent resistance. Acid dyes can impart high heat resistance, light resistance, and solvent resistance by sulfonamidation.

In addition, a salt-forming compound of an acid dye and a compound having an onium base may be used, and among these, a compound having an onium base is a resin having a cationic group in the side chain, and thus a coloring composition having excellent brightness and resistance can be obtained.

Examples of primary amine compounds include aliphatic unsaturated primary amines such as methylamine, ethylamine, propylamine, isopropylamine, butylamine, amylamine, hexylamine, heptylamine, octylamine, nonylamine, decylamine, undecylamine, dodecylamine (laurylamine), tridodecylamine, tetradecylamine (myristylamine), pentadecylamine, cetylamine, stearylamine, oleylamine, coco-alkylamine, beef tallow alkylamine, curebeef tallow alkylamine, and allylamine, aniline, and benzylamine.

Examples of secondary amine compounds include aliphatic unsaturated secondary amines such as dimethylamine, diethylamine, dipropylamine, diisopropylamine, dibutylamine, diamylamine, and diallylamine, methyl aniline, ethyl aniline, dibenzylamine, diphenylamine, dicoco-alkylamine, di-cured beef tallow alkylamine, and disteallylamine.

Examples of tertiary amine compounds include trimethylamine, triethylamine, tripropylamine, tributylamine, triamylamine, dimethyl aniline, diethyl aniline, and tribenzylamine.

In the case of a xanthene acid dye, it may be used as a salt-forming compound (a) including the acid dye and a quaternary ammonium salt compound. Hereinafter, a quaternary ammonium salt compound as a counter component for an acid dye will be described. The quaternary ammonium salt compound (a) functions as a counter for an acid dye when it has an amino group.

A preferable form of the quaternary ammonium salt compound, which is a counter component for a salt-forming compound, is colorless or white. Here, colorless or white refers to a so-called transparent state, and is defined as a state in which the transmittance is 95% or more, and preferably 98% or more in the entire wavelength range of 400 to 700 nm in the visible light region. That is, it is preferable that it not interfere with color development of a dye component and not cause color change.

The molecular weight of the counter part, which is a cationic component of the quaternary ammonium salt compound, is preferably in a range of 190 to 900. If the molecular weight is less than 190, the light resistance and heat resistance may decrease, and additionally, the solubility in the solvent may decrease. In addition, if the molecular weight is larger than 900, the proportion of the coloring component in the molecule may decrease, color development may deteriorate, and the brightness may also decrease. More preferably, the molecular weight of the counter part is in a range of 240 to 850. Particularly preferably, the molecular weight of the counter part is in a range of 350 to 800. Here, the molecular weight is calculated based on the structural formula, and the atomic weight of C is 12, the atomic weight of H is 1, and the atomic weight of N is 14.

The quaternary ammonium salt compound is preferably a compound represented by the following General Formula (5).

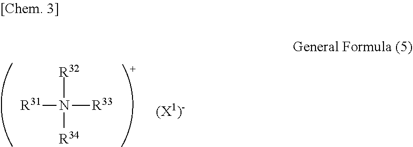

(in General Formula (5), R³¹ to R³⁴ each independently represent an alkyl group having 1 to 20 carbon atoms or a benzyl group, at least two or more of R³¹ to R³⁴ have 5 to 20 carbon atoms, and X¹⁻ represents an inorganic or organic anion).

When at least two or more of R³¹ to R³⁴ have 5 to 20 carbon atoms, the solubility in a solvent becomes favorable. If there are three or more alkyl groups having less than 5 carbon atoms, the solubility in a solvent deteriorates and foreign substances are more likely to occur in the coating. In addition, if there is an alkyl group having more than 20 carbon atoms, color development of the salt-forming compound (a) may be impaired.

X¹⁻ may be an inorganic or organic anion, and is preferably a halogen and preferably a chloride ion (anion).

Examples of quaternary ammonium salt compounds include tetramethylammonium chloride, tetraethylammonium chloride, monostearyltrimethylammonium chloride, distearyldimethylammonium chloride, tristearylmonomethylammonium chloride, cetyltrimethylammonium chloride, trioctylmethylammonium chloride, dioctyldimethylammonium chloride, monolauryltrimethylammonium chloride, dilauryldimethylammonium chloride, trilaurylmethylammonium chloride, triamylbenzylammonium chloride, trihexylbenzylammonium chloride, trioctylbenzylammonium chloride, trilaurylbenzylammonium chloride, benzyldimethylstearylammonium chloride, benzyldimethyloctylammonium chloride, and dialkyl (C14-C18 alkyl) dimethylammonium chloride (cured beef tallow).

Examples of specific quaternary ammonium salt compound products include Quartamin 24P, Quartamin 86P Conc, Quartamin 60W, Quartamin 86W, Quartamin D86P, SANISOL C, SANISOL B-50 and the like (commercially available from Kao Corporation), and Arquad 210-80E, 2C-75, 2HT-75, 2HT flake, 20-751, 2HP-75, 2HP flake and the like (commercially available from Lion Corporation), and among these, Quartamin D86P (distearyl dimethylammonium chloride), Arquad 2HT-75 (dialkyl (C14-C18 alkyl) dimethylammonium chloride) and the like may be exemplified.

### (Resin Having Cationic Group in Side Chain)

In the case of a xanthene acid dye, it may be used as a salt-forming compound (a′) including an acid dye and a resin having a cationic group in the side chain. A resin having a cationic group in the side chain for obtaining the salt-forming compound (a′) will be described.

The resin having a cationic group in the side chain for obtaining a salt-forming compound is not particularly limited as long as it has at least one onium base in the side chain, and suitable onium salt structures are preferably ammonium salts, iodonium salts, sulfonium salts, diazonium salts, and phosphonium salts in consideration of availability and the like, and more preferably ammonium salts, iodonium salts, and sulfonium salts in consideration of storage stability (thermal stability). Ammonium salts are still more preferable.

When a photosensitive coloring composition containing a salt-forming compound (a′) is prepared and properties of a color filter are exhibited, it is preferable to use the same resin as the binder resin constituting the photosensitive coloring composition. When an acrylic resin is used as a binder resin of the photosensitive coloring composition, the resin having a cationic group in the side chain for obtaining a salt-forming compound (a′) is preferably an acrylic resin.

As the resin having a cationic group in the side chain, an alkaline resin containing a structural unit represented by the following General Formula (6) is preferable. A salt-forming compound can be obtained by forming a salt between the cationic group in General Formula (6) and the anionic group in the xanthene acid dye.

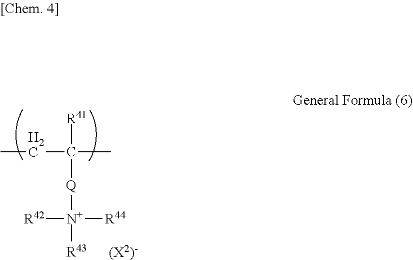

(in General Formula (6), R⁴¹ represents a hydrogen atom or a substituted or unsubstituted alkyl group, R⁴² to R⁴⁴ each independently represent a hydrogen atom, an optionally substituted alkyl group, an optionally substituted alkenyl group, or an optionally substituted aryl group, two of R⁴² to R⁴⁴ may be bonded to each other to form a ring, Q represents an alkylene group, an arylene group, —CONH—R⁴⁵—, or —COO—R⁴⁵—, R⁴⁵ represents an alkylene group, and X²⁻ represents an inorganic or organic anion).

Examples of alkyl groups for R⁴¹ include a methyl group, ethyl group, propyl group, n-butyl group, i-butyl group, t-butyl group, n-hexyl group, and cyclohexyl group. The alkyl group is preferably an alkyl group having 1 to 12 carbon atoms, more preferably an alkyl group having 1 to 8 carbon atoms, and particularly preferably an alkyl group having 1 to 4 carbon atoms.

When the alkyl group represented by R⁴¹ has a substituent, as the substituent, for example, a hydroxyl group and an alkoxyl group may be exemplified.

Among the above examples, R⁴¹ is most preferably a hydrogen atom or a methyl group.

Examples of alkyl groups for R⁴² to R⁴⁴ include linear alkyl groups (methyl, ethyl, n-propyl, n-butyl, n-pentyl, n-octyl, n-decyl, n-dodecyl, n-tetradecyl, n-hexadecyl and n-octadecyl, etc.), branched alkyl groups (isopropyl, isobutyl, sec-butyl, tert-butyl, isopentyl, neopentyl, tert-pentyl, isohexyl, 2-ethylhexyl and 1,1,3,3-tetramethylbutyl, etc.), cycloalkyl groups (cyclopropyl, cyclobutyl, cyclopentyl and cyclohexyl, etc.) and crosslinked cyclic alkyl groups (norbornyl, adamantly and pinanyl, etc.). The alkyl group is preferably an alkyl group having 1 to 18 carbon atoms and more preferably an alkyl group having 1 to 8 carbon atoms.

Examples of alkenyl groups for R⁴² to R⁴⁴ include linear or branched alkenyl groups (vinyl, allyl, 1-propenyl, 2-propenyl, 1-butenyl, 2-butenyl, 3-butenyl, 1-methyl-1-propenyl, 1-methyl-2-propenyl, 2-methyl-1-propenyl and 2-methyl-2-propenyl, etc.), and cycloalkenyl groups (2-cyclohexenyl and 3-cyclohexenyl, etc.). The alkenyl group is preferably an alkenyl group having 2 to 18 carbon atoms and more preferably an alkenyl group having 2 to 8 carbon atoms.

Examples of aryl groups for R⁴² to R⁴⁴ include monocyclic aryl groups (phenyl, etc.), condensed polycyclic aryl groups (naphthyl, anthracenyl, phenanthrenyl, anthraquinonyl, fluorenyl, naphthoquinonyl, etc.), aromatic heterocyclic hydrocarbon groups (thienyl (group derived from thiophene), furyl (group derived from furan), pyranyl (group derived from pyrane), pyridyl (group derived from pyridine), 9-oxoxanthenyl (group derived from xanthone) and 9-oxothioxanthenyl (group derived from thioxanthone), etc.).

When the alkyl group, alkenyl group, or aryl group represented by R⁴² to R⁴⁴ has a substituent, as the substituent, for example, a substituent selected from among a halogen atom, hydroxyl group, alkoxyl group, aryloxy group, alkenyl group, acyl group, alkoxycarbonyl group, carboxyl group, and phenyl group may be exemplified. Among the substituents, a halogen atom, hydroxyl group, alkoxyl group, or phenyl group is particularly preferable.

In consideration of stability, R⁴² to R⁴⁴ are preferably an optionally substituted alkyl group and more preferably an unsubstituted alkyl group.

In addition, two of R⁴² to R⁴⁴ may be bonded to each other to form a ring.

In General Formula (6), the component of Q that links the vinyl moiety and the ammonium base represents an alkylene group, arylene group, —CONH—R⁴⁵—, or —COO—R⁴⁵—, R⁴⁵ represents an alkylene group, and among these, —CONH—R⁴⁵— and —COO—R⁴⁵— are preferable in consideration of polymerizability and availability. In addition, R⁴⁵ is more preferably a methylene group, ethylene group, propylene group, or butylene group, and particularly preferably an ethylene group.

The component of X²⁻ in General Formula (6), which constitutes a counter anion of the resin, may be an inorganic or organic anion. As the counter anion, any known anion can be used without limitation, and specific examples thereof include hydroxide ions; halogen ions such as chloride ions, bromide ions, and iodide ions; carboxylic acid ions such as formate ions and acetate ions; and carbonate ions, bicarbonate ions, nitrate ions, sulfate ions, sulfite ions, chromate ions, dichromate ions, phosphate ions, cyanide ions, permanganate ions, and complex ions such as hexacyanoferrate(III) ions. In consideration of suitability for synthesis and stability, halogen ions and carboxylic acid ions are preferable, and halogen ions are most preferable. When the counter anions are organic acid ions such as carboxylic acid ions, the organic acid ions in the resin may be covalently bonded to form an inner salt.

One method of introducing an oxetane group into a resin having a cationic group in the side chain is a method of copolymerizing an ethylenically unsaturated monomer containing an oxetane structure with an ethylenically unsaturated monomer corresponding to a cationic group represented by General Formula (6). Examples of ethylenically unsaturated monomers having an oxetane group include (3-methyl-3-oxetanyl)methyl (meth)acrylate, (3-ethyl-3-oxetanyl)methyl (meth)acrylate, (3-butyl-3-oxetanyl)methyl (meth)acrylate, and (3-hexylethyl-3-oxetanyl)methyl (meth)acrylate. Examples of commercial products include ETERNACOLL OXMA (commercially available from Ube Industries, Ltd.), and OXE-10 and OXE-30 (all commercially available from Osaka Organic Chemical Industry Ltd.).

### (Salt Formation)

A salt-forming compound of an acid dye and a nitrogen-containing compound or a resin having a cationic group in the side chain can be produced by a conventionally known method. A specific method is disclosed in Japanese Patent Laid-Open No. H11-72969. As an example using a xanthene acid dye, a xanthene acid dye is dissolved in water and a quaternary ammonium salt compound is then added, and a salt-forming treatment may be performed with stirring. Here, a salt-forming compound in which moieties of a sulfonic acidic group (—SO₃H) and a sodium sulfonate group (—SO₃Na) in the xanthene acid dye and moieties of an ammonium group (NH₄⁺) of a quaternary ammonium salt compound are bonded is obtained. In addition, in place of water, methanol and ethanol are solvents that also can be used during salt-forming.

In addition, the salt-forming compound can be easily obtained by stirring or vibrating an aqueous solution in which a resin having a cationic group in the side chain represented by General Formula (6) and an acid dye are dissolved or by mixing an aqueous solution containing a resin having a cationic group in the side chain represented by General Formula (6) and an aqueous solution containing an acid dye under stirring or vibrating. In an aqueous solution, the ammonium group of the resin and the anionic group of the acid dye are ionized, and they form an ionic bond, and the ionic bond moiety becomes water-insoluble and precipitates. On the other hand, since a salt composed of counter anions of the resin and counter cations of the acid dye is water-soluble, it can be removed by washing with water or the like. The resin having a cationic group in the side chain and the acid dye used may be of a single type or may be a plurality of types having different structures.

In addition, a salt-forming compound can be obtained using a nitrogen-containing compound or a resin having a cationic group in the side chain with other acid dyes in the same method as for xanthene dyes.

### (Sulfonic Acid Amide Compound)

The acid dye may be a sulfonic acid amide compound obtained by reacting a sulfonic acid amide compound with an anionic dye.

A sulfonic acid amide compound of an acid dye that can be preferably used for an acid dye can be produced by chlorinating an acid dye having —SO₃H and —SO₃Na by a general method, converting —SO₃H into —SO₂Cl, and reacting this compound with an amine having a —NH₂ group.

In addition, as an amine compound that can be preferably used in sulfonamidation, specifically, 2-ethylhexylamine, dodecylamine, 3-decyloxypropylamine, 3-(2-ethylhexyloxy)propylamine, 3-ethoxypropylamine, cyclohexylamine or the like is preferably used.

As an example using an xanthene acid dye, in order to obtain a sulfonic acid amide compound obtained by modifying C. I. Acid Red 289 using 3-(2-ethylhexyloxy)propylamine, C. I. Acid Red 289 is subjected to sulfonyl chloridation, and then reacted with the theoretical equivalent of 3-(2-ethylhexyloxy)propylamine in dioxane, and thereby a sulfonic acid amide compound of C. I. Acid Red 289 may be obtained.

In addition, in order to obtain a sulfonic acid amide compound obtained by modifying C. I. Acid Red 52 using 3-(2-ethylhexyloxy)propylamine, C. I. Acid Red 52 is subjected to sulfonyl chloridation, and then reacted with the theoretical equivalent of 3-(2-ethylhexyloxy)propylamine in dioxane, and thereby a sulfonic acid amide compound of C. I. Acid Red 52 may be obtained.

Among other colorants for blue pixels, Pigment Violet 23 (colorant (A-9)) or a xanthene dye (colorant (A-10)) is preferable because it allows the spectral transmittance of pixels to be within a predetermined range, has high luminance, high color reproducibility, and excellent pixel linearity.

When the colorants (A-8), (A-9), and (A-10) are used in combination, in the colorant (A), preferably, the content of the colorant (A-8) is 58 weight % to 64 weight %, the content of the colorant (A-9) is 12 weight % to 20 weight %, and the content of the colorant (A-10) is 17 weight % to 25 weight %.

In the case of using a pigment together with colorants for the colors, it is preferable to make the pigment finer. The method for refining the pigment can be appropriately selected from among known methods, and examples thereof include wet grinding, dry grinding, and dissolution precipitation methods, and a salt milling treatment can be performed by a kneader method, which is a type of wet grinding.

The salt milling treatment is a treatment in which a mixture containing a pigment, a water-soluble inorganic salt and a water-soluble organic solvent is mechanically kneaded using a kneading machine such as a kneader, a 2-roll mill, a 3-roll mill, a ball mill, an attritor, and a sand mill while heating and the water-soluble inorganic salt and the water-soluble organic solvent are then removed by washing with water. The water-soluble inorganic salt functions as a crushing aid, and the pigment is crushed using the high hardness of the inorganic salt during salt milling. By optimizing conditions for the salt milling treatment of the pigment, it is possible to obtain a pigment having a very fine primary particle size, a narrow distribution width, and a sharp particle size distribution.

As the water-soluble inorganic salt, sodium chloride, barium chloride, potassium chloride, sodium sulfate or the like can be used, but sodium chloride (salt) is preferably used in consideration of cost. The amount of the water-soluble inorganic salt used with respect to 100 parts by mass of the pigment is preferably 50 to 2,000 parts by mass and most preferably 300 to 1,000 parts by mass in consideration of both treatment efficiency and production efficiency.

The water-soluble organic solvent has a function of moistening the pigment and the water-soluble inorganic salt, and is not particularly limited as long as it dissolves in (is miscible with) water, and does not substantially dissolve the inorganic salt used. However, since the temperature rises during salt milling and the solvent easily evaporates, a high-boiling-point solvent having a boiling point of 120° C. or higher is preferable in consideration of safety. For example, 2-methoxyethanol, 2-butoxyethanol, 2-(isopentyloxy)ethanol, 2-(hexyloxy)ethanol, diethylene glycol, diethylene glycol monoethyl ether, diethylene glycol monobutyl ether, triethylene glycol, triethylene glycol monomethyl ether, liquid polyethylene glycol, 1-methoxy-2-propanol, 1-ethoxy-2-propanol, dipropylene glycol, dipropylene glycol monomethyl ether, dipropylene glycol monoethyl ether, liquid polypropylene glycol and the like are used. The amount of the water-soluble organic solvent used with respect to 100 parts by mass of the pigment is preferably 5 to 1,000 parts by mass and most preferably 50 to 500 parts by mass.

When the pigment is subjected to a salt milling treatment, as necessary, a resin may be added. The type of the resin used is not particularly limited, and natural resins, modified natural resins, synthetic resins, synthetic resins modified with natural resins and the like can be used. The resin used is preferably a solid at room temperature and water-insoluble, and more preferably partially soluble in the organic solvent. The amount of the resin used with respect to 100 parts by mass of the pigment is preferably in a range of 5 to 200 parts by mass.

The primary particle size of the pigment is preferably 20 nm or more because it is favorably dispersed in the carrier. In addition, the primary particle size is preferably 100 nm or less because a color filter having a high contrast ratio can be formed. A particularly preferable range is a range of 25 to 85 nm. Here, the primary particle size of the pigment is determined by a method of directly measuring the primary particle size from an electron microscope image of the pigment under a transmission electron microscope (TEM). Specifically, the short axis diameter and the long axis diameter of primary particles of each pigment are measured, and an average thereof is used as the particle size of the pigment particles. Next, for 100 or more pigment particles, the volumes of the particles are obtained by approximating them to the cube with the determined particle sizes, and the volume average particle size is used as the average primary particle size.

### <Photopolymerizable Monomer (B)>

The photopolymerizable monomer (B) contains at least a compound represented by the following General Formula (1), and may further contain other photopolymerizable monomers as necessary.

[CH₂═CHC(═O)—(OCₘH₂ₘ)ₙ—OCH₂]₃—CR General Formula (1)

(in General Formula (1), m represents an integer of 1 to 3, n represents an integer of 0 to 2, and a plurality of m and n may be the same as or different from each other, and
R represents a substituent selected from among —CH₂CH₃, —CH₂OH, and —CH₂O(C═O)C═CH₂).

When a compound represented by General Formula (1) is used, it is possible to achieve both adhesion to a base material and the resolution of the resist pattern.

Specific examples of compounds represented by General Formula (1) include trimethylolpropane triacrylate, trimethylolpropane EO-modified triacrylate, trimethylolpropane PO-modified triacrylate, pentaerythritol triacrylate, and pentaerythritol tetraacrylate.

The compounds represented by General Formula (1) may be used alone or two or more thereof may be used in combination.

In addition, examples of other photopolymerizable monomers include known (meth)acrylate monomers. Specific examples thereof include various acrylic acid esters and methacrylic acid esters such as methyl (meth)acrylate, ethyl (meth)acrylate, 2-hydroxyethyl (meth)acrylate, 2-hydroxypropyl (meth)acrylate, cyclohexyl (meth)acrylate, β-carboxyethyl (meth)acrylate, polyethylene glycol di(meth)acrylate, 1,6-hexanediol di(meth)acrylate, triethylene glycol di(meth)acrylate, tripropylene glycol di(meth)acrylate, pentaerythritol tri(meth)acrylate, pentaerythritol tetra(meth)acrylate, 1,6-hexanediol diglycidyl ether di(meth)acrylate, bisphenol A diglycidyl ether di(meth)acrylate, neopentyl glycol diglycidyl ether di(meth)acrylate, dipentaerythritol hexa(meth)acrylate, dipentaerythritol penta(meth)acrylate, tricyclodecanyl (meth)acrylate, ester acrylate, (meth)acrylic acid ester of methylolated melamine, and epoxy (meth)acrylate, (meth)acrylic acid, styrene, vinyl acetate, hydroxyethyl vinyl ether, ethylene glycol divinyl ether, pentaerythritol trivinyl ether, (meth)acrylamide, N-hydroxymethyl (meth)acrylamide, N-vinylformamide, and acrylonitrile, but the present disclosure is not limited thereto.

Other photopolymerizable compounds may be used alone or two or more thereof may be used in combination.

The content of the photopolymerizable monomer (B) with respect to a total solid content of the photosensitive coloring composition is preferably 5 to 40 mass %. Within the above range, it is possible to prevent peeling when a fine pattern is formed and elongation of a tapered part of the pattern, and it is possible to form a high-definition fine pixel pattern. In addition, the content of the compound represented by General Formula (1), which is contained in the photopolymerizable monomer (B), with respect to a total amount of the photopolymerizable monomer (B) is preferably 50 to 100 mass % and more preferably 60 mass % or more. Within the above range, coating adhesion and chemical resistance to the substrate during development are excellent.

### <Photopolymerization Initiator (C)>

In the present organic EL display device, the photopolymerization initiator (C) contains an oxime ester photopolymerization initiator, and as necessary, may further contain other photopolymerization initiators. The photosensitive coloring composition containing the oxime ester photopolymerization initiator may be a photosensitive coloring composition having UV irradiation curability and solvent developability or alkali developability. Therefore, according to the photosensitive coloring composition, pixels can be formed by a photolithographic method. In addition, when the oxime ester photopolymerization initiator is used, a photosensitive coloring composition having excellent color properties and chemical resistance and favorable patterning properties is obtained.

The oxime ester photopolymerization initiator generates imidyl radicals and alkyloxy radicals upon cleaving N—O bonds of oximes by absorbing ultraviolet rays. These radicals are additionally decomposed to generate highly active radicals and thus patterns can be formed with a small amount of exposure. When the concentration of the colorant of the photosensitive coloring composition is high, the UV transmittance of the coating may be low and the degree of curing of the coating may be low. Since the present photosensitive coloring composition contains an oxime ester photopolymerization initiator having high quantum efficiency, it has excellent curability even when the concentration of the colorant is high.

Examples of oxime ester photopolymerization initiators include oxime ester photopolymerization initiators represented by the following General Formulae (2) to (4), and among these, an oxime ester photopolymerization initiator represented by the following General Formula (2) or (3) is preferable and an oxime ester photopolymerization initiator represented by General Formula (2) is more preferable.

(Oxime ester photopolymerization initiator represented by General Formula (2))

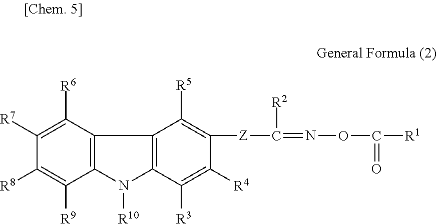

(in General Formula (2), Z represents a direct bond or a —C(═O)— group, R¹ represents an alkyl group which optionally has a substituent and has 1 to 20 carbon atoms, R² represents an alkyl group which optionally has a substituent and has 1 to 20 carbon atoms or an aryl group which optionally has a substituent, R³ to R¹⁰ each independently represent a hydrogen atom, an alkyl group which optionally has a substituent and has 1 to 20 carbon atoms, an aryl group which optionally has a substituent, a nitro group, or an R¹¹—C(═O)— group, and R¹¹ represents an aryl group which optionally has a substituent).

Examples of alkyl group having 1 to 20 carbon atoms for R¹ to R¹⁰ include linear alkyl groups such as a methyl group, ethyl group, propyl group, butyl group, hexyl group, octyl group, and dodecyl group.

Examples of aryl groups for R² to R¹¹ include a phenyl group, naphthyl group, and anthracenyl group.

Here, the fact that Z represents a direct bond means that Z has no atom and two atoms that are connected to Z in General Formula (2) are directly bonded.

The substituent that the alkyl group and the aryl group may have means that the alkyl group or the aryl group may have a substituent in place of a hydrogen atom. Examples of substituents include halogen atoms such as a fluorine atom, chlorine atom, bromine atom, and iodine atom; alkoxy groups such as a methoxy group, ethoxy group, and tert-butoxy group; aryloxy groups such as a phenoxy group and p-tolyloxy group; alkoxycarbonyl groups such as a methoxycarbonyl group, butoxycarbonyl group, and phenoxycarbonyl group; acyloxy groups such as an acetoxy group, propionyloxy group, and benzoyloxy group; acyl groups such as an acetyl group, benzoyl group, isobutyryl group, acryloyl group, methacryloyl group, and methoxalyl group; alkylsulfanyl groups such as a methylsulfanyl group and tert-butylsulfanyl group; arylsulfanyl groups such as a phenylsulfanyl group, and p-tolylsulfanyl group; alkylamino groups such as a methylamino group and cyclohexylamino group; dialkyl amino groups such as a dimethylamino group, diethylamino group, morpholino group, and piperidino group; arylamino groups such as a phenylamino group and p-tolylamino group; alkyl groups such as a methyl group, ethyl group, tert-butyl group, dodecyl group, cyclopropyl group, cyclobutyl group, cyclopentyl group, cyclohexyl group, cycloheptyl group, cyclooctyl group, and cyclooctadecyl group; aryl groups such as a phenyl group, p-tolyl group, xylyl group, cumenyl group, naphthyl group, anthryl group, and phenanthryl group; and heterocyclic groups such as a furyl group and thienyl group, and also a hydroxy group, carboxy group, formyl group, mercapto group, sulfo group, mesyl group, p-toluenesulfonyl group, amino group, nitro group, cyano group, trifluoromethyl group, trichloromethyl group, trimethylsilyl group, phosphinyl group, phosphono group, trimethylammoniumyl group, dimethylsulfoniumyl group, and triphenylphenacylphosfoniumyl group.

In addition, one or more of these substituents or one or more types thereof can be used, and hydrogen atoms of these substituents are additionally optionally substituted with other substituents.

Among these, in the oxime ester photopolymerization initiator represented by General Formula (2), preferably, Z is a direct bond or —C(═O)— group, R¹ is an alkyl group which optionally has a substituent and has 1 to 20 carbon atoms, R² is an alkyl group which optionally has a substituent and has 1 to 20 carbon atoms or an aryl group which optionally has a substituent, and R³ to R¹⁰ are each independently a hydrogen atom, an alkyl group which optionally has a substituent and has 1 to 20 carbon atoms, an aryl group which optionally has a substituent, a nitro group, or an R¹¹—CO— group. Among these, more preferably, R⁴ to R⁶ and R⁸ to R¹⁰ are a hydrogen atom, R⁷ is a hydrogen atom or an R¹¹—CO— group, and R¹¹ is an aryl group which optionally has a substituent.

Among the oxime ester photopolymerization initiators represented by General Formula (2), a compound represented by the following Chemical Formula (2-1) or (2-2) is preferable.

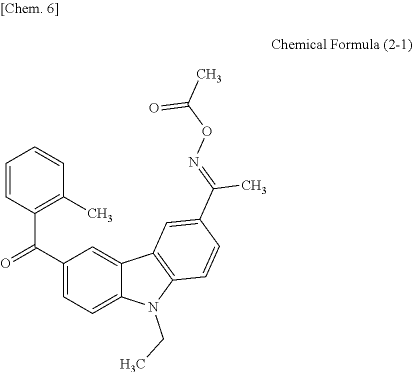

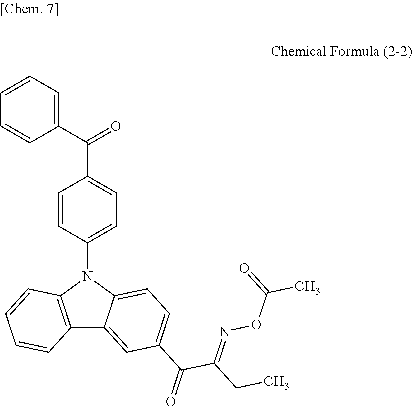

### (Oxime Ester Photopolymerization Initiator Represented by General Formula (3))

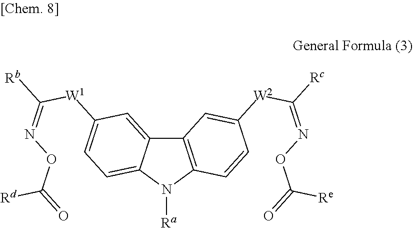

(in General Formula (3), W¹ and W² each independently represent a carbonyl bond (—CO—) or a single bond, and at least one of W¹ and W² is a carbonyl bond (—CO—), and

R^{a} is an alkyl group having 2 to 6 carbon atoms, R^{b} is an alkyl group having 4 to 10 carbon atoms, R^{c} is a group which contains at least a hydrocarbon ring or a heterocycle and may additionally contain at least one divalent linking group selected from among an alkylene chain having 1 to 4 carbon atoms, a thioether bond (—S—), and ether bond (—O—), and a carbonyl bond (—CO—), R^{b} and R^{c} are substituents different from each other, and R^{d} and R^{e} are each independently an alkyl group having 1 to 6 carbon atoms).

Examples of alkyl groups for R^{a} include linear alkyl groups such as an ethyl group, propyl group, butyl group, and hexyl group.

Examples of alkyl groups for R^{b} include linear alkyl groups such as a butyl group, hexyl group, octyl group, and dodecyl group.

Examples of hydrocarbon rings for R^{c} include aliphatic hydrocarbon rings such as a cyclohexyl group and aromatic hydrocarbon rings such as a phenyl group, naphthyl group, and anthracenyl group. In addition, examples of heterocycles for R^{c} include rings in which one, two or more carbon atoms of the hydrocarbon ring are substituted with a nitrogen atom, an oxygen atom, or a sulfur atom.

In addition, examples of alkyl groups for R^{d} and R^{e} include linear alkyl groups such as a methyl group, ethyl group, propyl group, butyl group, and hexyl group.

Among the oxime ester photopolymerization initiators represented by General Formula (3), a compound represented by the following Chemical Formula (3-1) is preferable.

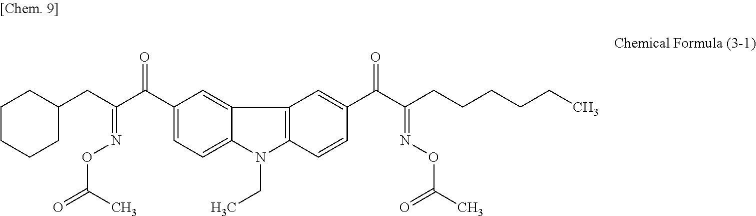

### (Oxime Ester Photopolymerization Initiator Represented by General Formula (4))

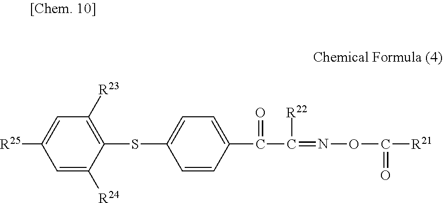

(in General Formula (4), R²¹ and R²² are each independently a hydrogen atom, an alkyl group which optionally has a substituent and has 1 to 20 carbon atoms, or an aryl group which optionally has a substituent, R²³ and R²⁴ are each independently a hydrogen atom, an alkyl group which optionally has a substituent and has 1 to 20 carbon atoms, or an aryl group which optionally has a substituent, R²⁵ is a hydrogen atom, an alkyl group which optionally has a substituent and has 1 to 20 carbon atoms, an aryl group which optionally has a substituent, or an R²⁶—CO— group, and R²⁶ is an alkyl group which optionally has a substituent and has 1 to 20 carbon atoms, an aryl group which optionally has a substituent or a heterocyclic group).

Aalkyl groups having 1 to 20 carbon atoms for R²¹ to R²⁶ may be the same as the alkyl groups having 1 to 20 carbon atoms for R¹ to R¹⁰.

Aryl groups for R²¹ to R²⁶ may be the same as the aryl groups for R² to R¹¹.

Examples of heterocycles in heterocyclic groups for R²⁶ include furan, thiophene, pyrrole, oxazole, thiazole, imidazole, pyrazole, pyrane, pyrone, pyridine, pyridazine, pyrimidine, pyrazine, benzofuran, thionaphthene, indole, carbazole, coumarin, quinoline, phthalazine, and quinoxaline.

In addition, substituents that an alkyl group and an aryl group optionally have may be the same as the substituents in General Formula (2).

In the oxime ester photopolymerization initiator represented by General Formula (4), preferably, R²¹ is an aryl group which optionally has a substituent, R²² is an alkyl group which optionally has a substituent and has 1 to 20 carbon atoms, R²³ and R²⁴ are a hydrogen atom, and R²⁵ is a hydrogen atom or R²⁶—CO— group.

Among the oxime ester photopolymerization initiators represented by General Formula (4), a compound represented by the following Chemical Formula (4-1) is preferable.

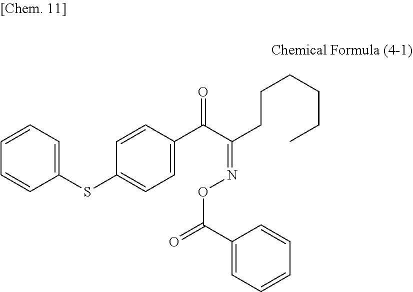

### (Other Photopolymerization Initiator)

In addition, the photopolymerization initiator (C) may further other photopolymerization initiators. Examples of other photopolymerization initiators include acetophenone compounds such as 4-phenoxydichloroacetophenone, 4-t-butyl-dichloroacetophenone, diethoxyacetophenone, 1-(4-isopropylphenyl)-2-hydroxy-2-methylpropan-1-one, 1-hydroxycyclohexylphenyl ketone, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, and 2-benzyl-2-dimethylamino-1-(4-morpholinophenyl)-butan-1-one; benzoin compounds such as benzoin, benzoin methyl ether, benzoin ethyl ether, benzoin isopropyl ether, and benzyl dimethyl ketal; benzophenone compounds such as benzophenone, benzoylbenzoic acid, methyl benzoylbenzoate, 4-phenylbenzophenone, hydroxybenzophenone, acrylated benzophenone, 4-benzoyl-4′-methyldiphenyl sulfide, and 3,3′,4,4′-tetra(t-butylperoxycarbonyl)benzophenone; thioxanthone compounds such as thioxanthone, 2-chlorothioxanthone, 2-methylthioxanthone, isopropylthioxanthone, 2,4-diisopropylthioxanthone, and 2,4-diethylthioxanthone; triazine compounds such as 2,4,6-trichloro-s-triazine, 2-phenyl-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-piperonyl-4,6-bis(trichloromethyl)-s-triazine, 2,4-bis(trichloromethyl)-6-styryl-s-triazine, 2-(naphth-1-yl)-4,6-bis(trichloromethyl)-s-triazine, 2-(4-methoxy-naphth-1-yl)-4,6-bis(trichloromethyl)-s-triazine, 2,4-trichloromethyl-(piperonyl)-6-triazine, and 2,4-trichloromethyl-(4′-methoxystyryl)-6-triazine; phosphine compounds such as bis(2,4,6-trimethylbenzoyl)phenylphosphine oxide, and 2,4,6-trimethylbenzoyl diphenylphosphine oxide; quinone compounds such as 9,10-phenanthrenequinone, camphorquinone, and ethylanthraquinone; borate compounds; carbazole compounds; imidazole compounds; and titanocene compounds.

These photopolymerization initiators may be used alone or as necessary, a mixture of two or more types thereof at any ratio may be used.

Examples of commercial products of photopolymerization initiators include, as acetophenone compounds, “IRGACURE 907” (2-methyl-1-[4-(methylthio)phenyl]-2-morpholinopropan-1-one), “IRGACURE 369” (2-(dimethylamino)-2-[(4-methylphenyl)methyl]-1-[4-(4-morpholinyl)phenyl]-1-butanone), and “IRGACURE 379″2-benzyl-2-dimethylamino-1-(4-morpholinophenyl)-butan-1-one (all commercially available from BASF Japan Ltd.), and as phosphine compounds, “IRGACURE 819”(bis(2,4,6-trimethylbenzoyl)phenylphosphine oxide), and “IRGACURE TPO” (2,4,6-trimethylbenzoyl diphenylphosphine oxide) (all commercially available from BASF Japan Ltd.).

The content of the photopolymerization initiator (C) with respect to 100 parts by mass of the colorant (A) is preferably 0.5 to 50 parts by mass, and in consideration of photocurability and developability, more preferably 1 to 30 parts by mass. When the content of the photopolymerization initiator (C) is 1 part by mass or more, adhesion to the base material is excellent. In addition, when the content of the photopolymerization initiator (C) is 30 parts by mass or less, the resolution is excellent.

### [Sensitizer]

The photosensitive coloring composition may further contain a sensitizer.

Examples of sensitizers include unsaturated ketones such as chalcone derivatives and dibenzoylacetone; 1,2-diketone derivatives such as benzyl and camphorquinone; polymethine pigments such as benzoin derivatives, fluorene derivatives, naphthoquinone derivatives, anthraquinone derivatives, xanthene derivatives, thioxanthene derivatives, xanthone derivatives, thioxanthone derivatives, coumarin derivatives, ketocoumarin derivatives, cyanine derivatives, merocyanine derivatives, and oxonol derivatives; and acridine derivatives, azine derivatives, thiazine derivatives, oxazine derivatives, indoline derivatives, azulene derivatives, azulenium derivatives, squarylium derivatives, porphyrin derivatives, tetraphenylporphyrin derivatives, triarylmethane derivatives, tetrabenzoporphyrin derivatives, tetrapyrazinoporphyrazine derivatives, phthalocyanine derivatives, tetraazaporphyrazine derivatives, tetraquinoxalyloporphyrazine derivatives, naphthalocyanine derivatives, subphthalocyanine derivatives, pyrylium derivatives, thiopyrylium derivatives, tetraphylline derivatives, annulene derivatives, spiropyrane derivatives, spirooxazine derivatives, thiospiropyrane derivatives, metal arene complexes, organic ruthenium complexes, Michler's ketone derivatives, α-acyloxyester, acylphosphine oxide, methylphenyl glyoxylate, 9,10-phenanthrenequinone, ethyl anthraquinone, 4,4′-diethyl isophthalophenone, 3,3′ or 4,4′-tetra(t-butylperoxycarbonyl)benzophenone, and 4,4′-bis(diethylamino)benzophenone.

Among the above sensitizers, examples of sensitizers capable of particularly suitable sensitizing include thioxanthone derivatives, Michler's ketone derivatives, and carbazole derivatives. More specific examples thereof include 2,4-diethylthioxanthone, 2-chlorothioxanthone, 2,4-dichlorothioxanthone, 2-isopropylthioxanthone, 4-isopropylthioxanthone, 1-chloro-4-propoxythioxanthone, 4,4′-bis(dimethylamino)benzophenone, 4,4′-bis(diethylamino)benzophenone, 4,4′-bis(ethylmethylamino)benzophenone, N-ethylcarbazole, 3-benzoyl-N-ethylcarbazole, and 3,6-dibenzoyl-N-ethylcarbazole.

In addition, examples of commercial products of sensitizers include “KAYACURE DETX-S” (2,3-diethylthioxanthone commercially available from Nippon Kayaku Co., Ltd.), and “EAB-F” (4,4′-bis(diethylamino)benzophenone, commercially available from Hodogaya Chemical Co., Ltd.).

In addition, a sensitizer that absorbs light in the UV to near-infrared region can be contained.

The sensitizers may be used alone or as necessary, a mixture of two or more types thereof at any ratio may be used.

The content of the sensitizer used with respect to 100 parts by mass of the photopolymerization initiator (C) contained in the coloring composition is preferably 3 to 60 parts by mass and in consideration of photocurability and developability, more preferably 5 to 50 parts by mass.

### <Resin (D)>

The present photosensitive coloring composition contains a resin (D). As the resin (D), a transparent resin that exhibits a transmittance of 80% or more in the entire wavelength range of 400 to 700 nm when a film having a thickness of 2 μm is formed is preferable, and the transmittance is preferably 95% or more. The resin (D) is preferably one or more selected from among thermoplastic resins and photosensitive resins. In addition, the alkali-soluble resin (D) is preferable. Therefore, a film formed from the photosensitive coloring composition can be patterned by a photolithographic method. Alkali-insoluble photosensitive resins and alkali-soluble resins may have a thermosetting group. Examples of thermosetting groups include an epoxy group and an oxetanyl group.

The resins (D) may be used alone or two or more thereof may be used in combination. The content of the resin (D) with respect to 100 parts by mass of the colorant (A) is preferably 20 to 400 parts by mass and more preferably 50 to 250 parts by mass. When an appropriate amount is contained, a film can be easily formed and favorable color properties can be easily obtained.

Examples of alkali-soluble resins include resins having an acidic group such as a carboxyl group and a sulfone group. Examples of alkali-soluble thermoplastic resins include acrylic resins having an acidic group, α-olefin/(anhydrous) maleic acid copolymers, styrene/styrene sulfonic acid copolymers, ethylene/(meth)acrylic acid copolymers, and isobutylene/(anhydrous) maleic acid copolymers. Among these, acrylic resins having an acidic group and styrene/styrene sulfonic acid copolymers are preferable in order to improve the developability, heat resistance, and transparency.

### (Thermoplastic Resin)

The thermoplastic resin may include alkali-insoluble resins. Examples of alkali-insoluble thermoplastic resins include acrylic resins, butyral resins, styrene-maleic acid copolymers, chlorinated polyethylene, chlorinated polypropylene, polyvinyl chloride, vinyl chloride-vinyl acetate copolymers, polyvinyl acetate, polyurethane resins, polyester resins, vinyl resins, alkyd resins, polystyrene resins, polyamide resins, rubber resins, cyclized rubber resins, celluloses, polyethylene (HDPE, LDPE), polybutadiene, and polyimide resins.

### <Alkali-Soluble Photosensitive Resin>

The alkali-soluble photosensitive resin has photosensitivity because it has a polymerizable unsaturated group. The alkali-soluble photosensitive resin is alkali-soluble and may have photosensitivity, and known resins can be used, and resins synthesized by the following methods (i) and (ii) are preferable. When an alkali-soluble photosensitive resin is used, light emission causes three-dimensional crosslinking to increase the crosslinking density and thus the chemical resistance of the film is improved.

[Method (i)]

In the method (i), for example, first, a polymer of an epoxy group-containing monomer and other monomers is synthesized. Next, a method of adding a monocarboxyl group-containing monomer to an epoxy group of the polymer and reacting the generated hydroxyl group with a polybasic acid anhydride to obtain an alkali-soluble photosensitive resin may be exemplified. Here, the monocarboxyl group-containing monomer is a monomer having one carboxyl group.

Examples of epoxy group-containing monomers include glycidyl (meth)acrylate, methyl glycidyl (meth)acrylate, 2-glycidoxyethyl (meth)acrylate, 3,4-epoxy butyl (meth)acrylate, and 3,4-epoxycyclohexyl (meth)acrylate. Among these, glycidyl (meth)acrylate is preferable in consideration of reactivity.

Examples of monocarboxyl group-containing monomers include (meth)acrylic acid, crotonic acid, o-, m-, p-vinylbenzoic acid, and monocarboxylic acids such as an α-position haloalkyl-, alkoxyl-, halogen-, nitro-, or cyano-substituted (meth)acrylic acid.

Examples of polybasic acid anhydrides include tetrahydrophthalic anhydride, phthalic anhydride, hexahydrophthalic anhydride, succinic anhydride, and maleic anhydride. Here, the polybasic acid anhydride may have a carboxyl group that does not form an acid anhydride.

Examples of other monomers include (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, 2-ethylhexyl (meth)acrylate, cyclohexyl (meth)acrylate, stearyl (meth)acrylate, lauryl (meth)acrylate, tetrahydrofurfuryl (meth)acrylate, isobornyl (meth)acrylate, phenyl (meth)acrylate, benzyl (meth)acrylate, phenoxyethyl (meth)acrylate, phenoxydiethylene glycol (meth)acrylate, methoxypolypropylene glycol (meth)acrylate, and ethoxypolyethylene glycol (meth)acrylate, alternatively, (meth)acrylamide such as (meth)acrylamide, N,N-dimethyl(meth)acrylamide, N,N-diethyl (meth)acrylamide, N-isopropyl (meth)acrylamide, diacetone (meth)acrylamide, and acryloylmorpholine, styrenes, or styrenes such asa-methylstyrene, vinyl ethers such as ethylvinyl ether, n-propylvinyl ether, isopropylvinyl ether, n-butylvinyl ether, and isobutyl vinyl ether, and fatty acid vinyls such as vinyl acetate and vinyl propionate.

In addition, examples thereof include N-substituted maleimides such as cyclohexylmaleimide, phenylmaleimide, methylmaleimide, ethylmaleimide, 1,2-bismaleimidoethane, 1,6-bismaleimidohexane, 3-maleimidopropionic acid, 6,7-methylenedioxy-4-methyl-3-maleimidocoumarin, 4,4′-bismaleimidodiphenylmethane, bis(3-ethyl-5-methyl-4-maleimidophenyl)methane, N,N′-1,3-phenylenedimaleimide, N,N′-1,4-phenylenedimaleimide, N-(1-pyrenyl)maleimide, N-(2,4,6-trichlorophenyl)maleimide, N-(4-aminophenyl)maleimide, N-(4-nitrophenyl)maleimide, N-benzylmaleimide, N-bromomethyl-2,3-dichloromaleimide, N-succinimidyl-3-maleimidobenzoate, N-succinimidyl-3-maleimidopropionate, N-succinimidyl-4-maleimidobutyrate, N-succinimidyl-6-maleimidohexanoate, N-[4-(2-benzimidazolyl)phenyl]maleimide, and 9-maleimidoacridine, EO-modified cresol acrylate, n-nonylphenoxy polyethylene glycol acrylate, phenoxyethyl acrylate, ethoxylated phenyl acrylate, phenol ethylene oxide (EO)-modified (meth)acrylate, paracumyl phenol EO- or propylene oxide (PO)-modified (meth)acrylate, nonylphenol EO-modified (meth)acrylate, and nonylphenol PO-modified (meth)acrylate.

In the method (ii), for example, a hydroxyl group-containing monomer, a carboxyl group-containing monomer, and other monomers are synthesized to produce a polymer. Next, a method of reacting a hydroxyl group of the polymer with an isocyanate group of an isocyanate group-containing monomer to synthesize an alkali-soluble photosensitive resin may be exemplified.

Examples of hydroxyl group-containing monomers include hydroxyalkyl methacrylates such as 2-hydroxyethyl (meth)acrylate, 2- or 3-hydroxypropyl(meth)acrylate, 2-, 3- or 4-hydroxybutyl(meth)acrylate, glycerol mono(meth)acrylate, and cyclohexane dimethanol mono(meth)acrylate. In addition, examples thereof include polyether mono(meth)acrylates obtained by addition polymerization of ethylene oxide, propylene oxide, and/or butylene oxide to hydroxyalkyl(meth)acrylate, and polyester mono(meth)acrylates obtained by adding poly γ-valerolactone, poly ε-caprolactone, and/or poly-12-hydroxy stearic acid. Among these, 2-hydroxyethyl methacrylate, and glycerol mono(meth)acrylate are preferable, and glycerol mono(meth)acrylate is more preferable.

Examples of isocyanate group-containing monomers include 2-(meth)acryloylethyl isocyanate, 2-(meth)acryloyloxyethyl isocyanate, and 1,1-bis[methacryloyloxy]ethyl isocyanate.

Examples of monomers that can be used in addition to the above monomers include other monomers exemplified in the above method (i) and also phosphate ester group-containing monomers.

The phosphate ester group-containing monomer is, for example, a compound obtained by reacting a hydroxyl group of a hydroxyl group-containing monomer with a phosphate esterifying agent such as phosphorus pentoxide or polyphosphate.

The raw materials for the resin (D) may be used alone or two or more thereof may be used in combination. In addition, the resins (D) may be used alone or two or more thereof may be used in combination.

The content of the resin (D) with respect to 100 parts by mass of the colorant (A) is preferably 20 to 400 parts by mass and more preferably 50 to 250 parts by mass. The content is preferably 20 parts by mass or more because film-forming properties and various resistances are favorable, and the content is preferably 400 parts by mass or less because the concentration of the colorant is high and favorable color properties can be exhibited.

The weight average molecular weight (Mw) of the resin (D) is preferably 2,000 to 40,000, more preferably 3,000 to 30,000, and still more preferably 4,000 to 20,000. The value of Mw/Mn is preferably 10 or less. Here, Mn is the number average molecular weight.

The acid value of the resin (D) is preferably 50 to 200 mg KOH/g, more preferably 70 to 180 mg KOH/g, and still more preferably 90 to 170 mg KOH/g. With an appropriate acid value, the balance between alkali solubility, adhesion, and residue minimization can be achieved at a high level.

### <Optional Components>

The present photosensitive coloring composition contains a colorant (A), a photopolymerizable monomer (B), a photopolymerization initiator (C), and a resin (D), and as necessary, may contain other components. Hereinafter, respective components that can be contained in the photosensitive coloring composition will be described.

### (Thermosetting Compound)

The photosensitive coloring composition may contain a thermosetting compound. Therefore, when a color filter is produced, the heat resistance is improved because the crosslinking density is improved in the heating step after the film is patterned by photolithography. In addition, in the heating step, since the colorant (A) is less likely to aggregate, the contrast ratio is further improved.

The thermosetting compound is a low-molecular-weight compound or a polymer (thermosetting resin), and the molecular weight thereof is not limited. In the present disclosure, the thermosetting resin is contained in the thermosetting compound.

Examples of thermosetting compounds include epoxy compounds, oxetane compounds, benzoguanamine compounds, rosin-modified maleic acid compounds, rosin-modified fumaric acid compounds, melamine compounds, urea compounds, and phenol compounds. Among these, epoxy compounds and oxetane compounds are preferable.

### ((Epoxy Compound))

Examples of epoxy compounds include polycondensates of bisphenols (bisphenol A, bisphenol F, bisphenol S, biphenol, bisphenol AD, etc.), phenols (phenol, alkyl-substituted phenol, aromatic-substituted phenol, naphthol, alkyl-substituted naphthol, dihydroxybenzene, alkyl-substituted dihydroxybenzene, dihydroxy naphthalene, etc.) and various aldehydes (formaldehyde, acetaldehyde, alkylaldehyde, benzaldehyde, alkyl-substituted benzaldehyde, hydroxybenzaldehyde, naphthaldehyde, glutaraldehyde, phthalaldehyde, crotonaldehyde, cinnamaldehyde, etc.), polymers of phenols and various diene compounds (dicyclopentadiene, terpenes, vinyl cyclohexene, norbornadiene, vinyl norbornene, tetrahydroindene, divinylbenzene, divinylbiphenyl, diisopropenylbiphenyl, butadiene, isoprene, etc.), polycondensates of phenols and ketones (acetone, methylethyl ketone, methyl isobutyl ketone, acetophenone, benzophenone, etc.), polycondensates of phenols and aromatic dimethanols ((benzenedimethanol, α,α,α′,α′-(benzenedimethanol, biphenyldimethanol, α,α,α′,α′-biphenyldimethanol, etc.), polycondensates of phenols and aromatic dichloromethyls (α,α′-dichloroxylene, bischloro methyl biphenyl, etc.), polycondensates of bisphenols and various aldehydes, glycidyl ether epoxy resins in which alcohols and the like are glycidylized, alicyclic epoxy resins, heterocyclic epoxy resins, aliphatic epoxy resins, glycidylamine epoxy resins, and glycidyl ester epoxy resins.

Examples of commercial products of epoxy compounds include Epikote 807, Epikote 815, Epikote 825, Epikote 827, Epikote 828, Epikote 190P, and Epikote 191P (all, product name; commercially available from Yuka Shell Epoxy Co., Ltd.), Epikote 1004 and Epikote 1256 (all product name; commercially available from Japan Epoxy Resin Co., Ltd.), TECHMORE VG3101L (product name; commercially available from Mitsui Chemicals Inc), EPPN-501H, 502H (product name; commercially available from Nippon Kayaku Co., Ltd.), JER 1032H60 (product name; commercially available from Japan Epoxy Resin Co., Ltd.), JER 157S65 and 157S70 (product name; commercially available from Japan Epoxy Resin Co., Ltd.), EPPN-201 (product name; commercially available from Nippon Kayaku Co., Ltd.), JER152 and JER154 (all product name; commercially available from Japan Epoxy Resin Co., Ltd.), EOCN-1025, EOCN-1035, EOCN-104S, and EOCN-1020 (all product name; commercially available from Nippon Kayaku Co., Ltd.), Celloxide 2021 and EHPE-3150 (all product name; commercially available from Daicel Corporation), Denacol EX-211, 212, 252, 313, 314, 321, 411, 421, 512, 521, 611, 612, 614, 614B, 622, 711, and 721 (all product name; commercially available from Nagase ChemteX Corporation), TEPIC-L, TEPIC-H, and TEPIC-S (commercially available from Nissan Chemical Corporation).

The content of the epoxy compound with respect to 100 parts by mass of the colorant (A) is preferably 0.5 to 300 parts by mass and more preferably 1.0 to 50 parts by mass. When an appropriate amount is added, the heat resistance and pattern shape of the film are further improved.

### ((Oxetane Compound))

The oxetane compound is a compound having an oxetane group. Examples of oxetane compounds include monofunctional oxetane compounds, bifunctional oxetane compounds, and tri- or higher-functional oxetane compounds.

Examples of monofunctional oxetane compounds include (3-ethyloxetan-3-yl)methyl acrylate, (3-ethyloxetan-3-yl)methyl methacrylate, 3-ethyl-3-hydroxymethyl oxetane, 3-ethyl-3-(2-ethylhexyloxymethyl)oxetane, 3-ethyl-3-(phenoxymethyl)oxetane, 3-ethyl-3-(2-methacryloxymethyl)oxetane, and 3-ethyl-3-{[3-(triethoxysilyl)propoxy]methyl}oxetane.

Examples of commercial products include OXE-10 and OXE-30 (commercially available from Osaka Organic Chemical Industry Ltd.) and OXT-101 and OXT-212 (commercially available from Toagosei Co., Ltd.).

Examples of bifunctional oxetane compounds include 4,4′-bis[(3-ethyl-3-oxetanyl)methoxymethyl]biphenyl), 1,4-bis[(3-ethyl-3-oxetanyl)methoxymethyl]benzene, 1,4-bis{[(3-ethyl-3-oxetanyl)methoxy]methyl}benzene, di[1-ethyl(3-oxetanyl)]methyl ether, di[1-ethyl(3-oxetanyl)]methyl ether-3-ethyl-3-hydroxymethyl oxetane, 3-ethyl-3-(2-ethylhexyloxymethyl)oxetane, 3-ethyl-3-(2-phenoxymethyl)oxetane, 3,7-bis(3-oxetanyl)-5-oxa-nonane, 1,2-bis[(3-ethyl-3-oxetanylmethoxy)methyl]ethane, 1,3-bis[(3-ethyl-3-oxetanylmethoxy)methyl]propane, ethylene glycol bis (3-ethyl-3-oxetanylmethyl)ether, dicyclopentenyl bis(3-ethyl-3-oxetanylmethyl)ether, triethylene glycol bis (3-ethyl-3-oxetanylmethyl)ether, tetraethylene glycol bis(3-ethyl-3-oxetanylmethyl)ether, 1,4-bis(3-ethyl-3-oxetanylmethoxy)butane, 1,6-bis(3-ethyl-3-oxetanylmethoxy)hexane, polyethylene glycol bis(3-ethyl-3-oxetanylmethyl)ether, ethylene oxide (EO)-modified bisphenol A bis(3-ethyl-3-oxetanylmethyl)ether, propylene oxide (PO)-modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether, and EO-modified bisphenol F (3-ethyl-3-oxetanylmethyl)ether.

Examples of commercial products include OXBP and OXTP (commercially available from Ube Industries, Ltd.), and OXT-121 and OXT-221 (commercially available from Toagosei Co., Ltd.).

Examples of compounds having tri- or higher-functional oxetane groups include pentaerythritol tris(3-ethyl-3-oxetanylmethyl)ether, pentaerythritol tetrakis(3-ethyl-3-oxetanylmethyl)ether, dipentaerythritol hexa(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexa(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, oxetane group-containing resins (for example, oxetane-modified phenolic novolac resins and the like described in Japanese Patent No. 3783462) and polymers obtained by radically polymerizing (meth)acrylic monomers such as the above OXE-30.

The content of the oxetane compound is preferably 0.5 to 50 parts by mass and more preferably 1 to 40 parts by mass. When an appropriate amount is contained, the solvent resistance of the film is further improved.

### ((Melamine Compound))

The melamine compound is a compound having a melamine ring structure. The melamine compound includes a low-molecular-weight compound and a high-molecular-weight compound. The melamine compound in this specification is preferably a compound in which a methylol group or an ether group is bonded to a melamine ring. The average number of bonds of methylol groups and/or ether groups per melamine ring is preferably 5.0 or more. If it has an appropriate number of bonds, the solvent resistance of the film is further improved, and the contrast ratio is less likely to decrease.

Examples of commercial products of melamine compounds include Nikalac MW-30HM, MW-390, MW-100LM, MX-750LM, MW-30M, MW-30, MW-22, MS-21, MS-11, MW-24X, MS-001, MX-002, MX-730, MX-750, MX-708, MX-706, MX-042, MX-45, MX-500, MX-520, MX-43, MX-417, MX-410 (Sanwa Chemical), and Cymel 232, 235, 236, 238, 285, 300, 301, 303, 350, 370 (Nihon Cytec Industries Inc.).

Among these, Nikalac MW-30HM, MW-390, MW-100LM, MX-750LM, MW-30M, MW-30, MW-22, MS-21, MS-11, MW-24X, MX-45 (Sanwa Chemical), and Cymel 232, 235, 236, 238, 300, 301, 303, 350 (Nihon Cytec Industries Inc.), which have an average number of methylol groups and/or ether groups per melamine ring of 5.0 or more, are preferable because the crosslinking density of the film is further improved.

When a thermosetting compound is used, a total content of the thermosetting compound with respect to 100 parts by mass of the colorant (A) is preferably 20 to 400 parts by mass and more preferably 50 to 250 parts by mass. The content is preferably parts by mass or more because film-forming properties and various resistances are favorable, and the content is preferably 400 parts by mass or less because the concentration of the colorant is high and favorable color properties can be exhibited.

### (Antioxidant)

The present photosensitive coloring composition may contain an antioxidant. The antioxidant prevents the photopolymerization initiator and the thermosetting compound from being oxidized and turning yellow in the heating step during thermosetting and ITO annealing so that the transmittance of pixels can increase.

The “antioxidant” may be a compound having an ultraviolet absorbing function, a radical scavenging function, or a peroxide decomposition function, and specific examples of antioxidants include hindered phenol, hindered amine, phosphorus, sulfur, benzotriazole, benzophenone, hydroxylamine, salicylic acid ester, and triazine compounds, and known ultraviolet absorbers, antioxidants and the like can be used.

Among these antioxidants, in order to achieve both transmittance and sensitivity of the coating, hindered phenol antioxidants, hindered amine antioxidants, phosphorus antioxidants or sulfur antioxidants are preferable, and hindered phenol antioxidants, hindered amine antioxidants, or phosphorus antioxidants are more preferable.

Examples of hindered phenol antioxidants include 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, pentaerythritol tetrakis[3-(3,5-di-tert-butyl-4-hydroxyphenyl)propionate, 2,6-di-t-butyl-4-nonylphenol, 2,2′-isobutylidene-bis-(4,6-dimethyl-phenol), 4,4′-butylidene-bis-(2-t-butyl-5-methylphenol), 2,2′-thio-bis-(6-t-butyl-4-methylphenol), 2,5-di-t-amyl-hydroquinone, 2,2′ thiodiethylbis-(3,5-di-t-butyl-4-hydroxyphenyl)-propionate, 1,1,3-tris-(2′-methyl-4′-hydroxy-5′-t-butylphenyl)-butane, 2,2′-methylene-bis-(6-(1-methyl-cyclohexyl)-p-cresol), 2,4-dimethyl-6-(1-methyl-cyclohexyl)-phenol, and N,N-hexamethylenebis(3,5-di-t-butyl-4-hydroxy-hydrocinnamamide). In addition, oligomer type and polymer type compounds having a hindered phenol structure can also be used.

Examples of hindered amine antioxidants include polycondensates of bis(2,2,6,6-tetramethyl-4-piperidyl) sebacate, bis(N-methyl-2,2,6,6-tetramethyl-4-piperidyl) sebacate, N,N′-bis(2,2,6,6-tetramethyl-4-piperidyl)-1,6-hexamethylenediamine, 2-methyl-2-(2,2,6,6-tetramethyl-4-piperidyl)amino-N-(2,2,6,6-tetramethyl-4-piperidyl)propionamide, tetrakis(2,2,6,6-tetramethyl-4-piperidyl)(1,2,3,4-butanetetracarboxylate, poly[{6-(1,1,3,3-tetramethylbutyl)imino-1,3,5-triazine-2,4-diyl}{(2,2,6,6-tetramethyl-4-piperidyl)imino}hexamethyl{(2,2,6,6-tetramethyl-4-piperidyl)imino}], poly[(6-morpholino-1,3,5-triazine-2,4-diyl){(2,2,6,6-tetramethyl-4-piperidyl)imino}hexamethyl{(2,2,6,6-tetramethyl-4-piperidyl)imino}], and dimethyl succinate, and 1-(2-hydroxyethyl)-4-hydroxy-2,2,6,6-tetramethylpiperidine, N,N′-4,7-tetrakis[4,6-bis{N-butyl-N-(1,2,2,6,6-pentamethyl-4-piperidyl)amino}-1,3,5-triazin-2-yl]-4,7-diazadecane-1,10-diamine. In addition, oligomer type and polymer type compounds having a hindered amine structure may be used.

Examples of phosphorus antioxidants include tris(isodecyl)phosphite, tris(tridecyl)phosphite, phenyl isooctyl phosphite, phenyl isodecyl phosphite, phenyl di(tridecyl)phosphite, diphenylisooctylphosphite, diphenylisodecylphosphite, diphenyl tridecyl phosphite, triphenyl phosphite, tris(nonylphenyl)phosphite, 4,4′-isopropylidene diphenolalkylphosphite, trisnonylphenylphosphite, trisdinonylphenyl phosphite, tris(2,4-di-t-butylphenyl)phosphite, tris(biphenyl)phosphite, distearylpentaerythritol diphosphite, di(2,4-di-t-butylphenyl) pentaerythritol diphosphite, di(nonylphenyl) pentaerythritol diphosphite, phenylbisphenol A pentaerythritol diphosphite, tetratridecyl 4,4′-butylidenebis(3-methyl-6-t-butylphenol)diphosphite, hexatridecyl 1,1,3-tris(2-methyl-4-hydroxy-5-t-butylphenyl)butane triphosphite, 3,5-di-t-butyl-4-hydroxybenzyl phosphite diethyl ester, sodium bis(4-t-butylphenyl) phosphite, sodium-2,2-methylene-bis(4,6-di-t-butylphenyl)-phosphite, 1,3-bis(diphenoxyphosphonyloxy)-benzene, and ethyl bis(2,4-di-tert-butyl-6-methylphenyl) phosphite. In addition, oligomer type and polymer type compounds having a phosphite structure may also be used.

Examples of sulfur antioxidants include 2,2-thio-diethylenebis[3-(3,5-di-t-butyl-4-hydroxyphenyl)propionate], 2,4-bis[(octylthio)methyl]-o-cresol, and 2,4-bis[(laurylthio)methyl]-o-cresol. In addition, oligomer type and polymer type compounds having a thioether structure may be used.

Examples of benzotriazole antioxidants include oligomer type and polymer type compounds having a benzotriazole structure.

Examples of benzophenone antioxidants include 2-hydroxy-4-methoxybenzophenone, 2,4-dihydroxybenzophenone, 2-hydroxy-4-n-octoxybenzophenone, 4-dodecyloxy-2-hydroxybenzophenone, 2-hydroxy-4-octadecyloxybenzophenone, 2,2′-dihydroxy-4-methoxybenzophenone, 2,2′-dihydroxy-4,4′-dimethoxybenzophenone, 2,2′,4,4′-tetrahydroxybenzophenone, 2-hydroxy-4-methoxy-5-sulfobenzophenone, 2-hydroxy-4-methoxy-2′-carboxybenzophenone, and 2-hydroxy-4-chlorobenzophenone. In addition, oligomer type and polymer type compounds having a benzophenone structure may be used.

Examples of triazine antioxidants include 2,4-bis(allyl)-6-(2-hydroxyphenyl)-1,3,5-triazine. In addition, oligomer type and polymer type compounds having a triazine structure may be used.

Examples of salicylic acid ester antioxidants include phenyl salicylate, p-octylphenyl salicylate, and p-tertbutylphenyl salicylate. In addition, oligomer type and polymer type compounds having a salicylic acid ester structure may be used.

These antioxidants may be used alone or as necessary, a mixture of two or more types thereof at any ratio may be used.

In addition, the content of the antioxidant with respect to a total solid content of the photosensitive coloring composition is preferably 0.5 to 5.0 mass % in consideration of brightness and sensitivity.

### (Adhesion Improving Agent)

The photosensitive coloring composition may contain an adhesion improving agent such as a silane coupling agent in order to improve adhesion to the base material.

When adhesion is improved using an adhesion improving agent, the reproducibility of fine lines is improved and the resolution is improved.

Examples of adhesion improving agents as silane coupling agents include vinyl silanes such as vinyltrimethoxysilane and vinyltriethoxysilane, (meth)acrylic silanes such as 3-methacryloxypropylmethyldimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane, epoxy silanes such as 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, and 3-glycidoxypropyltriethoxysilane, aminosilanes such as N-2-(aminoethyl)-3-aminopropylmethyl dimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, and N-(vinylbenzyl)-2-aminoethyl-3-aminopropyltrimethoxysilane hydrochloride, mercaptos such as 3-mercaptopropylmethyldimethoxysilane and 3-mercaptopropyltrimethoxysilane, styryls such as p-styryltrimethoxysilane, ureidos such as 3-ureidopropyltriethoxysilane, sulfides such as bis(triethoxysilylpropyl)tetrasulfide, and isocyanates such as 3-isocyanate propyltriethoxysilane. The amount of the adhesion improving agent used with respect to 100 parts by mass of the colorant in the coloring composition is 0.01 to 10 parts by mass, and preferably 0.05 to 5 parts by mass. If the amount is within the above range, it is more preferable because the effect is improved, and the balance between adhesion, resolution, and sensitivity becomes favorable.

### (Leveling Agent)

A leveling agent may be added to the photosensitive coloring composition in order to improve leveling properties of the composition. As the leveling agent, dimethylsiloxane having a polyether structure or a polyester structure in the main chain is preferable. Specific examples of dimethylsiloxane having a polyether structure in the main chain include FZ-2122 (commercially available from Dow Corning Toray Co., Ltd.) and BYK-333 (commercially available from BYK). Specific examples of dimethylsiloxane having a polyester structure include BYK-310 and BYK-370 (commercially available from BYK). Dimethylsiloxane having a polyether structure in the main chain and dimethylsiloxane having a polyester structure in the main chain can be used in combination. The content of the leveling agent with respect to a total solid content of the coloring composition is preferably 0.003 to 0.5 mass %.

As a particularly preferable leveling agent, one which is a type of so-called surfactant having a hydrophobic group and a hydrophilic group in the molecule, and which has a hydrophilic group but has low solubility in water, and has a property of a low surface tension-lowering ability when added to a coloring composition, and furthermore, and is beneficial to have favorable wettability with respect to a glass plate in spite of its low surface tension-lowering ability, and can sufficiently reduce electrification in an addition amount that does not cause defects on the coating due to foaming can be preferably used. As a leveling agent having such preferable properties, dimethylpolysiloxane having a polyalkylene oxide unit can be preferably used. Polyalkylene oxide units include a polyethylene oxide unit and a polypropylene oxide unit, and dimethylpolysiloxane may have both a polyethylene oxide unit and a polypropylene oxide unit.

Anionic, cationic, nonionic, or amphoteric surfactants can be auxiliarily added to the leveling agent. Two or more of surfactants may be used in combination.

Examples of anionic surfactants that are auxiliarily added to the leveling agent include polyoxyethylene alkyl ether sulfate, sodium dodecylbenzenesulfonate, alkali salts of styrene-acrylic acid copolymers, sodium alkylnaphthalene sulfonate, sodium alkyldiphenyl ether disulfonate, monoethanolamine lauryl sulfate, triethanolamine lauryl sulfate, ammonium lauryl sulfate, monoethanolamine stearate, sodium stearate, sodium lauryl sulfate, monoethanolamine of styrene-acrylic acid copolymers, and polyoxyethylene alkyl ether phosphate ester.

Examples of cationic surfactants that are auxiliarily added to the leveling agent include alkyl quaternary ammonium salts and ethylene oxide adducts thereof. Examples of nonionic surfactants that are auxiliarily added to the leveling agent include polyoxyethylene oleyl ether, polyoxyethylene lauryl ether, polyoxyethylene nonyl phenyl ether, polyoxyethylene alkyl ether phosphate ester, polyoxyethylene sorbitan monostearate, polyethylene glycol monolaurate and the like; alkylbetaines such as alkyldimethylaminoacetic acid betaine, amphoteric surfactants such as alkylimidazoline and fluorine or silicone surfactants.

### (Curing Agent and Curing Accelerator)

In addition, the photosensitive coloring composition may contain, as necessary, a curing agent and a curing accelerator, in order to assist curing of the thermosetting resin. Phenolic resins, amine compounds, acid anhydrides, active esters, carboxylic acid compounds, sulfonic acid compounds and the like are effective as curing agents, but the present disclosure is not particularly limited thereto, and any curing agent may be used as long as it can react with a thermosetting resin. In addition, among these, a compound having two or more phenolic hydroxyl groups in one molecule and an amine curing agent are preferably exemplified. As the curing accelerator, for example, amine compounds (for example, dicyandiamide, benzyldimethylamine, 4-(dimethylamino)-N,N-dimethylbenzylamine, 4-methoxy-N,N-dimethylbenzylamine, 4-methyl-N,N-dimethylbenzylamine, etc.), quaternary ammonium salt compounds (for example, triethylbenzylammonium chloride, etc.), blocked isocyanate compounds (for example, dimethylamine, etc.), imidazole derivative bicyclic amidine compounds and salts thereof (for example, imidazole, 2-methylimidazole, 2-ethylimidazole, 2-ethyl-4-methylimidazole, 2-phenylimidazole, 4-phenylimidazole, 1-cyanoethyl-2-phenylimidazole, 1-(2-cyanoethyl)-2-ethyl-4-methylimidazole, etc.), phosphorus compounds (for example, triphenylphosphine, etc.), guanamine compounds (for example, melamine, guanamine, acetoguanamine, benzoguanamine, etc.), S-triazine derivatives (for example, 2,4-diamino-6-methacryloyloxyethyl-S-triazine, 2-vinyl-2,4-diamino-S-triazine, 2-vinyl-4,6-diamino-S-triazineisocyanuric acid adduct, 2,4-diamino-6-methacryloyloxyethyl-S-triazineisocyanuric acid adduct, etc.) and the like can be used.

These may be used alone or two or more thereof may be used in combination. The content of the curing accelerator with respect to 100 parts by mass of the thermosetting resin is preferably 0.01 to 15 parts by mass.

### (Storage Stabilizer)

The present photosensitive coloring composition may contain a storage stabilizer in order to stabilize the viscosity over time.

Examples of storage stabilizers include quaternary ammonium chlorides such as benzyltrimethylammonium chloride and diethylhydroxyamine, organic acids such as lactic acid and oxalic acid, and methyl ethers thereof, t-butylpyrocatechol, organic phosphines such as tetraethylphosphine and tetraphenylphosphine, and phosphite. The amount of the storage stabilizer used with respect to 100 parts by mass of the colorant may be 0.1 to 10 parts by mass.

### (Solvent)

The photosensitive coloring composition may contain a solvent. Therefore, the viscosity of the photosensitive coloring composition is easily adjusted so that a film with a smooth surface is easily formed. The solvent may be appropriately selected according to the purpose of use, and may be contained in an appropriate amount.

Examples of solvents include ester solvents (solvents containing —COO— in the molecule and containing no —O—), ether solvents (solvents containing —O— in the molecule and containing no —COO—), ether ester solvents (solvents containing —COO— and —O— in the molecule), ketone solvents (solvents containing —CO— in the molecule and containing no —COO—), alcohol solvents (solvents containing OH in the molecule and containing none of —O—, —CO— and —COO—), aromatic hydrocarbon solvents, amide solvents, and dimethyl sulfoxide.

Examples of ester solvents include methyl lactate, ethyl lactate, butyl lactate, methyl 2-hydroxyisobutanoate, ethyl acetate, n-butyl acetate, isobutyl acetate, pentyl formate, isopentyl acetate, butyl propionate, isopropyl butyrate, ethyl butyrate, butyl butyrate, methyl pyruvate, ethyl pyruvate, propyl pyruvate, methyl acetoacetate, ethyl acetoacetate, cyclohexanol acetate, and γ-butyrolactone.

Examples of ether solvents include ether solvents having no hydroxyl group and ether alcohol solvents (solvents containing —OH and —O— in the molecule). Examples of ether alcohol solvents include ethylene glycol monomethyl ether, diethylene glycol monomethyl ether, ethylene glycol monoethyl ether, diethylene glycol monoethyl ether, ethylene glycol monopropyl ether, ethylene glycol monobutyl ether, diethylene glycol monomethyl ether, diethylene glycol monoethyl ether, diethylene glycol monobutyl ether, propylene glycol monomethyl ether, dipropylene glycol monomethyl ether, tripropylene glycol monomethyl ether, propylene glycol monoethyl ether, propylene glycol monopropyl ether, propylene glycol monobutyl ether, 3-methoxy-1-butanol, and 3-methoxy-3-methylbutanol.

Examples of ether solvents having no hydroxyl group include tetrahydrofuran, tetrahydropyrane, 1,4-dioxane, diethylene glycoldimethyl ether, diethylene glycol diethyl ether, diethylene glycolmethylethyl ether, diethylene glycol dipropyl ether, diethylene glycol dibutyl ether, dipropylene glycol dimethyl ether, dipropylene glycol methyl-n-propyl ether, anisole, phenetole, and methylanisole.

Among these, the present photosensitive coloring composition preferably contains an ether alcohol solvent in consideration of compatibility and coating properties of the photosensitive coloring composition.

Examples of ether ester solvents include methyl methoxyacetate, ethyl methoxyacetate, butyl methoxyacetate, methyl ethoxyacetate, ethyl ethoxyacetate, methyl 3-methoxypropionate, ethyl 3-methoxypropionate, methyl 3-ethoxypropionate, ethyl 3-ethoxypropionate, methyl 2-methoxypropionate, ethyl 2-methoxypropionate, propyl 2-methoxypropionate, methyl 2-ethoxypropionate, ethyl 2-ethoxypropionate, methyl 2-methoxy-2-methylpropionate, ethyl 2-ethoxy-2-methylpropionate, 3-methoxybutyl acetate, 3-methyl-3-methoxybutyl acetate, propylene glycol monomethyl ether acetate, propylene glycol monoethyl ether acetate, propylene glycol monopropyl ether acetate, ethylene glycol monomethyl ether acetate, ethylene glycol monoethyl ether acetate, diethylene glycol monoethyl ether acetate, diethylene glycol monobutyl ether acetate, dipropylene glycol methyl ether acetate, and dipropylene glycol diacetate.

Examples of ketone solvents include 4-hydroxy-4-methyl-2-pentanone, acetone, 2-butanone, 2-heptanone, 3-heptanone, 4-heptanone, 4-methyl-2-pentanone, cyclopentanone, cyclohexanone, and isophorone.

Examples of alcohol solvents include methanol, ethanol, propanol, butanol, hexanol, cyclohexanol, ethylene glycol, propylene glycol, 1,3-butylene glycol, and glycerin.

Examples of aromatic hydrocarbon solvents include benzene, toluene, xylene, and mesitylene.

Examples of amide solvents include N,N-dimethylformamide, N,N-dimethylacetamide, and N-methylpyrrolidone.

Among these, in consideration of coating properties and drying properties, a solvent having a boiling point of 120° C. or higher and 245° C. or lower at 1 atm is preferable. For example, propylene glycol monomethyl ether acetate, ethyl lactate, butyl lactate, propylene glycol monomethyl ether, ethyl 3-ethoxypropionate, ethylene glycol monomethyl ether, diethylene glycol monomethyl ether, diethylene glycol monoethyl ether, 4-hydroxy-4-methyl-2-pentanone, N,N-dimethylformamide, N-methylpyrrolidone, cyclohexanone, tripropylene glycol monomethyl ether, 3-methoxy-1-butanol, 3-methoxy-3-methylbutanol, diethylene glycol monomethyl ether, diethylene glycol monoethyl ether, diethylene glycol monobutyl ether, propylene glycol monomethyl ether, propylene glycol monobutyl ether, dipropylene glycol monomethyl ether and the like are more preferable, and propylene glycol monomethyl ether acetate, propylene glycol monomethyl ether, ethyl lactate, ethyl 3-ethoxypropionate, cyclohexanone, tripropylene glycol monomethyl ether, 3-methoxy-1-butanol and the like are still more preferable.

In addition, the amount of these solvents used with respect to a solid content of 100 parts by mass of the photosensitive coloring composition is preferably 200 to 900 parts by mass and more preferably 300 to 570 parts by mass because it is possible to adjust the viscosity of the photosensitive coloring composition to an appropriate level and it is possible to form a coating having a desired uniform film thickness. The viscosity of the photosensitive coloring composition is preferably 2.4 to 7.2 mPa·s and more preferably 3.4 to 6.4 mPa·s.

In addition, in the photosensitive coloring composition of the present organic EL display device, for the solvent, it is preferable to use an ether alcohol solvent and an ether ester solvent in combination. When the solvents are used in combination, cracks on the surface of pixels formed from the photosensitive coloring composition are reduced and the smoothness is improved. Here, the boiling point of these solvents is preferably 140° C. or higher and 245° C. or lower.

Among these, as the ether alcohol solvent, tripropylene glycol monomethyl ether, diethylene glycol monomethyl ether, diethylene glycol monoethyl ether, diethylene glycol monobutyl ether, propylene glycol monobutyl ether, dipropylene glycol monomethyl ether, 3-methoxy-1-butanol, and 3-methoxy-3-methylbutanol are preferable.

In addition, among these, as the ether ester solvent, propylene glycol monomethyl ether acetate, and ethyl 3-ethoxypropionate are preferable.

When an ether ester solvent and an ether alcohol solvent are used in combination as the solvent, the proportion of the ether ester solvent with respect to a solid content of 100 parts by mass of the photosensitive coloring composition is preferably 250 to 600 parts by mass and more preferably 300 to 450 parts by mass. In addition, the proportion of the ether alcohol solvent with respect to a solid content of 100 parts by mass of the photosensitive coloring composition is preferably 2.5 to 100 parts by mass and more preferably 5 to 45 parts by mass. Within the above range, the smoothness of pixels can be further improved, and cracks can be further reduced.

### (Dispersing Aid)

When the colorant is dispersed in the colorant carrier, a dispersing aid such as pigment derivatives, a dispersant, or a surfactant may be appropriately contained. Since the dispersing aid has a strong effect of preventing reaggregation of the colorant after dispersion, the coloring composition obtained by dispersing the colorant in the colorant carrier using the dispersing aid has favorable brightness and viscosity stability.

### ((Pigment Derivatives))

Examples of pigment derivatives include compounds obtained by introducing basic substituent, acidic substituent, or a phthalimidomethyl group which optionally has a substituent into an organic pigment, anthraquinone, acridone or triazine, and for example, those described in Japanese Patent Laid-Open No. S63-305173, “Japanese Examined Patent Publication No. S57-15620, “Japanese Examined Patent Publication No. S59-40172, “Japanese Examined Patent Publication No. S63-17102, “Japanese Examined Patent Publication No. H5-9469, Japanese Patent Laid-Open No. 2001-335717, Japanese Patent Laid-Open No. 2003-128669, Japanese Patent Laid-Open No. 2004-091497, Japanese Patent Laid-Open No. 2007-156395, Japanese Patent Laid-Open No. 2008-094873, Japanese Patent Laid-Open No. 2008-094986, Japanese Patent Laid-Open No. 2008-095007, Japanese Patent Laid-Open No. 2008-195916, Japanese Patent No. 4585781 and the like can be used, and these may be used alone or two or more thereof may be used in combination.

In order to improve dispersion, the content of pigment derivatives with respect to 100 parts by mass of the colorant is preferably 0.5 parts by mass or more, more preferably 1 part by mass or more, and most preferably 3 parts by mass or more. In addition, in consideration of heat resistance and light resistance, the content is preferably 40 parts by mass or less, and more preferably 35 parts by mass or less.

### ((Dispersant))

The dispersant has a colorant affinity part having a property of adsorbing to the colorant and a part compatible with a colorant carrier, and adsorbs to the colorant and functions to stabilize dispersion of the colorant in the colorant carrier. Specific examples of dispersants used include polycarboxylic acid esters such as polyurethane and polyacrylate, oily dispersants such as unsaturated polyamide, polycarboxylic acid, polycarboxylic acid (moiety) amine salts, polycarboxylic acid ammonium salts, polycarboxylic acidalkylamine salts, polysiloxane, long-chain polyaminoamide phosphate, hydroxyl group-containing polycarboxylic acid ester, modified products thereof, amides formed by the reaction of poly (lower alkyleneimine) with polyesters having free carboxyl groups and salts thereof, water-soluble resins and water-soluble polymer compounds such as (meth)acrylic acid-styrene copolymers, (meth)acrylic acid-(meth)acrylic acid ester copolymers, styrene-maleic acid copolymers, poly vinyl alcohol, and poly vinyl pyrrolidone, and polyester compounds, modified polyacrylate compounds, ethylene oxide/propylene oxide adduct compounds, phosphate ester compounds, and these may be used alone or two or more thereof may be used in combination, but the present disclosure is not necessarily limited thereto.

Examples of commercially available dispersants include Disperbyk-101, 103, 107, 108, 110, 111, 116, 130, 140, 154, 161, 162, 163, 164, 165, 166, 170, 171, 174, 180, 181, 182, 183, 184, 185, 190, 2000, 2001, 2020, 2025, 2050, 2070, 2095, 2150, 2155, or Anti-Terra-U, 203, 204, or BYK-P104, P104S, 220S, 6919, or Lactimon, Lactimon-WS or Bykumen (commercially available from BYKJapan), SOLSPERSE-3000, 9000, 13000, 13240, 13650, 13940, 16000, 17000, 18000, 20000, 21000, 24000, 26000, 27000, 28000, 31845, 32000, 32500, 32550, 33500, 32600, 34750, 35100, 36600, 38500, 41000, 41090, 53095, 55000, and 76500 (commercially available from Lubrizol Japan Ltd.), EFKA-46, 47, 48, 452, 4008, 4009, 4010, 4015, 4020, 4047, 4050, 4055, 4060, 4080, 4400, 4401, 4402, 4403, 4406, 4408, 4300, 4310, 4320, 4330, 4340, 450, 451, 453, 4540, 4550, 4560, 4800, 5010, 5065, 5066, 5070, 7500, 7554, 1101, 120, 150, 1501, 1502, and 1503 (commercially available from BASF Japan Ltd.), and Ajisper PA111, PB711, PB821, PB822, and PB824 (commercially available from Ajinomoto Fine-Techno Co., Inc.).

### ((Surfactant))

Examples of surfactants include anionic surfactants such as sodium lauryl sulfate, polyoxyethylene alkyl ether sulfate, sodium dodecylbenzenesulfonate, styrene-acrylic acid copolymer alkali salts, sodium stearate, sodium alkylnaphthalene sulfonate, sodium alkyldiphenyl ether disulfonate, monoethanolamine lauryl sulfate, triethanolamine lauryl sulfate, ammonium lauryl sulfate, monoethanolamine stearate, styrene-acrylic acid copolymer monoethanolamine, and polyoxyethylene alkyl ether phosphate ester; nonionic surfactants such as polyoxyethylene oleyl ether, polyoxyethylene lauryl ether, polyoxyethylene nonyl phenyl ether, polyoxyethylene alkyl ether phosphate ester, polyoxyethylene sorbitan monostearate, and polyethylene glycol monolaurate; cationic surfactants such as alkyl quaternary ammonium salts and ethylene oxide adducts thereof; alkylbetaine such as alkyldimethylaminoacetic acid betaine, and amphoteric surfactants such as alkylimidazoline, and these may be used alone or two or more thereof may be used in combination, but the present disclosure is not necessarily limited thereto.

When a dispersant and a surfactant are added, the content thereof with respect to 100 parts by mass of the colorant is preferably 0.1 to 55 parts by mass, and more preferably 0.1 to 45 parts by mass. When the content of the dispersant and the surfactant added is less than 0.1 parts by mass, it is difficult to obtain the effect of addition, and when the content is larger than 55 parts by mass, excessive dispersant may affect dispersion.

### [Method of Producing Photosensitive Coloring Composition]

A method of producing a photosensitive coloring composition is, for example, a method of preparing a colorant dispersing element first, and then adding a photopolymerizable monomer and a photopolymerization initiator, and other components used as necessary.

The colorant dispersing element can be prepared, for example, by finely dispersing the colorant in a colorant carrier such as a binder resin and/or an organic solvent, preferably together with a dispersing aid, using various dispersing units such as a kneader, a 2-roll mill, a 3-roll mill, a ball mill, a horizontal sand mill, a vertical sand mill, an annular type bead mill and an attritor. When the colorant (A) includes two or more colorants, the plurality of colorants may be dispersed in the colorant carrier at the same time or colorant dispersion solutions may be separately prepared and then mixed. In addition, if the colorant has high solubility, specifically, if it has high solubility in the organic solvent used, and if it is dissolved by stirring and no foreign substance is confirmed, it is not necessary to finely disperse the colorant as described above for production.

### <Removal of Coarse Particles>

In the present photosensitive coloring composition, it is preferable to remove coarse particles of 5 μm or more, preferably coarse particles of 1 μm or more, still more preferably 0.5 μm or more, and particularly preferably coarse particles of 0.3 μm or more and mixed dust using a method such as centrifugation, filtration with a sintered filter or a membrane filter or the like.

### 2. Organic EL Display Device

Next, the configuration of the organic EL display device will be described with reference to FIGURE. FIGURE is a schematic cross-sectional view of the present organic EL display device. The present organic EL display device 10 has an organic EL layer 2 and a color filter on a silicon substrate 1 on which a driving element is formed, and as necessary, may additionally have a sealing layer 4 and a cover glass 5 on the color filter 3, and may have a flat layer (a plane) between the organic EL layer 2 and the color filter 3 (not shown).

Next, each configuration of the organic EL display device will be described in detail.

### [Color Filter]

The color filter 3 is formed on the organic EL layer and has at least red pixels, green pixels, and blue pixels (3a, 3b, 3c). The pixels are a cured product of the photosensitive coloring composition described above. The color filter may also have magenta pixels, cyan pixels, yellow pixels, or other pixels.

### <Method of Producing Color Filter>

The color filter is formed on the organic EL layer 2 or on a flat layer provided as necessary. When the flat layer is provided, the fine uneven surface of the organic EL layer can be made flat.

For the flat layer, a known curable resin can be used, a UV curable resin is preferable, and as necessary, a thermosetting resin may be used in combination. Although the UV curable resin is not particularly limited, an acrylic resin exhibiting sensitivity to the i-line (a wavelength of 365 nm) is preferable.

The method of forming pixels constituting the color filter is not particularly limited, and for example, the following method can be used.

First, the above photosensitive coloring composition is applied to the organic EL layer or the flat layer using a coating method such as a spray coating method, a dip coating method, a bar coating method, a roll coating method, and a spin coating method to form a coating.

Next, as necessary, after being dried, the coating is exposed to light through a mask having a predetermined pattern to photopolymerize a photopolymerizable monomer and a photosensitive resin, and a cured coating is formed. Examples of light sources used for exposure include ultraviolet rays such as low pressure mercury lamps, high pressure mercury lamps, and metal halide lamps and electron beams. The amount of exposure may be appropriately adjusted depending on the light source used, the thickness of the coating and the like.

In addition, a heat treatment may be performed in order to promote the polymerization reaction after exposure. Since the photosensitive coloring composition has low-temperature curability, it can be sufficiently cured according to a heat treatment at 100° C. or lower.

The film thickness of pixels constituting the color filter is 0.5 μm to 2.0 μm, and more preferably 1.0 to 2.0 μm.

In addition, red pixels, green pixels, and blue pixels constituting the color filter have the following spectral characteristics so that a high-quality organic EL display device having high luminance and high color reproducibility can be obtained.

red pixel: the maximum transmittance of light in a wavelength range of 450 nm to 560 nm is 0.5% or less, and the maximum transmittance of light in a wavelength range of 600 nm to 700 nm is 80% or more and less than 100%.

green pixel: the maximum transmittance of light in a wavelength range of 400 nm to 470 nm is 2% or less, the maximum transmittance of light at a wavelength of 525 to 535 nm is 67% or more, the 50% half-value wavelength on the short wavelength side is 497 to 507 nm, and the 50% half-value wavelength on the long wavelength side is 554 to 581 nm.

blue pixel: the maximum transmittance of light in a wavelength range of 500 nm to 560 nm is less than 20%.

Since each pixel of the color filter has the above spectral characteristics, a color filter has a wide color gamut.

### [Organic EL Layer]

The organic EL layer can be formed of a single organic light emitting layer containing a light emitting material or a plurality layers thereof. When formed in a plurality of layers, for example, a 3-layer configuration in which a general hole transport layer, an electron transporting organic light emitting layer, and an electron transport layer are sequentially laminated, or a multi-layer configuration in which hole (electron) injection layer, a hole (electron) transport layer and a layer that separates the injection function and the transport function are provided or a layer that blocks hole (electron) transport is provided may be used.

As an example of the organic EL layer, a configuration in which an anode, an organic layer and a cathode are laminated in order from the side of the silicon substrate, and airtightly covered with a sealing layer may be exemplified.

The anode is provided on the silicon substrate and is formed of a conductive material with a large work function. Examples of conductive materials with a large work function include nickel, silver, gold, platinum, palladium, selenium, rhodium, ruthenium, iridium, rhenium, tungsten, molybdenum, chromium, tantalum, niobium and alloys thereof, tin oxide (SnO₂), indium tin oxide (ITO), zinc oxide, and titanium oxide.

The cathode is formed using a conductive material with a small work function. As such a conductive material, for example, alloys of active metals such as Li, Mg, and Ca and metals such as Ag, Al, and In, or a structure in which these are laminated can be used. In addition, for example, a structure in which a thin compound layer of active metals such as Li, Mg, and Ca, a halogen such as fluorine or bromine, oxygen or the like is inserted into the organic layer may be used.

The anode and the cathode are patterned into a suitable shape according to a method of driving a display device. For example, when a method of driving an organic EL display device is a simple matrix method, the anode and the cathode are formed in stripes that intersect with each other and the intersections of these stripes become organic EL elements.

The organic layer has at least a white-light emitting layer, but is generally composed of a plurality of organic layers, and it may have a charge injection layer such as a hole injection layer and an electron injection layer, a hole transport layer that transports holes to a white-light emitting layer, and a charge transport layer such as an electron transport layer that transports electrons to a white-light emitting layer.

A known light emitting layer can be used as long as it emits white light. White-light emission properties may include light emission in at least three regions: red region (600 nm to 780 nm), green region (475 nm to 600 nm) and blue region (380 nm to 475 nm). The number of light emission peaks does not necessarily need to be three or more, and for example, even if there are two light emission peaks, it is sufficient that light be emitted in the above region. However, in order to obtain wide color reproducibility, it is preferable to use a white-light emitting layer with three or more light emission peaks, and one or more of the above three color regions preferably have a light emission peak.

The material constituting such a white-light emitting layer is not particularly limited as long as it emits fluorescence or phosphorescence. In addition, the light emitting material may have hole transport properties and electron transport properties. Examples of light emitting materials include pigment materials, metal complex materials, and polymer materials.

Examples of pigment materials include cyclopentamine derivatives, tetraphenyl butadiene derivatives, triphenylamine derivatives, oxadiazole derivatives, pyrazoloquinoline derivatives, distyrylbenzene derivatives, distyrylarylene derivatives, silole derivatives, thiophene ring compounds, pyridine ring compounds, perinone derivatives, perylene derivatives, oligothiophene derivatives, trifmarylamine derivatives, oxadiazole dimers, and pyrazoline dimers.

Examples of metal complex materials include aluminum quinolinol complexes, benzoquinolinol beryllium complexes, benzoxazole zinc complexes, benzothiazole zinc complexes, azomethyl zinc complexes, porphyrin zinc complexes, and europium complexes, and metal complexes containing Al, Zn, Be or the like or a rare earth metal such as Tb, Eu, or Dy as central metals, and having oxadiazole, thiadiazole, phenylpyridine, phenylbenzimidazole, and quinoline structures as ligands.

Examples of polymer materials include polyparaphenylene vinylene derivatives, polythiophene derivatives, polyparaphenylene derivatives, polysilane derivatives, polyacetylene derivatives, polyfluorene derivatives, polyvinylcarbazole derivatives, and materials obtained by polymerizing the above pigment materials and metal complex materials.

Examples of methods of forming the white-light emitting layer include an evaporation method, a printing method, an inkjet method, a spin coating method, a casting method, a dipping method, a bar coating method, a blade coating method, a roll coating method, a gravure coating method, a flexographic printing method, a spray coating method, and a self-organization method (an interaction adsorption method and a self-organization monomolecular membrane method). In particular, it is preferable to use an evaporation method, a spin coating method, and an inkjet method, and the film thickness of the white-light emitting layer is generally about 5 nm to 5 μm.

In addition, in the organic EL layer, a hole injection layer may be formed between the white-light emitting layer and the anode. This is because, when the hole injection layer is provided, injection of holes into the white-light emitting layer can be stabilized, and the light emitting efficiency can increase. As a material for forming the hole injection layer, a material that is generally used for the hole injection layer of the organic EL element can be used. In addition, the material for forming the hole injection layer may be any material that has either hole injection properties or electron barrier properties.

Specific examples of materials for forming the hole injection layer include triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, polysilane and aniline copolymers, and conductive polymer oligomers such as thiophene oligomers.

In addition, examples of materials for forming the hole injection layer include porphyrin compounds, aromatic tertiary amine compounds, and styrylamine compounds. The film thickness of the hole injection layer is generally about 5 nm to 1 μm.

In addition, in the organic EL layer, an electron injection layer may be formed between the white-light emitting layer and the cathode. When the electron injection layer is provided, injection of electrons into the white-light emitting layer can be stabilized, and the light emitting efficiency can increase.

Examples of materials for forming the electron injection layer include nitro-substituted fluorene derivatives, anthraquinodimethane derivatives, diphenylquinone derivatives, thiopyran dioxide derivatives, heterocyclic tetracarboxylic acid anhydrides such as naphthalene perylene, carbodiimide, fluorenylidene methane derivatives, anthraquinodimethane, anthrone derivatives, oxadiazole derivatives, thiazole derivatives in which oxygen atoms of oxadiazole rings of oxadiazole derivatives are substituted with sulfur atoms, quinoxaline derivatives with a quinoxaline ring known as an electron withdrawing group, metal complexes of 8-quinolinol derivatives such as tris(8-quinolinol)aluminium, phthalocyanine, metal phthalocyanine, and distyrylpyrazine derivatives.

### EXAMPLES

Hereinafter, the present disclosure will be described with reference to examples. Here, “parts” and “%” in examples indicate “parts by weight” and “weight %,” respectively.

### <Preparation of Colorant>

### (Refined Red Pigment (PR177-1))

150 parts of dianthraquinone pigment C. I. Pigment Red 177 (“CinilexRedSR3C” CINIC Chemicals), 1,500 parts of sodium chloride, and 250 parts of diethylene glycol were put into a 1-gallon stainless steel kneader (commercially available from Inoue Co., Ltd.) and kneaded at 60° C. for 10 hours. Next, the kneaded mixture was put into warm water and stirred for 1 hour while heating at about 70° C. to form a slurry, the sample was filtered and washed with water to remove a salt and diethylene glycol, and then dried at 80° C. overnight and pulverized, and thereby 138 parts of an anthraquinone fine pigment (PR177-1) was obtained.

### (Refined Red Pigment (PR254-1))

200 parts of diketopyrrolopyrrole red pigment C. I. Pigment Red 254 (“Irgajin RedL 3630” commercially available from BASF), 1,400 parts of sodium chloride, and 360 parts of diethylene glycol were put into a 1-gallon stainless steel kneader (commercially available from Inoue Co., Ltd.), and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a diketopyrrolopyrrole refined red pigment (PR254-1) was obtained.

### (Refined Yellow Pigment (PY139-1))

200 parts of Yellow Pigment C. I. Pigment Yellow 139 (“Paliotol Yellow D1819” commercially available from BASF Japan Ltd.), 1,400 parts of sodium chloride, and 360 parts of diethylene glycol were put into a 1-gallon stainless steel kneader (commercially available from Inoue Co., Ltd.) and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a refined yellow pigment (PY139-1) was obtained.

### (Refined Yellow Pigment (PY185-1))

200 parts of C. I. Pigment Yellow 185 (“Paliotol Yellow L 1155” commercially available from BASF) as a yellow colorant, 1,000 parts of sodium chloride, and 100 parts of diethylene glycol were put into a 1-gallon stainless steel kneader (commercially available from Inoue Co., Ltd.) and kneaded at 100° C. for 6 hours. Next, the kneaded product was put into 5 L of warm water and stirred for 1 hour while heating at 70° C. to form a slurry, the sample was repeatedly filtered and washed with water to remove sodium chloride and diethylene glycol and then dried at 80° C. overnight, and thereby a refined yellow pigment (PY185-1) was obtained.

### (Refined Yellow Pigment (PY185-2))

95 parts of C. I. Pigment Yellow 185 (“Paliotol Yellow L 1155” commercially available from BASF) as a yellow colorant, 10 parts of a rosin maleate resin (“Malkyd 32” commercially available from Arakawa Chemical Industries, Ltd.), 1,200 parts of sodium chloride, and 120 parts of diethylene glycol were put into a 1-gallon stainless steel kneader (commercially available from Inoue Co., Ltd.) and kneaded at 60° C. for 8 hours. Next, the kneaded product was put into 8,000 parts of warm water and stirred for 1 hour while heating at about 70° C. to form a slurry, the sample was repeatedly filtered and washed with water to remove sodium chloride and diethylene glycol and then dried at 80° C. overnight, and thereby 105 parts of a refined yellow pigment (PY185-2) was obtained.

### (Refined Green Pigment (PG36-1))

120 parts of phthalocyanine pigment C. I. Pigment Green 36 (“Lionol Green 6YK” commercially available from Toyocolor Co., Ltd.), 1,600 parts of sodium chloride, and 270 parts of diethylene glycol were put into a 1-gallon stainless steel kneader (commercially available from Inoue Co., Ltd.) and kneaded at 70° C. for 12 hours. The mixture was put into 5,000 parts of warm water and stirred for 1 hour while heating at about 70° C. to form a slurry, the sample was repeatedly filtered and washed with water to remove a salt and a solvent and then dried at 80° C. overnight, and thereby 117 parts of a refined pigment (PG36-1) was obtained.

### (Refined Green Pigment (PG58-1))

200 parts of phthalocyanine green pigment C. I. Pigment Green 58 (“FASTOGEN GREEN A110” commercially available from DIC), 1,400 parts of sodium chloride, and 360 parts of diethylene glycol were put into a 1-gallon stainless steel kneader (commercially available from Inoue Co., Ltd.), and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a phthalocyanine refined green pigment (PG58-1) was obtained.

### (Refined Green Pigment (PG62-1))

200 parts of phthalocyanine green pigment C. I. Pigment Green 62 (commercially available from Toyocolor Co., Ltd.), 1,400 parts of sodium chloride, and 360 parts of diethylene glycol were put into a 1-gallon stainless steel kneader (commercially available from Inoue Co., Ltd.) and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a phthalocyanine refined green pigment (PG62-1) was obtained.

(Refined green pigment (PG63-1))

200 parts of phthalocyanine green pigment C. I. Pigment Green 63 (commercially available from Toyocolor Co., Ltd.), 1,400 parts of sodium chloride, and 360 parts of diethylene glycol were put into a 1-gallon stainless steel kneader (commercially available from Inoue Co., Ltd.) and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a phthalocyanine refined green pigment (PG63-1) was obtained.

### (Refined Green Pigment (PG59-1))

59 100 parts of C. I. Pigment Green, 1,200 parts of sodium chloride, and 120 parts of diethylene glycol were put into a 1-gallon stainless steel kneader (commercially available from Inoue Co., Ltd.) and kneaded at 70° C. for 6 hours. The kneaded product was put into 3,000 parts of warm water and stirred for 1 hour while heating at 70° C. to form a slurry, the sample was repeatedly filtered and washed with water to remove sodium chloride and diethylene glycol and then dried at 80° C. overnight, and thereby a refined pigment (PG59-1) was obtained.

(Refined blue pigment (PB15:6-1))

200 parts of phthalocyanine blue pigment C. I. Pigment Blue 15:6 (“LIONOL BLUE ES” commercially available from Toyocolor Co., Ltd., a specific surface area of 60 m²/g), 1,400 parts of sodium chloride, and 360 parts of diethylene glycol were put into a 1-gallon stainless steel kneader (commercially available from Inoue Co., Ltd.) and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a phthalocyanine refined blue pigment (PB15:6-1) was obtained.

(Refined blue pigment (PB15:3-1))

200 parts of phthalocyanine blue pigment (C. I. Pigment Blue 15:3, “LIONOL BLUE FG-7351” commercially available from Toyocolor Co., Ltd.), 600 parts of sodium chloride, and 600 parts of diethylene glycol were put into a 1-gallon stainless steel kneader (commercially available from Inoue Co., Ltd.) and kneaded at 120° C. for 8 hours. Next, the kneaded product was put into 5 L of warm water and stirred for 1 hour while heating at 70° C. to form a slurry, the sample was repeatedly filtered and washed with water to remove sodium chloride and diethylene glycol and then dried at 80° C. overnight, and thereby a phthalocyanine refined blue pigment (PB15:3-1) was obtained.

### (Refined Purple Pigment (PV23-1))

200 parts of dioxazine purple pigment C. I. Pigment Violet 23 (“LIONOGEN VIOLET RL” commercially available from Toyocolor Co., Ltd.), 1,400 parts of sodium chloride, and 360 parts of diethylene glycol were put into a 1-gallon stainless steel kneader (commercially available from Inoue Co., Ltd.) and kneaded at 80° C. for 6 hours. Next, the kneaded product was put into 8,000 parts of warm water and stirred for 2 hours while heating at 80° C. to form a slurry, the sample was repeatedly filtered and washed with water to remove sodium chloride and diethylene glycol and then dried at 85° C. overnight, and thereby a dioxazine refined purple pigment (PV23-1) was obtained.

### (Production of Salt-Forming Compound (V))

A salt-forming compound (V) including C. I. Acid Red 289 and tristearylmonomethylammonium chloride as a quaternary ammonium salt compound was produced by the following procedure. 10 parts of C. I. Acid Red 289 was dissolved in 200 parts of water and heated at 30 to 50° C. so that a 5% aqueous solution was obtained, and 5.5 parts of tristearylmonomethylammonium chloride was then dissolved in a solution containing methanol/water=20/80 to obtain a 5% solution, and the solution was added dropwise little by little. A tristearylmonomethylammonium chloride solution was added dropwise and then stirred at 30 to 50° C. for 3 hours. After being cooled to room temperature while stirring, suction filtration was performed, and after washing with water, the salt-forming compound remaining on the filter paper was dried with a dryer to remove water, and thereby 8 parts of a salt-forming compound (V) including C. I. Acid Red 289 and tristearylmonomethylammonium chloride was obtained.

### <Production of Dispersant Solution>

### (Dispersant Solution 1): Photosensitive Resin

8 parts of 3-mercapto-1,2-propanediol, 12 parts of pyromellitic anhydride, 80 parts of propylene glycol monomethyl ether acetate (PGMAc), and 0.2 parts of monobutyltin oxide as a catalyst were put into a reaction container including a gas introduction pipe, a thermometer, a condenser, and a stirrer, and after purging with nitrogen gas, the mixture was reacted at 120° C. for 5 hours (first step). The acid value was measured and it was confirmed that 95% or more of an acid anhydride was half-esterified. Next, 15 parts of methyl methacrylate (MMA), 10 parts of t-butyl acrylate (tBA), 10 parts of ethyl acrylate (EA), 5 parts of methacrylic acid (MAA), 10 parts of benzyl methacrylate (BzMA), and 50 parts of 2-hydroxyethyl methacrylate (HEMA) were put thereinto and the inside of the reaction container was heated at 80° C., and 1 part of 2,2′-azobis(2,4-dimethylvaleronitrile) was added and the mixture was reacted for 12 hours (second step). The solid content was measured, and it was confirmed that 95% of the mixture was reacted. Next, the inside of the flask was purged with air, 54.0 parts of 2-methacryloyloxyethyl isocyanate (MOI) and 0.1 parts of hydroquinone were put thereinto, and the mixture was reacted at 70° C. for 4 hours (third step). After it was confirmed with IR that the peak at 2,270 cm⁻¹ based on the isocyanate group had disappeared, the reaction solution was cooled, the solid content was adjusted with PGMAc, and thereby a dispersant solution 1, which is a photosensitive resin having a solid content of 40%, was obtained. The obtained dispersant had an acid value of 36 and a weight average molecular weight of 12,000.

### (Dispersant Solution 2): Non-Photosensitive

30 parts of ethyl acrylate, 20 parts of tert-butyl acrylate, and 40 parts of 2-methyl methacrylate were put into a reaction container including a gas introduction pipe, a thermometer, a condenser, and a stirrer, and purging with nitrogen gas was performed. The inside of the reaction container was heated at 80° C., a solution in which 0.1 parts of 2,2′-azobisisobutyronitrile was dissolved in 45.7 parts of cyclohexanone was added to 6 parts of 3-mercapto-1,2-propanediol, and the mixture was reacted for 10 hours. The solid content was measured, and it was confirmed that 95% of the mixture was reacted. In this case, the weight average molecular weight was 4,000. Next, 9.7 parts of pyromellitic dianhydride, 70 parts of PGMAc, and 0.20 parts of 1,8-diazabicyclo-[5.4.0]-7-undecene as a catalyst were added and the mixture was reacted at 120° C. for 7 hours. The acid value was measured and it was confirmed that 98% or more of an acid anhydride was half-esterified, and the reaction was completed. After the reaction was completed, the non-volatile content was adjusted to 40 weight %, and thereby a PGMAc solution of a dispersant having a weight average molecular weight of 8,100, an acid value of 50 mg KOH/g, and a glass transition temperature of 22.5° C. of a vinyl polymerization moiety (dispersant solution 2) was obtained.

### <Production of Binder Resin>

### (Acrylic Resin Solution (D-1)): Photosensitive Resin

100 parts of propylene glycol monomethyl ether acetate was put into a reaction container in which a thermometer, a cooling pipe, a nitrogen gas introduction pipe, and a stirring device were attached to a separable 4-neck flask, heating was performed to 120° C. while nitrogen gas was injected into the container, and at the same temperature, a mixture containing 5.2 parts of styrene, 35.5 parts of glycidyl methacrylate, 41.0 parts of dicyclopentanyl methacrylate, and 1.0 part of azobisisobutyronitrile was added dropwise from a dropping pipe over 2.5 hours and a polymerization reaction was performed. Next, the inside of the flask was purged with air, 0.3 parts of trisdimethylaminomethylphenol and 0.3 parts of hydroquinone were added to 17.0 parts of acrylic acid, the reaction was continued at 120° C. for 5 hours, the reaction was completed when the acid value of the solid content reached 0.8, and a resin solution having a weight average molecular weight of about 12,000 (measurement through GPC) was obtained.

In addition, 30.4 parts of tetrahydrophthalic anhydride and 0.5 parts of triethylamine were added, the mixture was reacted at 120° C. for 4 hours, propylene glycol monomethyl ether acetate was added so that the non-volatile content was 20%, and an acrylic resin solution (D-1) was prepared.

### (Acrylic Resin Solution (D-2)): Photosensitive Resin

182 g of propylene glycol monomethyl ether acetate was introduced into a flask including a stirrer, a thermometer, a reflux cooling pipe, a dropping funnel and a nitrogen introduction pipe, the atmosphere in the flask was changed from air to nitrogen, the temperature was then raised to 100° C., and a solution obtained by adding 3.6 g of azobisisobutyronitrile to a mixture containing 70.5 g (0.40 mol) of benzyl methacrylate, 43.0 g (0.5 mol) of methacrylic acid, 22.0 g (0.10 mol) of monomethacrylate with a tricyclodecane framework (FA-513M commercially available from Hitachi Chemical Company) and 136 g of propylene glycol monomethyl ether acetate was then added dropwise to the flask from a dropping funnel over 2 hours, and stirring was additionally continued at 100° C. for 5 hours. Next, the atmosphere in the flask was changed from nitrogen to air, 35.5 g of glycidyl methacrylate [0.25 mol, (50 mol % with respect to the carboxyl group of methacrylic acid used in this reaction)], 0.9 g of trisdimethylaminomethylphenol and 0.145 g of hydroquinone were put into the flask, the reaction was continued at 110° C. for 6 hours, propylene glycol monomethyl ether acetate was added so that the non-volatile content was 20%, and an acrylic resin solution (D-2) having a solid content acid value of 79 mg KOH/g was obtained. The weight average molecular weight in terms of polystyrene measured through GPC was 13,000 and the molecular weight distribution (Mw/Mn) was 2.1.

### (Acrylic Resin Solution (D-3)): Non-Photosensitive

196 parts of cyclohexanone was put into a reaction container in which a thermometer, a cooling pipe, a nitrogen gas introduction pipe, a dropping pipe and a stirring device were attached to a separable 4-neck flask, the temperature was raised to 80° C., the inside of the reaction container was purged with nitrogen, and a mixture containing 20.0 parts of benzyl methacrylate, 17.2 parts of n-butyl methacrylate, 12.9 parts of 2-hydroxyethyl methacrylate, 12.0 parts of methacrylic acid, 20.7 parts of paracumylphenol ethylene oxide-modified acrylate (“ARONIX M110” commercially available from Toagosei Co., Ltd.), and 1.1 parts of 2,2′-azobisisobutyronitrile was then added dropwise from a dropping pipe over 2 hours. After dropwise addition was completed, the reaction was additionally continued for 3 hours, and an acrylic resin solution was obtained.

After being cooled to room temperature, about 2 parts of the resin solution was sampled, heated and dried at 180° C. for 20 minutes, the non-volatile content was measured, propylene glycol monomethyl ether acetate was added to the resin solution synthesized previously so that the non-volatile content was 20 mass %, and an acrylic resin solution (D-3) was prepared. The weight average molecular weight (Mw) was 26,000.

### <Production of Pigment Dispersing Element>

### (Pigment Dispersing Element (PR-1))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PR-1) having a non-volatile component of 20 weight % was produced.

| | |
|---|---|
| refined red pigment (PR177-1): | 14.8 parts |
| dispersant solution 1 (photosensitive resin): | 13.0 parts |
| propylene glycol monomethyl ether acetate: | 72.2 parts |

(Pigment dispersing element (PR-2))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PR-2) having a non-volatile component of 20 weight % was produced.

| | |
|---|---|
| refined red pigment (PR254-1): | 14.8 parts |
| dispersant solution 1 (photosensitive resin): | 13.0 parts |
| propylene glycol monomethyl ether acetate: | 72.2 parts |

### (Pigment Dispersing Element (PY-1))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PY-1) having a non-volatile component of 20 weight % was produced.

| | |
|---|---|
| refined yellow pigment (PY139-1): | 14.0 parts |
| dispersant solution 2 (non-photosensitive): | 15.0 parts |
| propylene glycol monomethyl ether acetate: | 71.0 parts |

### (Pigment Dispersing Element (PY-2))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PY-2) having a non-volatile component of 20 weight % was produced.

| | |
|---|---|
| refined yellow pigment (PY185-1): | 12.0 parts |
| dispersant solution 1 (photosensitive resin): | 20.0 parts |
| propylene glycol monomethyl ether acetate: | 68.0 parts |

### (Pigment Dispersing Element (PY-3))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PY-3) having a non-volatile component of 20 weight % was produced.

| | |
|---|---|
| refined yellow pigment (PY185-2): | 12.0 parts |
| dispersant solution 1 (photosensitive resin): | 20.0 parts |
| propylene glycol monomethyl ether acetate: | 68.0 parts |

### (Pigment Dispersing Element (PY-4))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PY-4) having a non-volatile component of 20 weight % was produced.

| | |
|---|---|
| refined yellow pigment (PY185-1): | 12.0 parts |
| dispersant solution 2 (non-photosensitive): | 20.0 parts |
| propylene glycol monomethyl ether acetate: | 68.0 parts |

### (Pigment Dispersing Element (PG-1))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PG-1) having a non-volatile component of 20 weight % was produced.

| | |
|---|---|
| refined green pigment (PG36-1): | 15.0 parts |
| dispersant solution 2 (non-photosensitive): | 12.5 parts |
| propylene glycol monomethyl ether acetate: | 72.5 parts |

### (Pigment Dispersing Element (PG-2))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PG-2) having a non-volatile component of 20 weight % was produced.

| | |
|---|---|
| refined green pigment (PG58-1): | 15.0 parts |
| dispersant solution 2 (non-photosensitive): | 12.5 parts |
| propylene glycol monomethyl ether acetate: | 72.5 parts |

### (Pigment Dispersing Element (PG-3))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PG-3) having a non-volatile component of 20 weight % was produced.

| | |
|---|---|
| refined green pigment (PG62-1): | 15.0 parts |
| dispersant solution 2 (non-photosensitive): | 12.5 parts |
| propylene glycol monomethyl ether acetate: | 72.5 parts |

### (Pigment Dispersing Element (PG-4))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PG-4) having a non-volatile component of 20 weight % was produced.

| | |
|---|---|
| refined green pigment (PG63-1): | 15.0 parts |
| dispersant solution 2 (non-photosensitive): | 12.5 parts |
| propylene glycol monomethyl ether acetate: | 72.5 parts |

### (Pigment Dispersing Element (PG-5))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PG-5) having a non-volatile component of 20 weight % was produced.

| | |
|---|---|
| refined green pigment (PG59-1): | 15.0 parts |
| dispersant solution 2 (non-photosensitive): | 12.5 parts |
| propylene glycol monomethyl ether acetate: | 72.5 parts |

### (Pigment Dispersing Element (PB-1))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PB-1) having a non-volatile component of 20 weight % was produced.

| | |
|---|---|
| refined blue pigment (PB15: 3-1): | 13.0 parts |
| dispersant solution 2 (non-photosensitive): | 17.5 parts |
| propylene glycol monomethyl ether acetate: | 69.5 parts |

### (Pigment Dispersing Element (PB-2))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PB-2) having a non-volatile component of 17 weight % was produced.

| | |
|---|---|
| refined blue pigment (PB15: 6-1): | 11.9 parts |
| dispersant solution 1 (photosensitive resin): | 12.8 parts |
| propylene glycol monomethyl ether acetate: | 75.4 parts |

### (Pigment Dispersing Element (PV-1))

The following mixture was stirred and mixed so that it became uniform and then dispersed in IGER mill (“Mini Model M-250 MKII” commercially available from IGER Japan) using zirconia beads with a diameter of 0.5 mm for 3 hours, and then filtered through a 5.0 μm filter, and a pigment dispersing element (PV-1) having a non-volatile component of 17 weight % was produced.

| | |
|---|---|
| refined purple pigment (PV23-1): | 12.0 parts |
| dispersant solution 1 (photosensitive resin): | 15.0 parts |
| propylene glycol monomethyl ether acetate: | 73.0 parts |

### <Method of Producing Salt-Forming Compound-Containing Solution (SV)>

The following mixture was stirred and mixed so that it became uniform and then filtered through a 5.0 μm filter, and a salt-forming compound-containing solution (SV) was produced.

| | |
|---|---|
| salt-forming compound (V): | 13.00 parts |
| cyclohexanone: | 87.00 parts |

### <Production of Photosensitive Coloring Composition>

### Production Example 1

(Photosensitive coloring composition (R-1))

The following mixture was stirred and mixed so that it became uniform and then filtered through a 1.0 μm filter, and a photosensitive coloring composition (R-1) was obtained.

| | | |
|---|---|---|
| pigment dispersing element (PR-1): | 52.70 | parts |
| pigment dispersing element (PR-2): | 17.57 | parts |
| pigment dispersing element (PY-1): | 18.57 | parts |
| photopolymerizable monomer (B-1): | 2.12 | parts |
| photopolymerization initiator (C-1): | 0.10 | parts |
| leveling agent (non-volatile content 1%): | 1.00 | part |
| solvent (S-1): | 7.94 | parts |

### Production Examples 2 to 69

(Preparation of photosensitive coloring compositions (R-2 to 69))

Photosensitive coloring compositions (R-2 to 69) were obtained in the same manner as in the photosensitive coloring composition (R-1) except that types and addition amounts of pigment dispersing elements, photopolymerizable monomers, photopolymerization initiators, and resin solutions were changed to those shown in Tables 1 to 7.

TABLE 1
Red photosensitive coloring composition

| | | Production | Production | Production | Production | Production | Production |
|---|---|---|---|---|---|---|---|
| | | Example 1 | Example 2 | Example 3 | Example 4 | Example 5 | Example 6 |
| | | R-1 | R-2 | R-3 | R-4 | R-5 | R-6 |
| Pigment dispersing | | PR-1 | PR-1 | PR-1 | PR-1 | PR-1 | PR-1 |
| element 1 | | 52.70 | 52.70 | 52.70 | 52.70 | 52.70 | 52.70 |
| Pigment dispersing | | PR-2 | PR-2 | PR-2 | PR-2 | PR-2 | PR-2 |
| element 2 | | 17.57 | 17.57 | 17.57 | 17.57 | 17.57 | 17.57 |
| Pigment dispersing | | PY-1 | PY-1 | PY-1 | PY-1 | PY-1 | PY-1 |
| element 3 | | 18.57 | 18.57 | 18.57 | 18.57 | 18.57 | 18.57 |
| Photopolymerizable | compound of | B-1 | B-1 | B-1 | B-1 | B-2 | B-3 |
| monomer (B) | General Formula (1) | 2.12 | 2.02 | 2.02 | 2.02 | 2.12 | 2.12 |
| | other compounds | | | | | | |
| Photopolymerization | oxime ester type | C-1 | C-1 | C-1 | C-1 | C-1 | C- [symbol] |
| initiator (C) | | 0.10 | 0.10 | 0.10 | 0.10 | 0.10 | 0.10 |
| | other | | | | | | |
| Resin solution | photosensitive | | D-1 | D-2 | | | |
| | resin | | 0.50 | 0.50 | | | |
| | non-photosensitive | | | | D-3 | | |
| | resin | | | | [symbol] .50 | | |

| | | | | | | |
|---|---|---|---|---|---|---|
| Leveling agent | 1.00 | 1.00 | 1.00 | 1.00 | 1.00 | 1.00 |
| Solvent 1 | S-1 | S-1 | S-1 | S-1 | S-1 | S-1 |
| | 7.94 | 7.54 | 7.54 | 7.54 | 7.94 | 7.94 |
| Solvent 2 | | | | | | |
| Sum | 100.00 | 100.00 | 100.00 | 100.00 | 100.00 | 100.00 |
| NV | 20.00 | 20.00 | 20.00 | 20.00 | 20.00 | 20.00 |
| Viscosity | 3.80 | 3.80 | 3.80 | 3.80 | 3.80 | 3.80 |

| | | Production | Production | Production | Production |
|---|---|---|---|---|---|
| | | Example 7 | Example 8 | Example 9 | Example 10 |
| | | R-7 | R-8 | R-9 | R-10 |
| Pigment dispersing | | PR-1 | PR-1 | PR-1 | PR-1 |
| element 1 | | 52.70 | 52.70 | 52.70 | 52.70 |
| Pigment dispersing | | PR-2 | PR-2 | PR-2 | PR-2 |
| element 2 | | 17.57 | 17.57 | 17.57 | 17.57 |
| Pigment dispersing | | PY-1 | PY-1 | PY-1 | PY-1 |
| element 3 | | 18.57 | 18.57 | 18.57 | 18.57 |
| Photopolymerizable | compound of | B-1 | B-1 | B-1 | B-1 |
| monomer (B) | General Formula (1) | 1.0 [symbol] | 2.12 | 2.12 | 2.12 |
| | other compounds | | | | |
| Photopolymerization | oxime ester type | C-1 | C-2 | C-3 | C-1 |
| initiator (C) | | 0.10 | 0.10 | 0.10 | 0.0 [symbol] |
| | other | | | | C-4 |
| Resin solution | photosensitive | | | | 0.01 |
| | resin | | | | |
| | non-photosensitive | | | | |
| | resin | | | | |

| | | | | |
|---|---|---|---|---|
| Leveling agent | 1.00 | 1.00 | 1.00 | 1.00 |
| Solvent 1 | S-1 | S-1 | S-1 | S-1 |
| | 7.94 | 7.94 | 7.94 | 7.94 |
| Solvent 2 | | | | |
| Sum | 98.94 | 100.00 | 100.00 | 100.00 |
| NV | 20.00 | 20.00 | 20.00 | 20.00 |
| Viscosity | 3.80 | 3.80 | 3.80 | 3.80 |

[symbol]

indicates data missing or illegible when filed

TABLE 2
Red photosensitive coloring composition

| | | Production | Production | Production | Production |
|---|---|---|---|---|---|
| | | Example 11 | Example 12 | Example 13 | Example 14 |
| | | R-11 | R-12 | R-13 | R-14 |
| Pigment dispersing element 1 | | PR-1 | PR-1 | PR-1 | PR-1 |
| | | [symbol] 8.31 | 57.09 | 52.70 | 52.70 |
| Pigment dispersing element 2 | | PR-2 | PR-2 | PR-2 | PR-2 |
| | | 21.96 | 13.18 | 21.96 | 13.18 |
| Pigment dispersing element 3 | | PY-1 | PY-1 | PY-1 | PY-1 |
| | | 18.57 | 18.57 | 13.93 | 23.21 |
| Photopolymerizable | compound of General | B-1 | B-1 | B-1 | B-1 |
| monomer (B) | Formula (1) | 2.12 | 2.12 | 2.12 | 2.07 |
| | other compounds | | | | |
| Photopolymerization | oxime ester type | C-1 | C-1 | C-1 | C-1 |
| initiator (C) | | 0.10 | 0.10 | 0.10 | 0.10 |
| | other | | | | |
| Resin solution | photosensitive resin | | | D-1 | |
| | | | | 0.25 | |
| | non-photosensitive resin | | | | |
| Leveling agent | | 1.00 | 1.00 | 1.00 | 1.00 |
| Solvent 1 | | S-1 | S-1 | S-1 | S-1 |
| | | 7.94 | 7.94 | 7.94 | 7.74 |
| Solvent 2 | | | | | |
| Sum | | 100.00 | 100.00 | 100.00 | 100.00 |
| NV | | 20.00 | 20.00 | 20.00 | 20.00 |
| Viscosity | | 3.80 | 3.80 | 3.80 | 3.80 |
| | | Production | Production | Production | Production |
| | | Example 15 | Example 16 | Example 64 | Example 65 |
| | | R-15 | R-16 | R-64 | R-65 |
| Pigment dispersing element 1 | | PR-1 | PR-1 | PR-1 | PR-1 |
| | | 52.70 | 52.70 | 52.70 | 52.70 |
| Pigment dispersing element 2 | | PR-2 | PR-2 | PR-2 | PR-2 |
| | | 17.57 | 17.57 | 17.57 | 17.57 |
| Pigment dispersing element 3 | | PY-1 | PY-1 | PY-1 | PY-1 |
| | | 18.57 | 18.57 | 18.57 | 18.57 |
| Photopolymerizable | compound of General | | B-1 | B-1 | B-1 |
| monomer (B) | Formula (1) | | 2.12 | 2.12 | 2.12 |
| | other compounds | B-4 | | | |
| | | 2.12 | | | |
| Photopolymerization | oxime ester type | C-1 | | C-1 | C-1 |
| initiator (C) | | 0.10 | | 0.10 | 0.10 |
| | other | | C-4 | | |
| | | | 0.10 | | |
| Resin solution | photosensitive resin | | | | |
| | non-photosensitive resin | | | | |

| Leveling agent | 1.00 | 1.00 | 1.00 | 1.00 |
|---|---|---|---|---|
| Solvent 1 | S-1 | S-1 | S-1 | S-1 |
| | 7.94 | 7.94 | 4.94 | 4.94 |
| Solvent 2 | | | S-2 | S-3 |
| | | | 3.00 | 3.00 |
| Sum | 100.00 | 100.00 | 100.00 | 100.00 |
| NV | 20.00 | 20.00 | 20.00 | 20.00 |
| Viscosity | 3.80 | 3.80 | 3.80 | 3.80 |

[symbol]

indicates data missing or illegible when filed

TABLE 3
Green photosensitive coloring composition

| | | Production | Production | Production | Production | Production | Production |
|---|---|---|---|---|---|---|---|
| | | Example 17 | Example 18 | Example 19 | Example 20 | Example 21 | Example 22 |
| | | R-17 | R-18 | R-19 | R-20 | R-21 | R-22 |
| Pigment dispersing element 1 | | PY-2 | PY-2 | PY-2 | PY-2 | PY-2 | PY-2 |
| | | 46.80 | 46.80 | 46.80 | 46.80 | 46.80 | 46.80 |
| Pigment dispersing element 2 | | PG-1 | PG-1 | PG-1 | PG-1 | PG-1 | PG-1 |
| | | 26.35 | 26.35 | 26.35 | 26.35 | 26.35 | 26.35 |
| Pigment dispersing element 3 | | PB-1 | PB-1 | PB-1 | PB-1 | PB-1 | PB-1 |
| | | 6.40 | 6.40 | 6.40 | 6.40 | 6.40 | 6.40 |
| Photopolymerizable | compound of | B-2 | B-2 | B-2 | B-2 | B-1 | B-3 |
| monomer (B) | General Formula (1) | 3.35 | 3.10 | 3.10 | 3.10 | 3.35 | 3.35 |
| | other compounds | | | | | | |
| Photopolymerization | oxime ester type | C-1 | C-1 | C-1 | C-1 | C-1 | C-1 |
| initiator (C) | | 0.70 | 0.70 | 0.70 | 0.70 | 0.70 | 0.70 |
| | other | | | | | | |
| Resin solution | photosensitive | | D-1 | D-2 | | | |
| | resin | | 1.25 | 1.25 | | | |
| | non-photosensitive | | | | D-3 | | |
| | resin | | | | 1.25 | | |

| Leveling agent | 4.00 | 4.00 | 4.00 | 4.00 | 4.00 | 4.00 |
|---|---|---|---|---|---|---|
| Solvent 1 | S-1 | S-1 | S-1 | S-1 | S-1 | S-1 |
| | 12.40 | 1 [symbol] .40 | 1 [symbol] .40 | [symbol] .40 | 12.40 | 12.40 |
| Solvent 2 | | | | | | |
| Sum | 100.00 | 100.00 | 100.00 | 100.00 | 100.00 | 100.00 |
| NV | 20.00 | 20.00 | 20.00 | 20.00 | 20.00 | 20.00 |
| Viscosity | 3.80 | 3.80 | 3.80 | 3.80 | 3.80 | 3.80 |

| | | Production | Production | Production | Production | Production |
|---|---|---|---|---|---|---|
| | | Example 23 | Example 24 | Example 25 | Example 26 | Example 27 |
| | | R-23 | R-24 | R-25 | R-26 | R-27 |
| Pigment dispersing element 1 | | PY-2 | PY-2 | PY-2 | PY-2 | PY-3 |
| | | 46.80 | 46.80 | 46.80 | 46.80 | 46.80 |
| Pigment dispersing element 2 | | PG-1 | PG-1 | PG-1 | PG-1 | PG-1 |
| | | 26.35 | 26.35 | 26.35 | 26.35 | 26.35 |
| Pigment dispersing element 3 | | PB-1 | PB-1 | PB-1 | PB-1 | PB-1 |
| | | 6.40 | 6.40 | 6.40 | 6.40 | 6.40 |
| Photopolymerizable | compound of | B-2 | B-2 | B-2 | B-2 | B-2 |
| monomer (B) | General Formula (1) | [symbol] .35 | [symbol] .35 | 3.35 | 3.35 | 3.35 |
| | other compounds | B-4 | | | | |
| | | 1.01 | | | | |
| Photopolymerization | oxime ester type | C-1 | C-2 | C-3 | C-1 | C-1 |
| initiator (C) | | 0.7 | 0.7 | 0.7 | 0.6 | 0.7 |
| | other | | | | C-4 | |
| | | | | | 0.10 | |
| Resin solution | photosensitive | | | | | |
| | resin | | | | | |
| | non-photosensitive | | | | | |
| | resin | | | | | |

| Leveling agent | 4.00 | 4.00 | 4.00 | 4.00 | 4.00 |
|---|---|---|---|---|---|
| Solvent 1 | S-1 | S-1 | S-1 | S-1 | S-1 |
| | 12.40 | 12.40 | 12.40 | 12.40 | 12.40 |
| Solvent 2 | | | | | |
| Sum | 100.01 | 100.00 | 100.00 | 100.00 | 100.00 |
| NV | 20.00 | 20.00 | 20.00 | 20.00 | 20.00 |
| Viscosity | 3.80 | 3.80 | 3.80 | 3.80 | 3.80 |

[symbol]

indicates data missing or illegible when filed

TABLE 4
Green photosensitive coloring composition

| | | Production | Production | Production | Production | Production | Production |
|---|---|---|---|---|---|---|---|
| | | Example 28 | Example 29 | Example 30 | Example 31 | Example 32 | Example 33 |
| | | R-28 | R-29 | R-30 | R-31 | R-32 | R-3.3 |
| Pigment dispersing element 1 | | PY-2 | PY-2 | PY-2 | PY-2 | PY-2 | PY-2 |
| | | 46.80 | 42.47 | [symbol] 1.13 | [symbol] 1.13 | 42.47 | 46.80 |
| Pigment dispersing element 2 | | PG-2 | PG-1 | PG-1 | PG-1 | PG-1 | PG-1 |
| | | 30.40 | 29.81 | 22.88 | 26.35 | 26.35 | 26.35 |
| Pigment dispersing element 3 | | PB-1 | PB-1 | PB-1 | PB-1 | PB-1 | PB-1 |
| | | 6.40 | 6.40 | 6.40 | 2.40 | 10.40 | 6.40 |
| Photopolymerizable | compound of | B-2 | B-2 | B-2 | B-2 | B-2 | |
| monomer (B) | General Formula (1) | 2. [symbol] 4 | 3.19 | 3.18 | 3.19 | 3.18 | |
| | other compounds | | | | | | B- [symbol] |
| | | | | | | | [symbol] .35 |
| Photopolymerization | oxime ester type | C-1 | C-1 | C-1 | C-1 | C-1 | C-1 |
| initiator (C) | | 0.7 | 0.7 | 0.7 | 0.7 | 0.7 | 0.7 |
| | other | | | | | | |
| Resin solution | photosensitive | | D-1 | | D-1 | D-1 | |
| | resin | | 1.67 | | 0.47 | 1.20 | |
| | non-photosensitive | | | | | | |
| | resin | | | | | | |

| Leveling agent | 4.00 | 4.00 | 4.00 | 4.00 | 4.00 | 4.00 |
|---|---|---|---|---|---|---|
| Solvent 1 | S-1 | S-1 | S-1 | S-1 | S-1 | S-1 |
| | 9.16 | 11.76 | 11.71 | 11.76 | 11.71 | 12.40 |
| Solvent 2 | | | | | | |
| Sum | 100.00 | 100.00 | 100.00 | 100.00 | 100,00 | 100.00 |
| NV | 20.00 | 20.00 | 20.00 | 20.00 | 20.00 | 20.00 |
| Viscosity | 3.80 | 3.80 | 3.80 | 3.88 | 3.80 | 3.80 |

| | | Production | Production | Production | Production | Production |
|---|---|---|---|---|---|---|
| | | Example 34 | Example 50 | Example 51 | Example 52 | Example 53 |
| | | R-34 | R-50 | R-51 | R-52 | R-53 |
| Pigment dispersing element 1 | | PY-2 | PY-2 | PY-2 | PY-2 | PY-2 |
| | | 46.80 | 40.83 | 45.00 | 49.17 | 39.17 |
| Pigment dispersing element 2 | | PG-1 | PG-3 | PG-3 | PG-3 | PG-3 |
| | | 26.35 | 34.00 | 30.67 | 27.33 | 35.33 |
| Pigment dispersing element 3 | | PB-1 | | | | |
| | | [symbol] .40 | | | | |
| Photopolymerizable | compound of | B-2 | B-2 | B-2 | B-2 | B-2 |
| monomer (B) | General Formula (1) | [symbol] .35 | 4.29 | 4.13 | 3.96 | 4.36 |
| | other compounds | | | | | |
| Photopolymerization | oxime ester type | | C-1 | C-1 | C-1 | C-1 |
| initiator (C) | | | 0.70 | 0.70 | 0.70 | 0.70 |
| | other | C-4 | | | | |
| | | 0.70 | | | | |
| Resin solution | photosensitive | | | | | |
| | resin | | | | | |
| | non-photosensitive | | | | | |
| | resin | | | | | |

| Leveling agent | 4.00 | 4.00 | 4.00 | 4.00 | 4.00 |
|---|---|---|---|---|---|
| Solvent 1 | S-1 | S-1 | S-1 | S-1 | S-1 |
| | 12.40 | 16.17 | 15.51 | 14.84 | 16.44 |
| Solvent 2 | | | | | |
| Sum | 100.00 | 100.00 | 100.00 | 100.00 | 100.00 |
| NV | 20.00 | 20.00 | 20.00 | 20.00 | 20.00 |
| Viscosity | 3.80 | 3.80 | 3.80 | 3.80 | 3.80 |

[symbol]

indicates data missing or illegible when filed

TABLE 5
Green photosensitive coloring composition

| | | Production | Production | Production | Production | Production | Production |
|---|---|---|---|---|---|---|---|
| | | Example 54 | Example 55 | Example 56 | Example 57 | Example 58 | Example 59 |
| | | R-54 | R-55 | R-56 | R-57 | R-58 | R-59 |
| Pigment dispersing element 1 | | PY-2 | PY-2 | PY-2 | PY-2 | PY-2 | PY-2 |
| | | 32.67 | 36.67 | 39.33 | 29.40 | 40.83 | 45.00 |
| Pigment dispersing element 2 | | PG-3 | PG-3 | PG-3 | PG-3 | PG-4 | PG-4 |
| | | 27.20 | 24.00 | 21.87 | 24.48 | 34.00 | 30.67 |
| Pigment dispersing element 3 | | | | | | | |
| Photopolymerizable | compound of | B-2 | B-2 | B-2 | B-2 | B-2 | B-2 |
| monomer (B) | General Formula (1) | 7.29 | 7.13 | 7.02 | 8.48 | 4.29 | 4.13 |
| | other compounds | | | | | | |
| Photopolymerization | oxime ester type | C-1 | C-1 | C-1 | C-1 | C-1 | C-1 |
| initiator (C) | | 0.70 | 0.70 | 0.70 | 0.70 | 0.70 | 0.70 |
| | other | | | | | | |
| Resin solution | photosensitive | | | | | | |
| | resin | | | | | | |
| | non-photosensitive | | | | | | |
| | resin | | | | | | |
| Leveling agent | | 4.00 | 4.00 | 4.00 | 4.00 | 4.00 | 4.00 |
| Solvent 1 | | S-1 | S-1 | S-1 | S-1 | S-1 | S-1 |
| | | 28.15 | 27.51 | 27.08 | 22.72 | 16.17 | 15.51 |
| Solvent 2 | | | | | | | |
| Sum | | 100.00 | 100.00 | 100.00 | 89.78 | 100.00 | 100.00 |
| NV | | 20.00 | 20.00 | 20.00 | 20.00 | 20.00 | 20.00 |
| Viscosity | | 3.80 | 3.80 | 3.80 | 3.80 | 3.80 | 3.80 |
| | | Production | Production | Production | Production | Production | Production |
| | | Example 60 | Example 61 | Example 62 | Example 63 | Example 66 | Example 67 |
| | | R-60 | R-61 | R-62 | R-63 | R-66 | R-67 |
| Pigment dispersing element 1 | | PY-2 | PY-2 | PY-2 | PY-2 | PY-2 | PY-2 |
| | | 49.17 | 40.83 | 45.00 | 49.17 | 46.80 | 46.80 |
| Pigment dispersing element 2 | | PG-4 | PG-5 | PG-5 | PG-5 | PG-1 | PG-1 |
| | | 27.33 | 34.0 [symbol] | 30.67 | 27.33 | 26.35 | 26.35 |
| Pigment dispersing element 3 | | | | | | PB-1 | PB-1 |
| | | | | | | 6.40 | 6.40 |
| Photopolymerizable | compound of | B-2 | B-2 | B-2 | B-2 | B-2 | B-2 |
| monomer (B) | General Formula (1) | 3.96 | 4.29 | 4.13 | 3. [symbol] | 3.35 | 3.35 |
| | other compounds | | | | | | |
| Photopolymerization | oxime ester type | C-1 | C-1 | C-1 | C-1 | C-1 | C-1 |
| initiator (C) | | 0.70 | 0.70 | 0.70 | 0.70 | 0.70 | 0.70 |
| | other | | | | | | |
| Resin solution | photosensitive | | | | | | |
| | resin | | | | | | |
| | non-photosensitive | | | | | | |
| | resin | | | | | | |

| Leveling agent | 4.00 | 4.00 | 4.00 | 4.00 | 4.00 | 4.00 |
|---|---|---|---|---|---|---|
| Solvent 1 | S-1 | S-1 | S-1 | S-1 | S-1 | S-1 |
| | 14.84 | 16.17 | 15.51 | 14. [symbol] 4 | 9.40 | 9.40 |
| Solvent 2 | | | | | S-2 | S-3 |
| | | | | | 3.00 | 3.00 |
| Sum | 100.00 | 100.00 | 100.00 | 100.00 | 100.00 | 100.00 |
| NV | 20.00 | 20.00 | 20.00 | 20.00 | 20.00 | 20.00 |
| Viscosity | 3.80 | 3.80 | 3.80 | 3.80 | 3.80 | 3.80 |

[symbol]

indicates data missing or illegible when filed

TABLE 6
Blue photosensitive coloring composition

| | | Production | Production | Production | Production | Production |
|---|---|---|---|---|---|---|
| | | Example 35 | Example 36 | Example 37 | Example 38 | Example 39 |
| | | R-35 | R-36 | R-37 | R-38 | R-39 |
| Pigment dispersing element 1 | | PB-2 | PB-2 | PB-2 | PB-2 | PB-2 |
| | | 30.91 | 30.91 | 30.91 | 30.91 | 30.91 |
| Pigment dispersing element 2 | | PV-1 | PV-1 | PV-1 | PV-1 | PV-1 |
| | | 7.65 | 7.65 | 7.65 | 7.65 | 7.65 |
| Pigment dispersing element 3 | | PV-2 | PV-2 | PV-2 | PV-2 | PV-2 |
| | | 35.41 | 35.41 | 35.41 | 35.41 | 35.41 |
| Photopolymerizable | compound of | B-2 | B-2 | B-2 | B-1 | B-3 |
| monomer (B) | General Formula (1) | 4.59 | 4.59 | 4.59 | 4.59 | 4.59 |
| | other compounds | | | | | |
| Photopolymerization | oxime ester type | C-1 | C-1 | C-1 | C-1 | C-1 |
| initiator (C) | | 0.34 | 0.34 | 0.34 | 0.34 | 0.34 |
| | other | | | | | |
| Resin solution | photosensitive resin | D-1 | D-2 | | | |
| | | [symbol] .11 | [symbol] .11 | | | |
| | non-photosensitive | | | D-3 | D-3 | D-3 |
| | resin | | | 9.11 | 9.11 | 9.11 |
| Leveling agent | | 1.00 | 1.00 | 1.00 | 1.00 | 1.00 |
| Solvent 1 | | S-1 | S-1 | S-1 | S-1 | S-1 |
| | | 10.99 | 10.99 | 10.99 | 10.99 | 10.99 |
| Solvent 2 | | | | | | |
| Sum | | 100.00 | 100.00 | 100.00 | 100.00 | 100.00 |
| NV | | 18.00 | 18.00 | 18.00 | 18.00 | 18.00 |
| Viscosity | | 3.90 | 3.90 | 3.90 | 3.90 | 3.90 |
| | | Production | Production | Production | Production | Production |
| | | Example 40 | Example 41 | Example 42 | Example 43 | Example 44 |
| | | R-40 | R-41 | R-42 | R-43 | R-44 |
| Pigment dispersing element 1 | | PB-2 | PB-2 | PB-2 | PB-2 | PB-2 |
| | | 30.91 | 30.91 | 30.91 | 30.91 | 28.68807 |
| Pigment dispersing element 2 | | PV-1 | PV-1 | PV-1 | PV-1 | PV-1 |
| | | 7.65 | 7.65 | 7.65 | 7.65 | [symbol] .81 |
| Pigment dispersing element 3 | | PV-2 | PV-2 | PV-2 | PV-2 | PV-2 |
| | | 35.41 | 35.41 | 35.41 | 35.41 | 35.57 |
| Photopolymerizable | compound of | B-2 | B-2 | B-2 | B-2 | B-2 |
| monomer (B) | General Formula (1) | [symbol] .21 | 4.59 | 4.59 | 4.59 | 4.59 |
| | other compounds | B-4 | | | | |
| | | 1.38 | | | | |
| Photopolymerization | oxime ester type | C-1 | C-2 | C-3 | C-3 | C-1 |
| initiator (C) | | 0.34 | 0.34 | 0.34 | 0.2907 | 0.342 |
| | other | | | | C-4 | |
| | | | | | 0.0 [symbol] | |
| Resin solution | photosensitive resin | | | | | |
| | non-photosensitive | D-3 | D-3 | D-3 | D-3 | D-3 |
| | resin | 9.11 | 9.11 | 9.11 | 9.11 | 8.96 |

| Leveling agent | 1.00 | 1.00 | [symbol] .00 | [symbol] .00 | [symbol] .00 |
|---|---|---|---|---|---|
| Solvent 1 | S-1 | S-1 | S-1 | S-1 | S-1 |
| | 10.99 | 10.99 | 10.99 | 10.99 | 11.04 |
| Solvent 2 | | | | | |
| Sum | 100.00 | 100.00 | 100.00 | 100.00 | 100.00 |
| NV | 18.00 | 18.00 | 18.00 | 18.00 | 18.00 |
| Viscosity | 3.90 | 3.90 | 3.90 | 3.90 | 3.90 |

[symbol]

indicates data missing or illegible when filed

TABLE 7
Blue photosensitive coloring composition

| | | Production | Production | Production | Production |
|---|---|---|---|---|---|
| | | Example 45 | Example 46 | Example 47 | Example 48 |
| | | R-45 | R-46 | R-47 | R-48 |
| Pigment dispersing element 1 | | PB-2 | PB-2 | PB-2 | PB-2 |
| | | [symbol] 1.6558 | [symbol] 1.16118 | [symbol] 1.16118 | [symbol] 0.91 |
| Pigment dispersing element 2 | | PV-1 | PV-1 | PV-1 | PV-1 |
| | | 6.86 | 9.81 | 5.88 | 7.65 |
| Pigment dispersing element 3 | | PV-2 | PV-2 | PV-2 | PV-2 |
| | | 35.57 | 27.49 | 40.43 | 35.41 |
| Photopolymerizable monomer (B) | compound of General Formula (1) | B-2 | B-2 | B-2 | |
| | | 4.59 | 4.59 | 4.59 | |
| | other compounds | | | | B- [symbol] |
| | | | | | 4.59 |
| Photopolymerization initiator (C) | oxime ester type | C-1 | C-1 | C-1 | C-1 |
| | | 0.342 | 0.342 | 0.342 | 0.342 |
| | other | | | | |
| Resin solution | photosensitive resin | | | | D-1 |
| | | | | | 9.11 |
| | non-photosensitive resin | D-3 | D-3 | D-3 | |
| | | 9.08 | 12.11 | 7.23 | |

| Leveling agent | 1.00 | 1.00 | 1.00 | 1.00 |
|---|---|---|---|---|
| Solvent 1 | S-1 | S-1 | S-1 | S-1 |
| | 10.8 [symbol] | 13.50 | 9.37 | 10.99 |
| Solvent 2 | | | | |
| Sum | 100.00 | 100.00 | 100.00 | 100.00 |
| NV | 18.00 | 18.00 | 18.00 | 18.00 |
| Viscosity | 3.90 | 3.90 | 3.90 | 3.90 |

| | | Production | Production | Production |
|---|---|---|---|---|
| | | Example 49 | Example 68 | Example 69 |
| | | R-49 | R-68 | R-69 |
| Pigment dispersing element 1 | | PB-2 | PB-2 | PB-2 |
| | | [symbol] 0. [symbol] 1 | [symbol] 0.91 | [symbol] 0.91 |
| Pigment dispersing element 2 | | PV-1 | PV-1 | PV-1 |
| | | 7.65 | 7.65 | 7.65 |
| Pigment dispersing element 3 | | PV-2 | PV-2 | PV-2 |
| | | 35.41 | 35.41 | 35.41 |
| Photopolymerizable monomer (B) | compound of General Formula (1) | B-2 | B-2 | B-2 |
| | | 4.59 | 4.59 | 4.59 |
| | other compounds | | | |
| Photopolymerization initiator (C) | oxime ester type | | C-1 | C-1 |
| | | | 0.34 | 0.34 |
| | other | C-4 | | |
| | | 0.34 | | |
| Resin solution | photosensitive resin | D-1 | D-1 | D-1 |
| | | 9.11 | 9.11 | 9.11 |
| | non-photosensitive resin | | | |

| Leveling agent | 1.00 | 1.00 | 1.00 |
|---|---|---|---|
| Solvent 1 | S-1 | S-1 | S-1 |
| | 10.99 | 7.99 | 7.99 |
| Solvent 2 | | S-2 | S-3 |
| | | 3.00 | 3.00 |
| Sum | 100.00 | 100.00 | 100.00 |
| NV | 18.00 | 18.00 | 18.00 |
| Viscosity | 3.90 | 3.90 | 3.90 |

[symbol]

indicates data missing or illegible when filed

Abbreviations in Table 1-7 are shown below.

### <Photopolymerizable Monomer (B)>

photopolymerizable monomer B-1: trimethylolpropane EO-modified triacrylate (“ARONIX M-350” commercially available from Toagosei Co., Ltd.)

photopolymerizable monomer B-2: trimethylolpropane triacrylate (“ARONIX M-309” commercially available from Toagosei Co., Ltd.)

photopolymerizable monomer B-3: pentaerythritol tri- and tetra-acrylate (“ARONIX M-306” commercially available from Toagosei Co., Ltd.)

photopolymerizable monomer B-4: dipentaerythritol hexaacrylate (“ARONIX M-402” commercially available from Toagosei Co., Ltd.)

### <Photopolymerization Initiator (C)>

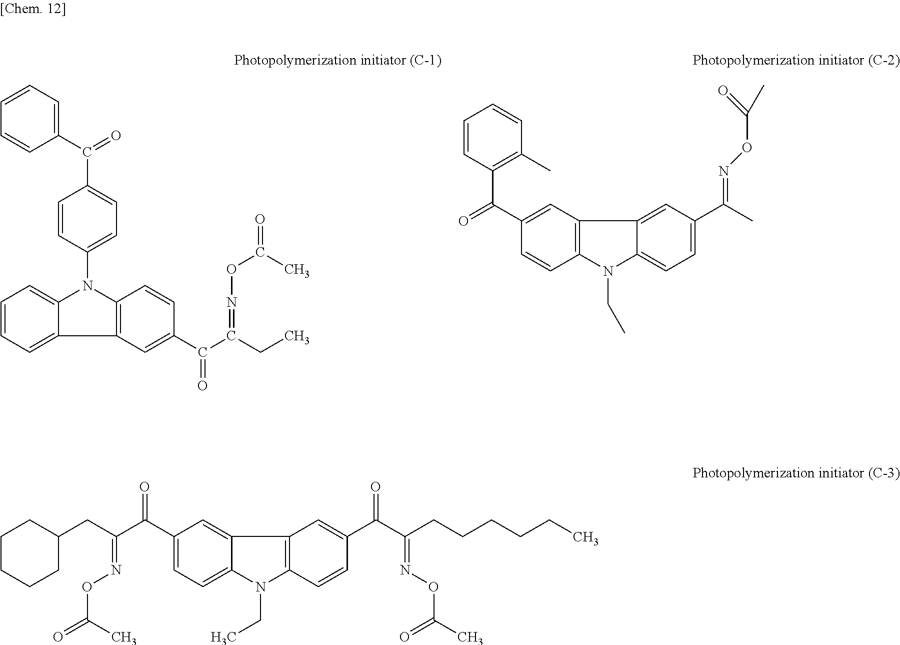 [SMILES: CCC(=NOC(C)=O)C(=O)c1ccc2c(c1)c1ccccc1n2-c1ccc(C(=O)c2ccccc2)cc1 ; CCn1c2ccc(C(=O)c3ccccc3C)cc2c2cc(/C(C)=N/OC(C)=O)ccc21 ; CCCCCC/C(=N\OC(C)=O)C(=O)c1ccc2c(c1)c1cc(C(=O)/C(CC3CCCCC3)=N/OC(C)=O)ccc1n2CC]

photopolymerization initiator C-4: 2-methyl-1-[4-(methylthio)phenyl]-2-morpholinopropan-1-one (“IRGACURE-907” commercially available from BASF Japan Ltd.)

### <Leveling Agent>

leveling agent: a solution obtained by dissolving 1 part of “FZ-2122” (commercially available from Dow Corning Toray Co., Ltd.) in 99 parts of propylene glycol monomethyl ether acetate (PGMAc)

### <Solvent (S)>

solvent S-1: propylene glycol monomethyl ether acetate
solvent S-2: tripropylene glycol monomethyl ether
solvent S-3: 3-methoxy-1-butanol

### <Production of OLED Element>

A TFT layer was formed on a silicon substrate using a known method such as a sputtering method or an etching method. In addition, a white organic EL element was formed on the TFT layer using a known method such as an evaporation method and silicon nitride was then applied by a CVD method to form an organic EL element substrate.

### <Production of Color Filter⋅Organic EL Display Device>

A green photosensitive coloring composition was applied onto the OLED element with a spinner so that the film thickness of the cured finish was 1.5 and a green layer (G) of a color filter was formed through UV exposure through a pattern mask, alkali development, washing with water and a drying step. Then, heating and curing were performed using a heating oven at 80° C. for 10 minutes, and formation of the green layer (G) of the color filter was completed.

Next, in the same manner as in the method of forming the green layer (G) of the color filter described above, a red photosensitive coloring composition was applied with a spinner so that the film thickness of the cured finish was 1.5 μm, and a red layer (R) of the color filter was temporarily formed through UV exposure through a pattern mask, alkali development, washing with water and a drying step. Then, heating and curing were performed using a heating oven at 80° C. for 10 minutes, and formation of the red layer (R) of the color filter was completed.

In addition, in the same manner as in the method of forming the green layer (G) of the color filter described above, a blue photosensitive coloring composition was applied with a spinner so that the film thickness of the cured finish was 1.5 μm, and a blue layer (B) of the color filter was temporarily formed through UV exposure through a pattern mask, alkali development, washing with water and a drying step. Then, heating and curing were performed using a heating oven at 80° C. for 10 minutes, formation of the blue layer (B) of the color filter was completed, and thereby the color filter was produced.

After the green, red, and blue layers were formed, they were bonded to a cover glass using an encapsulant Struct Bond XMF-T107 (commercially available from Mitsui Chemicals Inc) to produce an organic EL display device.

Tables 8 to 11 show the combinations of the photosensitive coloring compositions used when the color filters and organic EL display devices of examples and comparative examples were produced. In addition, Tables 8 to 11 show the appearances of the obtained color filters and organic EL display devices and the results of spectral transmittance measured.

TABLE 8

| | | | Example | Example | Example | Example | Example |
|---|---|---|---|---|---|---|---|
| | | | 1 | 2 | 3 | 4 | 5 |
| Color filter Si-OLED | | | C [symbol] -1 | C [symbol] -2 | C [symbol] -3 | C [symbol] -4 | C [symbol] -5 |
| Coloring composition | | red coloring composition | R-1 | R-2 | R-3 | R-4 | R-5 |
| | | green coloring composition | R-17 | R-18 | R-19 | R-20 | R-21 |
| | | blue coloring composition | R-37 | R-35 | R-36 | R-37 | R-38 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | green pixel | 0.0% | 0.0% | 0.0% | 0.0% | 0.0% |
| | | (400 nm to 470 nm) | | | | | |
| | | green pixel | 70.1% | 70.1% | 70.1% | 70.1% | 70.1% |
| | | (525 nm to 53.5 nm) | | | | | |
| | | green pixel hall-value | 504 nm | 504 nm | 504 nm | 504 nm | 504 nm |
| | | wavelength | | | | | |
| | | (497 nm to 507 nm) | | | | | |
| | | green pixel half-value | 559 nm | 559 nm | 559 nm | 559 nm | 559 nm |
| | | wavelength | | | | | |
| | | (554 nm to 581 nm) | | | | | |
| | | blue pixel | 16.2% | 16.2% | 16.2% | 16.2% | 16.2% |
| | | (500 nm to 560 nm) | | | | | |
| | Pixel shape | | ◯ | Δ | Δ | ◯ | ◯ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | Δ | Δ |
| | | green pixel | ◯ | ◯ | ◯ | Δ | Δ |
| | | blue pixel | ◯ | ◯ | ◯ | ◯ | Δ |
| | W-L | | ◯ | ◯ | ◯ | ◯ | ◯ |
| | NTSC | | ◯ | ◯ | ◯ | ◯ | ◯ |
| | Pixel crack | | Δ | Δ | Δ | Δ | Δ |
| | | | Example | Example | Example | Example | Example |
| | | | 6 | 7 | 8 | 9 | 10 |
| Color filter Si-OLED | | | C [symbol] -6 | C [symbol] -7 | C [symbol] -8 | C [symbol] -9 | C [symbol] -10 |
| Coloring composition | | red coloring composition | R-6 | R-7 | R-8 | R-9 | R-10 |
| | | green coloring composition | R-22 | R-23 | R-24 | R-25 | R-26 |
| | | blue coloring composition | R-39 | R-40 | R-41 | R-42 | R-43 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | green pixel | 0.0% | 0.0% | 0.0% | 0.0% | 0.0% |
| | | (400 nm to 470 nm) | | | | | |
| | | green pixel | 70.1% | 70.1% | 70.1% | 70.1% | 70.1% |
| | | (525 nm to 53.5 nm) | | | | | |
| | | green pixel hall-value | 504 nm | 504 nm | 504 nm | 504 nm | 504 nm |
| | | wavelength | | | | | |
| | | (497 nm to 507 nm) | | | | | |
| | | green pixel half-value | 559 nm | 559 nm | 559 nm | 559 nm | 559 nm |
| | | wavelength | | | | | |
| | | (554 nm to 581 nm) | | | | | |
| | | blue pixel | 16.2% | 16.2% | 16.2% | 16.2% | 16.2% |
| | | (500 nm to 560 nm) | | | | | |
| | Pixel shape | | Δ | Δ | Δ | ◯ | Δ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | ◯ | Δ |
| | | green pixel | ◯ | ◯ | ◯ | ◯ | Δ |
| | | blue pixel | ◯ | ◯ | ◯ | ◯ | Δ |

| | | | | | |
|---|---|---|---|---|---|
| W-L | ◯ | ◯ | ◯ | ◯ | ◯ |
| NTSC | ◯ | ◯ | ◯ | ◯ | ◯ |
| Pixel crack | Δ | Δ | Δ | Δ | Δ |

[symbol]

indicates data missing or illegible when filed

TABLE 9

| | | | Example | Example | Example | Example | Example |
|---|---|---|---|---|---|---|---|
| | | | 11 | 12 | 13 | 14 | 15 |
| Color filter Si-OLED | | | C [symbol] -11 | C [symbol] -12 | C [symbol] -13 | C [symbol] -14 | C [symbol] -15 |
| Coloring composition | | red coloring composition | R-1 | R-11 | R-12 | R-13 | R-14 |
| | | green coloring composition | R-27 | R-17 | R-17 | R-17 | R-17 |
| | | blue coloring composition | R-37 | R-37 | R-37 | R-37 | R-37 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.4% | 0.2% | 0. [symbol] % |
| | | (450 nm to 560 nm) | | | | | |
| | | red pixel | 98.4% | 94.9% | 95.3% | 95.1% | 95.2% |
| | | (600 nm to 700 nm) | | | | | |
| | | red pixel half-value | 598 nm | 597 nm | 598 nm | 598 nm | 598 nm |
| | | wavelength | | | | | |
| | | (593 nm to 603 nm) | | | | | |
| | | green pixel | 0.0% | 0.0% | 0.0% | 0.0% | 0.0% |
| | | (400 nm to 470 nm) | | | | | |
| | | green pixel | 70.1% | 70.1% | 70.1% | 70.1% | 70.1% |
| | | (525 nm to 535 nm) | | | | | |
| | | green pixel half-value | 504 nm | 504 nm | 504 nm | 504 nm | 504 nm |
| | | wavelength | | | | | |
| | | (497 nm to 507 nm) | | | | | |
| | | green pixel half-value | 559 nm | 559 nm | 559 nm | 559 nm | 559 nm |
| | | wavelength | | | | | |
| | | (554 nm to 581 nm) | | | | | |
| | | blue pixel | 16.2% | 16.2% | 16.2% | 16.2% | 16.2% |
| | | (500 nm to 560 nm) | | | | | |
| | Pixel shape | | ◯ | ◯ | ◯ | ◯ | ◯ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | ◯ | ◯ |
| | | green pixel | ◯ | ◯ | ◯ | ◯ | ◯ |
| | | blue pixel | ◯ | ◯ | ◯ | ◯ | ◯ |
| | W-L | | ◯ | ◯ | ◯ | ◯ | ◯ |
| | NTSC | | ◯ | ◯ | ◯ | ◯ | ◯ |
| | Pixel crack | | Δ | Δ | Δ | Δ | Δ |
| | | | Example | Example | Example | Example | Example |
| | | | 16 | 17 | 18 | 19 | 20 |
| Color filter Si-OLED | | | C [symbol] -16 | C [symbol] -17 | C [symbol] -18 | C [symbol] -19 | C [symbol] -20 |
| Coloring composition | | red coloring composition | R-1 | R-1 | R-1 | R-1 | R-1 |
| | | green coloring composition | R-29 | R-30 | R-31 | R-32 | R-17 |
| | | blue coloring composition | R-37 | R-37 | R-37 | R-37 | R-44 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | (593 nm to 603 nm) | | | | | |
| | | green pixel | 0.2% | 0.1% | 0.1% | 0.2% | 0.0% |
| | | (400 nm to 470 nm) | | | | | |
| | | green pixel | 73.7% | 72.8% | 75.2% | 71.4% | [symbol] 0.1% |
| | | (525 nm to 535 nm) | | | | | |
| | | green pixel half-value | 499 [symbol] | 500 nm | 500 nm | 500 nm | 504 nm |
| | | wavelength | | | | | |
| | | (497 nm to 507 nm) | | | | | |
| | | green pixel half-value | 562 nm | 564 nm | 581 nm | 554 nm | 559 um |
| | | wavelength | | | | | |
| | | (554 nm to 581 nm) | | | | | |
| | | blue pixel | 16.2% | 16.2% | 16.2% | 16.2% | 12.3% |
| | | (500 nm to 560 nm) | | | | | |
| | Pixel shape | | ◯ | ◯ | ◯ | ◯ | ◯ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | ◯ | ◯ |
| | | green pixel | ◯ | ◯ | ◯ | ◯ | ◯ |
| | | blue pixel | ◯ | ◯ | ◯ | ◯ | ◯ |

| | | | | | |
|---|---|---|---|---|---|
| W-L | ◯ | ◯ | ◯ | ◯ | ◯ |
| NTSC | ◯ | ◯ | ◯ | ◯ | ◯ |
| Pixel crack | Δ | Δ | Δ | Δ | Δ |

[symbol]

indicates data missing or illegible when filed

TABLE 10

| | | | Example | Example | Example | Example | Example |
|---|---|---|---|---|---|---|---|
| | | | 21 | 22 | 23 | 24 | 25 |
| Color filter | | | C [symbol] -21 | C [symbol] -22 | C [symbol] -23 | C [symbol] -24 | C [symbol] -25 |
| Coloring composition | | red coloring composition | R-1 | R-1 | R-1 | R-1 | R-1 |
| | | green coloring composition | R-17 | R-17 | R-17 | R-50 | R-51 |
| | | blue coloring composition | R-45 | R-46 | R-47 | R-37 | R-37 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | (593 nm to 603 nm) | | | | | |
| | | green pixel | 0.0% | 0.0% | 0.0% | 0.7% | 0.5% |
| | | (400 nm to 470 nm) | | | | | |
| | | green pixel | 70.1% | 70.1% | 70.1% | 70.1% | 70.1% |
| | | (525 nm to 535 nm) | | | | | |
| | | green pixel half-value | 504 nm | 504 nm | 504 nm | 502 nm | 503 nm |
| | | wavelength | | | | | |
| | | (497 nm to 507 nm) | | | | | |
| | | green pixel half-value | 559 nm | 559 nm | 559 nm | 534 nm | 555 nm |
| | | wavelength | | | | | |
| | | (554 nm to 581 nm) | | | | | |
| | | blue pixel | 18.8% | 14.6% | 19.6% | 16.2% | 16.2% |
| | | (500 nm to 560 nm) | | | | | |
| | Pixel shape | | ◯ | ◯ | ◯ | ◯ | ◯ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | ◯ | ◯ |
| | | green pixel | ◯ | ◯ | ◯ | ◯ | ◯ |
| | | blue pixel | ◯ | ◯ | ◯ | ◯ | ◯ |
| | W-L | | ◯ | ◯ | ◯ | ◯ | ◯ |
| | NTSC | | ◯ | ◯ | ◯ | ⊚ | ⊚ |
| | Pixel crack | | Δ | Δ | Δ | Δ | Δ |
| | | | Example | Example | Example | Example | Example |
| | | | 26 | 27 | 28 | 29 | 30 |
| Color filter | | | C [symbol] -26 | C [symbol] -27 | C [symbol] -28 | C [symbol] -29 | C [symbol] -30 |
| Coloring composition | | red coloring composition | R-1 | R-1 | R-1 | R-1 | R-1 |
| | | green coloring composition | R-52 | R-54 | R-55 | R-56 | R-58 |
| | | blue coloring composition | R-37 | R-37 | R-37 | R-37 | R-37 |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | (593 nm to 603 nm) | | | | | |
| | | green pixel | 0.3% | 2.0% | 1.3% | 0.9% | 0.7% |
| | | (400 nm to 470 nm) | | | | | |
| | | green pixel | 70.1% | 70.1% | 70.1% | 70.1% | 78.8% |
| | | (525 nm to 535 nm) | | | | | |
| | | green pixel half-value | 504 nm | 497 nm | 499 nm | 501 nm | 500 nm |
| | | wavelength | | | | | |
| | | (497 nm to 507 nm) | | | | | |
| | | green pixel half-value | 557 nm | 561 nm | 563 nm | 565 nm | [symbol] 67 nm |
| | | wavelength | | | | | |
| | | (554 nm to 581 nm) | | | | | |
| | | blue pixel | 16.2% | 16.2% | 16.2% | 16.2% | 16.2% |
| | | (500 nm to 560 nm) | | | | | |
| | Pixel shape | | ◯ | ◯ | ◯ | ◯ | ◯ |
| | Developability (residue) | | ◯ | ◯ | ◯ | ◯ | ◯ |
| | Light resistance | | ◯ | ◯ | ◯ | ◯ | ◯ |
| | Appearance and surface roughness | red pixel | ◯ | ◯ | ◯ | ◯ | ◯ |
| | | green pixel | ◯ | ◯ | ◯ | ◯ | ◯ |
| | | blue pixel | ◯ | ◯ | ◯ | ◯ | ◯ |

| | | | | | |
|---|---|---|---|---|---|
| W-L | ◯ | ◯ | ◯ | ◯ | ◯ |
| NTSC | ⊚ | ◯ | ◯ | ◯ | ⊚ |
| Pixel crack | Δ | Δ | Δ | Δ | Δ |

[symbol]

indicates data missing or illegible when filed

TABLE 11

| | | | Example | Example | Example | Example | Example | Example | Example |
|---|---|---|---|---|---|---|---|---|---|
| | | | 31 | 32 | 33 | 34 | 35 | 36 | 37 |
| Color filter | | | C [symbol] -31 | C [symbol] -32 | C [symbol] -33 | C [symbol] -34 | C [symbol] -35 | C [symbol] -36 | C [symbol] -37 |
| Coloring composition | | red coloring | R-1 | R-1 | R-1 | R-1 | R-1 | R-64 | R-65 |
| | | composition | | | | | | | |
| | | green coloring | R-59 | R-60 | R-61 | R-62 | R-63 | R-66 | R-67 |
| | | composition | | | | | | | |
| | | blue coloring | R-37 | R-37 | R-37 | R-37 | R-37 | R- [symbol] | R-69 |
| | | composition | | | | | | | |
| CF/EL | Film thickness | red pixel | 1.5 μm | 1.5 μm | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm | 1.5 μm | 1.5 μm |
| | Spectral transmittance | red pixel | 0.3% | 0.3% | 0.3% | 0.3% | 0.3% | 0.3% | 0.3% |
| | | (450 nm to 560 nm) | | | | | | | |
| | | red pixel | 98.4% | 98.4% | 98.4% | 98.4% | 98.4% | 98.4% | 98.4% |
| | | (600 nm to 700 nm) | | | | | | | |
| | | red pixel half-value | 598 nm | 598 nm | 598 nm | 598 nm | 598 nm | 598 nm | 598 nm |
| | | wavelength | | | | | | | |
| | | (593 nm to 603 nm) | | | | | | | |
| | | green pixel | 0.4% | 0.3% | 0.4% | 0.3% | 0.2% | 0.0% | 0.0% |
| | | (400 nm to 470 nm) | | | | | | | |
| | | green pixel | 78.3% | 77.6% | 73.3% | 74.0% | 73.8% | 70.1% | 70.1% |
| | | (525 nm to 535 nm) | | | | | | | |
| | | green pixel | 501 nm | 502 nm | 501 nm | 502 nm | 502 nm | 504 nm | 504 nm |
| | | half-value | | | | | | | |
| | | wavelength | | | | | | | |
| | | (497 nm to 507 nm) | | | | | | | |
| | | green pixel | 571 nm | 574 nm | 568 nm | 570 nm | 572 nm | 559 nm | 559 nm |
| | | half-value | | | | | | | |
| | | wavelength | | | | | | | |
| | | (554 nm to 581 nm) | | | | | | | |
| | | blue pixel | 16.2% | 16.2% | 16.2% | 16.2% | 16.2% | 16.2% | 16.2% |
| | | (500 nm to 560 nm) | | | | | | | |
| | Pixel shape | | ◯ | ◯ | ◯ | ◯ | ◯ | ◯ | ◯ |
| | Developability (residue) | | ◯ | ◯ | ◯ | ◯ | ◯ | ◯ | ◯ |
| | Light resistance | | ◯ | ◯ | ◯ | ◯ | ◯ | ◯ | ◯ |
| | Appearance and surface | red pixel | ◯ | ◯ | ◯ | ◯ | ◯ | ◯ | ◯ |
| | roughness | green pixel | ◯ | ◯ | ◯ | ◯ | ◯ | ◯ | ◯ |
| | | blue pixel | ◯ | ◯ | ◯ | ◯ | ◯ | ◯ | ◯ |

| | | | | | | | |
|---|---|---|---|---|---|---|---|
| W-L | ◯ | ◯ | ◯ | ◯ | ◯ | ◯ | ◯ |
| NTSC | ⊚ | ⊚ | ⊚ | ⊚ | ⊚ | ◯ | ◯ |
| Pixel crack | Δ | Δ | Δ | Δ | Δ | ◯ | ◯ |

| | | | Comparative | Comparative | Comparative | Comparative | Comparative |
|---|---|---|---|---|---|---|---|
| | | | Example 1 | Example 2 | Example 3 | Example 4 | Example 5 |
| Color filter | | | C [symbol] -38 | C [symbol] -39 | C [symbol] -40 | C [symbol] -41 | C [symbol] -42 |
| Coloring composition | | red coloring | R-15 | R-16 | R-1 | R-1 | R-1 |
| | | composition | | | | | |
| | | green coloring | R-33 | R-34 | R-28 | R-53 | R-57 |
| | | composition | | | | | |
| | | blue coloring | R-48 | R-49 | R-37 | R-37 | R-37 |
| | | composition | | | | | |
| CF/EL | Film thickness | red pixel | 1.5 μm | 1.5 μm | 1.5 μm | 1.5 μm | 1.5 μm |
| display | | green pixel | 1.5 μm | 1.5 μm | 1.5 μm | 1.5 μm | 1.5 μm |
| device | | blue pixel | 1.5 μm | 1.5 μm | 1.5 μm | 1.5 μm | 1.5 μm |
| | Spectral transmittance | red pixel | 0.3% | 0.3% | 0.3% | 0.3% | 0.3% |
| | | (450 nm to 560 nm) | | | | | |
| | | red pixel | 98.4% | 98.4% | 98.4% | 98.4% | 98.4% |
| | | (600 nm to 700 nm) | | | | | |
| | | red pixel half-value | 598 nm | 598 nm | 598 nm | 598 nm | 598 nm |
| | | wavelength | | | | | |
| | | (593 nm to 603 nm) | | | | | |
| | | green pixel | 0.0% | 0.0% | 0.1% | 0.9% | 2.9% |
| | | (400 nm to 470 nm) | | | | | |
| | | green pixel | 70.1% | 70.1% | 74. [symbol] % | 70.1% | 70.1% |
| | | (525 nm to 535 nm) | | | | | |
| | | green pixel | 504 nm | 504 nm | 501 nm | 502 nm | 496 nm |
| | | half-value | | | | | |
| | | wavelength | | | | | |
| | | (497 nm to 507 nm) | | | | | |
| | | green pixel | 559 nm | 559 nm | 564 nm | 553 nm | 560 nm |
| | | half-value | | | | | |
| | | wavelength | | | | | |
| | | (554 nm to 581 nm) | | | | | |
| | | blue pixel | 16.2% | 16.2% | 16.2% | 16.2% | 16.2% |
| | | (500 nm to 560 nm) | | | | | |

| Pixel shape | | X | X | ◯ | ◯ | ◯ |
|---|---|---|---|---|---|---|
| Developability (residue) | | X | ◯ | ◯ | ◯ | ◯ |
| Light resistance | | ◯ | ◯ | | ◯ | ◯ |
| Appearance and surface | red pixel | ◯ | X | ◯ | ◯ | ◯ |
| roughness | green pixel | ◯ | X | ◯ | X | X |
| | blue pixel | ◯ | X | ◯ | ◯ | ◯ |

| | | | | | |
|---|---|---|---|---|---|
| W-L | ◯ | ◯ | X | X | ◯ |
| NTSC | ◯ | ◯ | Δ | ⊚ | X |
| Pixel crack | Δ | Δ | Δ | Δ | Δ |

[symbol]

indicates data missing or illegible when filed

### <Pixel Shape (Linearity)>

Each photosensitive coloring composition was applied onto a silicon wafer substrate with a diameter of 200 mm with a spin coater so that the thickness after drying was 1.50 μm and dried at 70° C. for 1 minute to obtain a substrate. Next, using an i-line stepper exposure device FPA-3000i5+ (commercially available from Canon), exposure was performed at a wavelength of 365 nm and 3,000 J/m². Exposure was performed through a photomask with 2.40 μm square openings. The film after exposure was subjected to puddle development with 2.38% TMAH (an aqueous solution containing 2.38% of tetramethylammonium hydroxide, commercially available from Tama Chemicals Co., Ltd.) for 1 minute. After puddle development, rinsing was performed with pure water using a spin shower for 20 seconds, and spin-drying was performed. The linearity of the pixels formed according to the openings was observed using a scanning electron microscope (“S-3000N” commercially available from Hitachi High-Tech Corporation) and evaluated based on the following criteria.

∘: the linearity of pixels over the entire surface was good (preferable level for practical use)
Δ: the linearity of pixels was partially good (practical level)
x: the linearity of pixels over the entire surface was poor (level not suitable for practical use)

### <Developability (Residue)>

Each photosensitive coloring composition was applied onto a silicon wafer substrate with a diameter of 200 mm with a spin coater so that the thickness after drying was 1.50 μm and dried at 70° C. for 1 minute to obtain a substrate. Next, using an i-line stepper exposure device FPA-3000i5+(commercially available from Canon), exposure was performed at a wavelength of 365 nm and 3,000 J/m². Exposure was performed through a photomask with 2.40 μm square openings. The film after exposure was subjected to puddle development with 2.38% TMAH (an aqueous solution containing 2.38% of tetramethylammonium hydroxide, commercially available from Tama Chemicals Co., Ltd.) for 1 minute. After puddle development, rinsing was performed with pure water using a spin shower for 20 seconds, and spin-drying was performed.

The development residue in the non-exposed part was observed using a scanning electron microscope (“S-3000N” commercially available from Hitachi High-Tech Corporation) and evaluated based on the following criteria.

∘: no development residue in the non-exposed part (preferable level for practical use)
Δ: the development residue was present in a part of the non-exposed part (practical level)
x: the development residue was present on the entire surface of the non-exposed part (level not suitable for practical use)

### <Evaluation of Light Resistance>

Each photosensitive coloring composition was spin-coated on a glass substrate with a length of 100 mm, a width of 100 mm, and a thickness of 0.7 mm using a spin coater so that the dry film thickness was 1.50 μm, and dried at 70° C. for 1 minute. Next, the obtained film was exposed to light at 3,000 mJ/cm² with an i-line illuminance of 30 mW/cm² from a super high pressure mercury lamp through a photomask in which 400 μm square pattern mask patterns were arranged.

For the pattern-exposed film, the unexposed part was developed with 2.38% of TMAH and washing with pure water was then performed. Then, water droplets were blown off with high pressure air, the substrate was naturally dried, and post-baked on a hot plate at 80° C. for 10 minutes, and the pattern of the cured film was formed on the glass substrate. The chromaticity ([L*(1), a*(1), b*(1)]) of the obtained coating at the C light source was measured using a microspectrophotometer (“OSP-SP100” commercially available from Olympus Corporation). Then, a UV cut filter (“COLORED OPTICAL GLASS L38” commercially available from Hoya Corporation) was bonded onto the substrate, ultraviolet rays were emitted for 100 hours using a 470 W/m² xenon lamp, the chromaticity ([L*(2), a*(2), b*(2)]) at the C light source was then measured, and the color difference ΔEab* was determined from the calculation formula and evaluated according to the following four stages.

ΔEab*=((L*(2)−L*(1))²+(a*(2)−a*(1))²+(b*(2)−b*(1))²)^{1/2}

∘: ΔEab* was less than 3.0 (preferable level for practical use)
Δ: ΔEab* was 3.0 or more and less than 6.0 (practical level)
x: ΔEab* was 6.0 or more (level not suitable for practical use)

### <Observation of Appearance of Color Filter and Organic EL Display Device>

Appearance observation was performed by reflection observation using an optical microscope “ECLIPSELV100” (commercially available from NIKON). A sample with no pixel bleeding or surface roughness was evaluated as ◯, a sample with slight bleeding was evaluated as Δ, and a sample with surface roughness and color bleeding from adjacent pixels was evaluated as x. A sample with surface roughness and color bleeding from adjacent pixels was determined not to be practical.

In addition, as evaluation of pixel overlapping, if the amount of red, green and blue pixels overlapping was less than 0.1 μm, it was evaluated as ∘, if the amount of pixels overlapping was 0.1 μm or more and less than 0.3 μm, it was evaluated as Δ, and if the amount thereof was 0.3 μm or more, it was evaluated as x. If the amount of pixels overlapping was 0.3 μm or more, it was determined not to be practical because the display area became small, and the luminance of the organic EL display device decreased.

### <Chromaticity of Organic EL Display Device>

In the organic EL display devices of Examples 1 to 37 and Comparative Examples 1 to 5, the chromaticities during red display, during green display, and during blue display were measured using a “spectral radiance meter CS-1000” (commercially available from Olympus Corporation). From the obtained red, green and blue chromaticities, the NTSC area ratio (the ratio of the color gamut of the organic EL display device of examples or comparative examples with respect to the color gamut defined by the NTSC standards) was calculated. Here, the color reproducibility could be evaluated according to NTSC chromaticity.

If the NTSC area ratio was 93% or more, it was evaluated as ⊚, if the NTSC area ratio was 90% or more, it was evaluated as ◯, if the NTSC area ratio was 85% or more and less than 90%, it was evaluated as Δ, and if the NTSC area ratio was less than 85%, it was evaluated as x. If the NTSC area ratio was less than 85%, it was determined not to be practical because the image lacked sharpness when an image was displayed on the organic EL display device.

All three red, green, and blue pixels were lit and displayed, and if the luminance (W-L) during white display was 330 cd/m² or more, it was evaluated as ⊚, if the luminance was 300 cd/m² or more and less than 330 cd/m² it was evaluated as ◯, if the luminance was 280 cd/m² or more and less than 300 cd/m² it was evaluated as A, and if the luminance was less than 280 cd/m², it was evaluated as x. If the luminance was less than 280 cd/m², it was determined not to be practical as an organic EL display device because it looked dark when the image was displayed.

### <Pixel Crack>

Each photosensitive coloring composition was applied onto a silicon wafer substrate with a diameter of 200 mm with a spin coater so that the thickness after drying was 1.50 μm and dried at 70° C. for 1 minute to obtain a substrate. Next, using an i-line stepper exposure device FPA-3000i5+ (commercially available from Canon), exposure was performed at a wavelength of 365 nm and 3,000 J/m². Exposure was performed through a photomask with 2.40 μm square openings. The film after exposure was subjected to puddle development with 2.38% TMAH (an aqueous solution containing 2.38% of tetramethylammonium hydroxide, commercially available from Tama Chemicals Co., Ltd.) for 1 minute. After puddle development, rinsing was performed with pure water using a spin shower for 20 seconds, and spin-drying was performed. After spin-drying, firing was performed on a hot plate at 90° C. for 5 minutes to obtain a monochromatic patterned substrate. The 2^{nd} and 3^{rd} colors were added in the same manner to obtain a patterned substrate with three RGB colors. The pixel surface was observed using a scanning electron microscope (“S-3000N” commercially available from Hitachi High-Tech Corporation) and evaluated based on the following criteria.

∘: no cracks on pixels (preferable level for practical use)
Δ: pixels with cracks were partially present (practical level)
x: pixels with cracks were present overall (level not suitable for practical use)

### INDUSTRIAL APPLICABILITY

The present disclosure can be used as an organic EL display device for electronic devices such as smart glasses, head-mounted displays, and electronic viewfinders.

Priority is claimed on Japanese Patent Application No. 2021-072704, filed Apr. 22, 2021, the content of which is incorporated herein by reference.

1. An organic EL display device, comprising an organic EL layer and a color filter on a silicon substrate on which a driving element is formed,
wherein the color filter has pixels including red pixels, green pixels, and blue pixels,
wherein, when the film thickness of the pixel is 1.5 μm, for a spectral transmittance of the red pixel, a maximum transmittance of light in a wavelength range of 450 nm to 560 nm is 0.5% or less, a 50% half-value wavelength is 593 nm to 603 nm, and a maximum transmittance of light in a wavelength range of 600 nm to 700 nm is 80% or more and less than 100%,
for the spectral transmittance of the green pixel, a maximum transmittance of light in a wavelength range of 400 nm to 470 nm is 2% or less, a maximum transmittance of light at a wavelength of 525 to 535 nm is 67% or more, a 50% half-value wavelength on the short wavelength side is 497 to 507 nm, and a 50% half-value wavelength on the long wavelength side is 554 to 581 nm, and
for the spectral transmittance of the blue pixel, a maximum transmittance of light in a wavelength range of 500 nm to 560 nm is less than 20%,
wherein the pixel is a cured product of a photosensitive coloring composition containing a colorant (A), a photopolymerizable monomer (B), a photopolymerization initiator (C) and a resin (D),
wherein, in the red pixel, the colorant (A) contains Pigment Red 177 and other colorants,
wherein, in the green pixel, the colorant (A) contains Pigment Yellow 185, and one or more selected from the group consisting of Pigment Green 36, Pigment Green 62, Pigment Green 63 and Pigment Green 59, and optionally contains other colorants, and a content of Pigment Yellow 185 in the colorant (A) of the green pixel is 49 weight % to 59 weight %,
wherein the blue pixel contains Pigment Blue 15:6 and other colorants,
wherein, in the red pixel, the other colorants include one or more selected from the group consisting of Pigment Red 254 and Pigment Yellow 139,
wherein, in the green pixel, the other colorants include Pigment Blue 15:3,
wherein, in the blue pixel, the other colorants include one or more selected from the group consisting of Pigment Violet 23 and a xanthene dye,
wherein the photopolymerizable monomer (B) contains a compound represented by the following General Formula (1), and
wherein the photopolymerization initiator (C) contains an oxime ester photopolymerization initiator:
[CH₂═CHC(═O)—(OCₘH₂ₘ)ₙ—OCH₂]₃—CR General Formula (1)
(in General Formula (1), m represents an integer of 1 to 3, n represents an integer of 0 to 2, and a plurality of m and n may be the same as or different from each other, and
R represents a substituent selected from among —CH₂CH₃, —CH₂OH, and —CH₂O(C═O)C═CH₂).

2. The organic EL display device according to claim 1,
wherein a cured product constituting the red pixel contains a colorant (A-1) Pigment Red 177, a colorant (A-2) Pigment Red 254, and a colorant (A-3) Pigment Yellow 139,
wherein, in the colorant (A) in the red pixel,
a content of the colorant (A-1) is 55 weight % to 65 weight %,
a content of the colorant (A-2) is 15 weight % to 25 weight %, and
a content of the colorant (A-3) is 15 weight % to 25 weight %,
wherein a cured product constituting the green pixel contains a colorant (A-4) Pigment Yellow 185, a colorant (A-5) Pigment Green 36, a colorant (A-6) Pigment Green 62, a colorant (A-11) Pigment Green 63, a colorant (A-12) Pigment Green 59, and a colorant (A-7) Pigment Blue 15:3 according to the following combinations (I) to (IV):
(I) the colorant (A-4), the colorant (A-5) and the colorant (A-7)
(II) the colorant (A-4) and the colorant (A-6)
(III) the colorant (A-4) and the colorant (A-11)
(IV) the colorant (A-4) and the colorant (A-12),
wherein, in the colorant (A) in the green pixel,
a content of the colorant (A-4) is 49 weight % to 59 weight %,
a content of the colorant (A-5), the colorant (A-6), the colorant (A-11) or the colorant (A-12) is 33 weight % to 51 weight %, and a content of the colorant (A-7) is 0 weight % to 13 weight %,
wherein a cured product constituting the blue pixel contains a colorant (A-8) Pigment Blue 15:6, a colorant (A-9) Pigment Violet 23, and a colorant (A-10) xanthene dye, and
wherein, in the colorant (A) in the blue pixel
a content of the colorant (A-8) is 58 weight % to 64 weight %, a content of the colorant (A-9) is 12 weight % to 20 weight %, and a content of the colorant (A-10) is 17 weight % to 25 weight %.

3. The organic EL display device according to claim 1,
wherein a content of the compound represented by General Formula (1) with respect to a total amount of the photopolymerizable monomer (B) is 50 weight % or more.

4. The organic EL display device according to claim 1,
wherein the oxime ester photopolymerization initiator is a compound represented by the following General Formula (2): 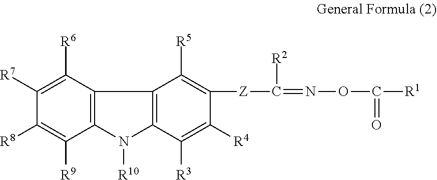
(in General Formula (2), Z represents a direct bond or a —C(═O)— group, R¹ represents an alkyl group which optionally has a substituent and has 1 to 20 carbon atoms, R² represents an alkyl group which optionally has a substituent and has 1 to 20 carbon atoms or an aryl group which optionally has a substituent, R³ to R¹⁰ each independently represent a hydrogen atom, an alkyl group which optionally has a substituent and has 1 to 20 carbon atoms, an aryl group which optionally has a substituent, a nitro group, or an R¹¹—C(═O)— group, and R¹¹ represents an aryl group which optionally has a substituent).

5. The organic EL display device according to claim 1,
wherein the oxime ester photopolymerization initiator is a compound represented by the following General Formula (3): 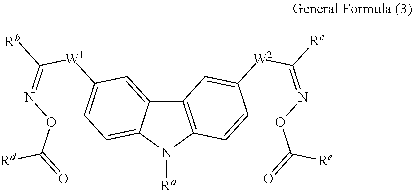
(in General Formula (3), W¹ and W² each independently represent a carbonyl bond (—CO—) or a single bond, and at least one of W¹ and W² is a carbonyl bond (—CO—), and
R^{a} is an alkyl group having 2 to 6 carbon atoms, R^{b} is an alkyl group having 4 to 10 carbon atoms, R^{c} is a group which contains at least a hydrocarbon ring or a heterocycle and may additionally contain at least one divalent linking group selected from among an alkylene chain having 1 to 4 carbon atoms, a thioether bond (—S—), an ether bond (—O—), and a carbonyl bond (—CO—), R^{b} and R^{c} are substituents different from each other, and R^{d} and R^{e} are each independently an alkyl group having 1 to 6 carbon atoms).

6. The organic EL display device according to claim 1,
wherein the resin (D) includes a photosensitive resin.

7. The organic EL display device according to claim 6,
wherein the photosensitive resin contains a vinyl polymer having an aromatic carboxylic acid at terminal of the photosensitive resin.

8. The organic EL display device according to claim 1,
wherein the photosensitive coloring composition further contains a solvent, and the solvent includes an ether ester solvent and an ether alcohol solvent.
